(19) United States
(12) Patent Application Publication
(10) Pub. No.: US 2009/0194783 A1
(43) Pub. Date: Aug. 6, 2009

(54) LIGHT EMITTING ELEMENT, PRODUCTION METHOD THEREOF, BACKLIGHT UNIT HAVING THE LIGHT EMITTING ELEMENT, AND PRODUCTION METHOD THEREOF

(75) Inventors: Masashi TAKEMOTO, Mihara-Shi (JP); Haruhisa TAKIGUCHI, Nara-shi (JP); Nobuo OGATA, Higashihiroshima-shi (JP); Kenichi UKAI, Uda-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/415,486

(22) Filed: Mar. 31, 2009

Related U.S. Application Data
(62) Division of application No. 11/603,885, filed on Nov. 22, 2006.

(30) Foreign Application Priority Data
Nov. 22, 2005 (JP) 2005-337801
Sep. 7, 2006 (JP) 2006-243327
Sep. 26, 2006 (JP) 2006-261567

(51) Int. Cl. H01L 33/00

(52) U.S. Cl. 257/98; 257/E33.001

(57) ABSTRACT

A light emitting element includes: A light emitting element, includes: at least one LED chip provided on an installation surface of a substrate; a metallic reflecting plate, provided upright in a light projecting direction of the LED chip on the installation surface so as to surround an entire periphery of the LED chip, the metallic reflecting plate reflecting light projected from the LED chip to guide the light to a light projecting surface provided in the light projecting direction; and a first metallic portion and a second metallic portion, respectively connected to the LED chip as electrode terminals for supplying a driving current to the LED chip, each being formed in an area surrounded by the metallic reflecting plate on the installation surface, wherein an insulating section is formed surrounding the second metallic portion, to electrically insulate the second metallic portion from other portion in the area, and the first metallic portion is formed outside the insulating section in the area as an installation surface metallic reflecting film so as to be in contact with the metallic reflecting plate.

### CROSS-REFERENCE TO RELATED APPLICATIONS

This application is a divisional application of U.S. application Ser. No. 11/603,885, filed Nov. 22, 2006, which claims benefit of priority under 35 U.S.C. § 119(a) on Patent Applications No. 337801/2005 filed in Japan on Nov. 22, 2005, No. 243327/2006 filed in Japan on Sep. 7, 2006, and No. 261567/2006 filed in Japan on Sep. 26, 2006, the entire contents of which are hereby incorporated by reference.

### FIELD OF THE INVENTION

The present invention relates to (i) a light emitting element suitable for laterally illuminating a thin display such as a liquid crystal panel, (ii) a production method thereof, (iii) a backlight unit having the light emitting element, and (iv) a production method thereof.

### BACKGROUND OF THE INVENTION

Conventionally, as a backlight for laterally illuminating a display panel of liquid crystal or the like, a light emitting element such as a laterally light emitting diode (hereinafter, referred to as “LED”) disclosed in, for example, Japanese Unexamined Patent Publication No. 223082/2005 ((Tokukai 2005-223082)(Publication date: Aug. 18, 2005) (corresponding to Publication of US Patent Application No. 2005/0167682) (Publication date: Aug. 4, 2005)).

As illustrated in FIG. 11, a light emitting element 101 includes: a chip substrate 114 having a die-bond pattern 108 and an electrode terminal 109; an LED chip 103 provided on the chip substrate 114; a wire 116 for connecting the LED chip 103 to the electrode terminal 109; a reflecting frame 123 which is provided on the chip substrate 114 so as to surround the LED chip 103 and has an opening at an upper surface and a part of a sidewall thereof; a reflecting surface 122 which is an internal periphery of the sidewall of the reflecting frame 123; a translucent resin 119 which is provided on the chip substrate 114 so as to fill the reflecting frame 123 and whose opening at the side of the sidewall serves as a light projecting surface 117; and a reflecting film 121 covering an upper surface of the translucent resin 119. The light emitting element 101 is arranged so that: light emitted from the LED chip 103 is reflected by a reflecting surface 122 and a reflecting surface 121 of the reflecting frame 123, and the reflected light is projected outward from the light projecting surface 117 formed on one side face.

Further, if heat generated in the light emitting element is not sufficiently radiated, the heat damages members of the element, so that light emission efficiency drops or the element per se is damaged. As a result, it is impossible to keep the long-term reliability. Thus, it is desired to develop a light emitting element having excellent heat radiating property.

For example, Japanese Unexamined Patent Publication No. 282004/2004 (Tokukai 2004-282004)(Publication date: Oct. 7, 2004) discloses a light emitting element substrate having excellent heat radiating property.

With reference to FIGS. 26 and 27, an arrangement of the light emitting element substrate of Tokukai 2004-282004 is described as follows.

FIG. 26 is a cross sectional view illustrating an arrangement of a conventional light emitting element 1000 having the light emitting element substrate.

FIG. 27 is a diagram illustrating shapes of a conduction pattern 1008 and a wiring layer 1009 of the light emitting element substrate illustrated in FIG. 26.

As illustrated in FIG. 26, the light emitting element substrate has a first electrode 1004 and a second electrode 1005 as a conduction pattern 1003, and one electrode of an LED chip (not shown) is connected to the first electrode 1004, and the other electrode of the LED is connected to the second electrode 1005.

Further, the first electrode 1004, an interlayer connection pattern 1006, a protective metallic layer 1007, and a conduction pattern 1008 are sequentially formed between a lower side of a reflector 1001 and a lower side of a portion where the LED chip is formed. Note that, the conduction pattern 1008 is formed on the wiring layer 1009.

Further, a metallic laminate on and above which the first electrode 1004, the interlayer connection pattern 1006, the protective metallic layer 1007, and the conduction pattern 1008 are laminated is arranged so as to have a larger heat transmission area which allows transmission of heat of the reflector 1001. That is, as illustrated in FIG. 27, the conduction pattern 1008 occupies a large area.

As a result, the heat of the reflector 1008 can be efficiently transmitted via the protective metallic layer 1002 and the metallic laminate to a protective metallic layer 1012 and a metallic substrate 1010 which is a lowest layer.

Generally, intensity of light emitted from the LED chip 103 is maximum in an upward direction indicated by an arrow 118 of FIG. 11. However, in the arrangement of Tokukai 2005-223082, the reflecting film 121 is formed in a light projecting direction of the LED chip 103 so as to be opposite to a light projecting surface of the LED chip 103. Thus, light emitted from the LED chip 103 is repetitively reflected between the reflecting film 121 and the chip substrate 114, so that a large part of the light emitted from the LED chip 103 is not efficiently projected outward from the light projecting surface 117. As a result, the light is absorbed by the reflecting film 121 and the chip substrate 114.

Further, according to the arrangement of the light emitting element 101 of Tokukai 2005-223082, a position of the light projecting surface 117 deviates by 90° from the upward direction (arrow 118) in which the intensity of the light emitted from the LED chip 103 is maximum. Thus, the light emitted from the LED chip 103 cannot be efficiently guided to the light projecting surface of the light emitting element 101 and cannot be projected outward from the element. Further, light which cannot be converted into fluorescent light or light which cannot be scattered in case of using fluorescent particles in a resin constituting the translucent resin 119 is repetitively reflected between the reflecting film 121 and the chip substrate 114, so that a large part of the light is absorbed by the reflecting film 121 and the chip substrate 114. Further, variation in an amount of the fluorescent particles changes scattering degree, so that the light cannot be stably projected outward.

Recently, with thickness reduction of electronic devices such as mobile phones each having a liquid crystal panel, the laterally illuminating LED used for a liquid crystal backlight is required to be thinner. However, in a conventional structure described in Tokukai 2005-223082, as a distance between an upper surface of the LED chip 103 and the reflecting film 121 is shorter, the light absorption/light leakage results in greater loss. Hence, this raises such a problem that light is much less efficiently projected outward from the light emitting element.

Thus, it is desired to develop a laterally illuminating LED which can realize smaller thickness without decreasing efficiency at which light is projected outward.

Further, as illustrated in FIGS. 26 and 27, a light emitting element of Tokukai 2004-282004 is arranged so that a metallic reflector 1001 surrounds an entire side face of the element in case where an installation surface on which the LED chip is formed is regarded as a bottom surface. Thus, light irradiated from the LED chip leaks outward from a part of the side face which part is not covered by the metallic reflector 1001.

Further, an insulating layer 1011 made of resin which less radiates heat is formed on the installation surface except for an area where the first electrode 1004 is formed and an area where the second electrode 1005 is formed. Thus, out of light emitted from the LED chip, a large part of light moving toward the substrate passes through the resin insulating layer 1011 and leaks outward from a rear surface side of the element.

The light which leaks in the foregoing manner is absorbed by other members provided on the outside of the element. This results in great energy loss in all. Thus, light emitted from the LED chip cannot be efficiently projected outward, so that intensity of light projected from the light projecting surface decreases.

### SUMMARY OF THE INVENTION

The present invention was made in view of the foregoing problems, and an object of the present invention is to provide (i) a light emitting element in which long-term reliability is realized by enhancing intensity of light projected outward from a light projecting surface and by more efficiently radiating heat while suppressing light leakage, (ii) a production method thereof, and (iii) a backlight unit having the light emitting element.

In order to achieve the foregoing object, a light emitting element of the present invention includes: at least one LED chip provided on an installation surface of a substrate; a metallic reflecting plate, provided upright in a light projecting direction of the LED chip on the installation surface so as to surround an entire periphery of the LED chip, the metallic reflecting plate reflecting light projected from the LED chip to guide the light to a light projecting surface provided in the light projecting direction; and a first metallic portion and a second metallic portion, respectively connected to the LED chip as electrode terminals for supplying a driving current to the LED chip, each of which is provided in an area surrounded by the metallic reflecting plate on the installation surface, wherein an insulating section is provided in the area so as to surround the second metallic portion, to electrically insulate the second metallic portion from other portion of the area, and the first metallic portion is formed outside the insulating section in the area as an installation surface metallic reflecting film so as to be in contact with the metallic reflecting plate.

According to the arrangement, the metallic reflecting plate which reflects light emitted from the LED chip and guides the light toward the light projecting surface provided in the light projecting direction is provided upright in the light projecting direction of the LED chip so as to surround an entire periphery of the LED chip. Thus, light irradiated from the LED chip is reflected by the metallic reflecting plate, so that the light can be efficiently guided to the light projecting surface. As a result, it is possible to suppress light leakage from the side face of the element and to enhance intensity of light projected outward from the light projecting surface.

In the area positioned at the installation surface and surrounded by the metallic reflecting plate, the insulating section for electrically insulating the second metallic portion from other portion of the area is formed so as to surround the second metallic portion. Thus, the installation surface metallic reflecting film can be formed on the area except for an area where the insulating section is formed. Thus, out of light emitted from the LED chip, a large part of light moving toward the substrate can be more efficiently guided by the installation surface metallic reflecting film toward the light projecting surface provided in a direction in which the reflected light is projected outward.

In order to achieve the foregoing object, another light emitting element of the present invention includes: at least one LED chip provided on an installation surface of a substrate; a metallic reflecting plate, provided upright in a light projecting direction of the LED chip on the installation surface so as to surround an entire periphery of the LED chip, the metallic reflecting plate reflecting light projected from the LED chip to guide the light to a light projecting surface provided in the light projecting direction; a first metallic portion and a second metallic portion, respectively connected to the LED chip as electrode terminals for supplying a driving current to the LED chip, each of which is provided in an area surrounded by the metallic reflecting plate on the installation surface; and an installation metallic reflecting film, provided on the installation surface in the area surrounded by the metallic reflecting plate so as to be in contact with the metallic reflecting plate, wherein the metallic reflecting plate is electrically insulated from both the first metallic portion and the second metallic portion.

According to the arrangement, the metallic reflecting plate which reflects light emitted from the LED chip and guides the light toward the light projecting surface provided in the light projecting direction is provided upright in the light projecting direction of the LED chip so as to surround an entire periphery of the LED chip. Thus, light irradiated from the LED chip is reflected by the metallic reflecting plate, so that the light can be efficiently guided to the light projecting surface. As a result, it is possible to suppress light leakage from the side face of the element and to enhance intensity of light projected from the light projecting surface.

Further, the metallic reflecting plate is insulated from both the first metallic portion and the second metallic portion. Thus, in providing the light emitting element of the present invention onto a housing provided as a member of an electronic device such as a mobile phone and made of aluminum or the like, the metallic reflecting plate has no potential. As a result, it is possible to provide the light emitting element, not via a resin which less radiates heat, with the metallic reflecting plate in contact with the housing. Thus, heat generated at the metallic reflecting film can be efficiently radiated to the outside of the element. As a result, it is possible to realize a light emitting element having long-term reliability.

In order to achieve the foregoing object, another light emitting element of the present invention includes: at least one LED chip provided on an installation surface of a substrate; a metallic reflecting plate, provided upright in a light projecting direction of the LED chip so as to reflect light projected from the LED chip and guide the light to a light projecting surface provided in the light projecting direction; and a translucent sealant which is provided so as to seal the LED chip and whose end in the light projecting direction has an opening as the light projecting surface, wherein a part of the side face of the translucent sealant serves as a shield-free surface, and the metallic reflecting plate is provided so as to entirely cover the side face other than the part which is shield-free, and the shield-free part is formed in a direction substantially perpendicular to a direction in which the light projecting surface is formed.

According to the arrangement, the light projecting surface is provided in the light projecting direction of the LED chip. Thus, unlike the arrangement of Tokukai 2005-223082 in which the reflecting plate is formed in the light projecting direction and the light projecting surface deviates by 90° from the light projecting direction, it is possible to project light, emitted from the LED chip, outward from the light projecting surface without any loss.

Further, the metallic reflecting plate which is provided upright in the light projecting direction of the LED chip so as to reflect light emitted from the LED chip and so as to guide the light to the light projecting surface provided in the light projecting direction is formed on a side face of the translucent sealant for sealing the LED chip, and a side face on which the metallic reflecting plate is not formed serves as a shield-free surface in a direction substantially perpendicular to a direction in which the light projecting surface is formed. Thus, for example, the backlight unit reflective sheet is disposed so as to cover the shield-free surface which is not covered by the foregoing metallic reflecting plate, thereby using the backlight unit reflective sheet also as a part of the metallic reflecting plate of the light emitting element.

Thus, if the light emitting element arranged in the foregoing manner is used for the backlight unit, it is possible to form a metallic reflecting plate which reflects light emitted from the LED chip under such condition that the backlight unit reflective sheet and the metallic reflecting plate of the light emitting element entirely cover side faces of the translucent sealant sealing the LED chip and guide the light to the light projecting surface providing in the light projecting direction. As a result, it is possible to reduce the thickness of the backlight unit without decreasing efficiency at which light is projected outward.

In order to achieve the foregoing object, a backlight unit of the present invention includes the aforementioned light emitting element and a waveguide disposed in a vicinity of the light projecting surface.

According to the arrangement, it is possible to realize a backlight unit which efficiently utilizes light and has long-term reliability due to its light emitting element which allows not only less light leakage and higher efficiency in projecting light but also excellent heat radiation.

It is desirable to arrange the backlight unit according to the present invention so as to include the light emitting element of the present invention which is provided on a light source section, wherein a heat radiating sheet covers not only an external periphery of the light emitting element but also at least a part of an external periphery of the metallic reflecting plate of the light emitting element.

It is desirable to arrange the backlight unit so that the light emitting element includes an earth electrode (third rear surface electrode) provided on a rear surface of the substrate and electrically connected to the metallic reflecting plate and an installation surface metallic reflecting film which is in contact with the metallic reflecting plate.

According to the arrangement, in addition to the aforementioned heat radiating sheet, also the third rear surface electrode thermally connected to an LED chip installation surface (installation surface metallic reflecting film) is expected to radiate heat. Further, after providing the LED chip, it is possible to prevent the metallic reflecting plate and the installation surface metallic reflecting film which is in contact with the metallic reflecting plate from having a floating potential by connecting the third rear surface electrode with the earth terminal on the installation side. As a result, it is possible to prevent malfunction or breakage which caused by surge or the like.

Another backlight unit of the present invention includes a light emitting element which includes: at least one LED chip provided on an installation surface of a substrate; a metallic reflecting plate, provided upright in a light projecting direction of the LED chip so as to reflect light projected from the LED chip and guide the light to a light projecting surface provided in the light projecting direction; and a translucent sealant which is provided so as to seal the LED chip and whose end in the light projecting direction has an opening as the light projecting surface, wherein: a part of the side face of the translucent sealant serves as a shield-free surface, and the metallic reflecting plate is provided so as to entirely cover the side face other than the part which is shield-free, and the shield-free part is formed in a direction substantially perpendicular to a direction in which the light projecting surface is formed, the backlight unit further comprising: an optical waveguide which is disposed in a vicinity of the light projecting surface so as to scatter light projected from the light projecting surface; and a reflective sheet which is disposed in contact with the optical waveguide so as to project the light scattered by the optical waveguide to a desired area, wherein: the reflective sheet is disposed so as to entirely cover the opening which constitutes a part of a side face of the translucent sealant, and the reflective sheet serves also as a metallic reflecting plate which reflects light emitted from the LED chip to guide the light to the light projecting surface.

According to the arrangement, the backlight unit reflective sheet is disposed so as to cover the shield-free surface which is not covered by the foregoing metallic reflecting plate, thereby using the backlight unit reflective sheet also as a part of the metallic reflecting plate of the light emitting element. Thus, it is possible to form a metallic reflecting plate which reflects light emitted from the LED chip under such condition that the backlight unit reflective sheet and the metallic reflecting plate of the light emitting element entirely cover side faces of the translucent sealant sealing the LED chip and guide the light to the light projecting surface provided in the light projecting direction. As a result, it is possible to reduce the thickness of the backlight unit without decreasing efficiency at which light is projected outward.

In order to achieve the foregoing object, a method according to the present invention for producing a light emitting element includes the steps of: forming at least one LED chip on an installation surface of a substrate; forming a metallic reflecting plate for reflecting light emitted from the LED chip to guide the light to a light projecting surface provided in a light projecting direction on the installation surface, so as to be disposed upright in the light projecting direction to surround an entire periphery of the LED chip; filling a space formed by the installation surface and the metallic reflecting plate with a translucent sealant so as to seal the LED chip; and segmentizing an area surrounded by the metallic reflecting plate so that a segmentized face of the translucent sealant serves as a shield-free surface in a direction substantially perpendicular to a direction in which the light projecting surface is formed.

In order to achieve the foregoing object, another method according to the present invention for producing a light emitting element includes the steps of: forming at least one LED chip on an installation surface of a substrate; forming a metallic reflecting plate for reflecting light emitted from the LED chip to guide the light to a light projecting surface provided in a light projecting direction on the installation surface, so as to be disposed upright in the light projecting direction to surround an entire periphery of the LED chip; forming a first metallic portion and a second metallic portion, each serving as an electrode terminal for supplying a driving current to the LED chip, each of which is provided on the installation surface in an area surrounded by the metallic reflecting plate so as to be electrically connected to the LED chip; and forming an installation surface metallic reflecting film in a space formed by the installation surface and the metallic reflecting plate so as to be in contact with the metallic reflecting plate, wherein the metallic reflecting plate is electrically insulated from both the first metallic portion and the second metallic portion.

According to the arrangement, the metallic reflecting plate which reflects light emitted from the LED chip and guides the light to the light projecting surface provided in the light projecting direction is provided upright in the light projecting direction of the LED chip so as to surround an entire periphery of the LED chip. Thus, the light emitting element produced in accordance with the aforementioned production method allows the metallic reflecting plate to reflect light radiated from the LED chip, thereby efficiently guiding the light to the light projecting surface. As a result, it is possible to suppress light leakage from the light emitting element, thereby enhancing intensity of light projected from the light projecting surface.

Further, the metallic reflecting plate is insulated from both the first metallic portion and the second metallic portion. Thus, in providing the light emitting element of the present invention onto a housing provided as a member constituting an electronic device such as a mobile phone and made of metal such as aluminum, the metallic reflecting plate has no potential. Thus, it is possible to provide the light emitting element on the housing, not via a resin or the like which less radiates heat, with the metallic reflecting plate in contact with the housing, so that it is possible to efficiently radiate the heat generated at the metallic reflecting plate to the outside of the element. As a result, it is possible to realize a light emitting element having long-term reliability.

In order to achieve the foregoing object, a method according to the present invention for producing a backlight unit includes: the steps of the aforementioned method; and the step of forming a heat radiating sheet for radiating outward heat, generated at the metallic reflecting plate, not only on an external periphery of the light emitting element but also on at least a part of an external periphery of the metallic reflecting plate.

As described above, the metallic reflecting plate of the present invention is insulated from other portions, so that the metallic reflecting plate has no potential. Thus, the light emitting element produced according to the foregoing method can more efficiently radiate heat generated at the metallic reflecting plate to the outside via the heat radiating sheet made of conductive material having excellent heat radiating property without any problem such as short circuit. It is desirable to use graphite having an excellent heat radiating property as the conductive material.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is an oblique perspective view of a light emitting element of Embodiment 1.

FIG. 2 is a cross sectional view of the light emitting element of Embodiment 1.

FIG. 3 is a cross sectional view of the light emitting element of Embodiment 1.

FIG. 4 is a cross sectional view of the light emitting element of Embodiment 1.

FIG. 5 illustrates a flow of a first production step for producing the light emitting element of Embodiment 1.

FIG. 6 is an oblique perspective view illustrating a state in which the light emitting element of Embodiment 1 is being produced.

FIG. 7(a) is an oblique perspective view illustrating a state in which the light emitting element of Embodiment 1 is being produced.

FIG. 7(b) is an oblique perspective view illustrating a state in which the light emitting element of Embodiment 1 is being produced.

FIG. 8 illustrates a flow of a second production step for producing the light emitting element of Embodiment 1.

FIG. 9 is an oblique perspective view of a backlight using a light emitting element of Embodiment 2.

FIG. 10 is a cross sectional view of the backlight of Embodiment 2.

FIG. 11 is an oblique perspective view of a conventional laterally illuminating LED.

FIG. 12 is an oblique perspective view of a light emitting element of Embodiment 3.

FIG. 13 is a cross sectional view of the light emitting element of Embodiment 3.

FIG. 14(a) to FIG. 14(h) are diagrams each of which illustrates how a metallic reflecting plate and a laminate substrate of the light emitting element of Embodiment 3 are arranged.

FIG. 15 is an oblique perspective view of the light emitting element of Embodiment 3.

FIG. 16 is an oblique perspective view of the light emitting element of Embodiment 3.

FIG. 17 is an oblique perspective view of a light emitting element of Embodiment 4.

FIG. 18 is a cross sectional view of the light emitting element of Embodiment 4.

FIG. 19(a) to FIG. 19(f) are diagrams each of which illustrates how a metallic reflecting plate and a laminate substrate of the light emitting element of Embodiment 4 are arranged.

FIG. 20 is an oblique perspective view of the light emitting element of Embodiment 4.

FIG. 21 is an oblique perspective view of the light emitting element of Embodiment 4.

FIG. 22 is an oblique perspective view of the light emitting element of Embodiment 4.

FIG. 23 is a cross sectional view of the light emitting element of Embodiment 4.

FIG. 24 is an oblique perspective view of the light emitting element of Embodiment 4.

FIG. 25 is a cross sectional view of the light emitting element of Embodiment 4.

FIG. 26 is a cross sectional view of a conventional light emitting element.

FIG. 27 is a cross sectional view, taken along l-l, which illustrates the light emitting element illustrated in FIG. 26.

FIG. 28 is a cross sectional view of a light emitting element of Embodiment 5.

FIG. 29 is a schematic illustrating a state in which the light emitting element of Embodiment 5 is provided in a housing of an electronic device.

FIG. 30 is a cross sectional view of a light emitting element of Embodiment 6.

FIG. 31 is a diagram schematically illustrating an arrangement of the light emitting element of Embodiment 6.

FIG. 32 is a diagram schematically illustrating an arrangement of a light emitting element of Embodiment 7.

FIG. 33(a) to FIG. 33(h) are diagrams each of which illustrates how a metallic reflecting plate and a laminate substrate of the light emitting element of Embodiment 7 are arranged.

FIG. 34 is a diagram schematically illustrating an arrangement of the light emitting element of Embodiment 4.

FIG. 35 is a diagram schematically illustrating an arrangement of the light emitting element of Embodiment 4.

FIG. 36 is a diagram schematically illustrating an arrangement of the light emitting element of Embodiment 4.

FIG. 37 is a diagram schematically illustrating an arrangement of the light emitting element of Embodiment 4.

FIG. 38 is a diagram schematically illustrating an arrangement of the light emitting element of Embodiment 5.

FIG. 39 is a diagram schematically illustrating an arrangement of the light emitting element of Embodiment 5.

FIG. 40 is a diagram illustrating an example of potentials of the light emitting element of Embodiments 5 and 6.

FIG. 41 is a diagram illustrating an example of potentials of the light emitting element of Embodiment 5.

FIG. 42 is a diagram illustrating an example of potentials of the light emitting element of Embodiment 5.

FIG. 43 is a diagram schematically illustrating an arrangement of a light emitting element of Embodiment 6.

FIG. 44 is a diagram schematically illustrating an arrangement of the light emitting element of Embodiment 6.

FIG. 45 is a diagram schematically illustrating an arrangement of the light emitting element of Embodiment 6.

FIG. 46 is a diagram schematically illustrating an arrangement of a light emitting element of Embodiment 7.

FIG. 47 is a diagram illustrating an example of potentials of the light emitting element of Embodiment 7.

FIG. 48 is a diagram illustrating an example of potentials of the light emitting element of Embodiment 7.

### DESCRIPTION OF THE EMBODIMENTS

### Best Mode for Carrying Out the Invention

### Embodiment 1

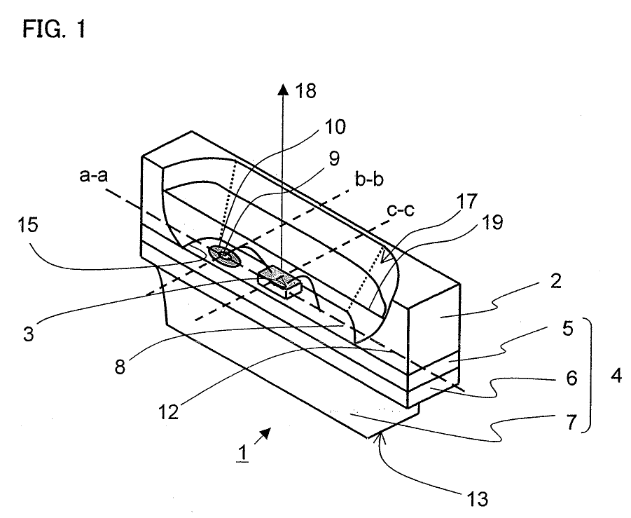

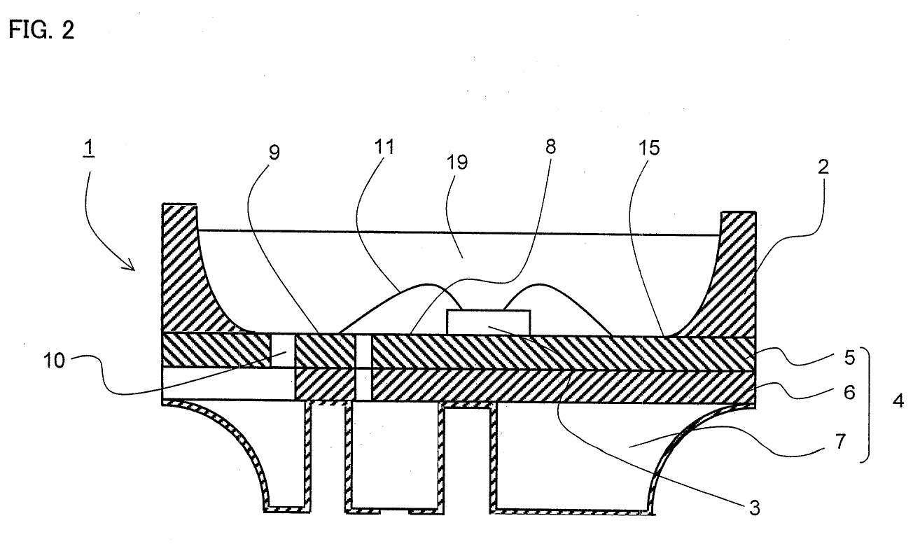

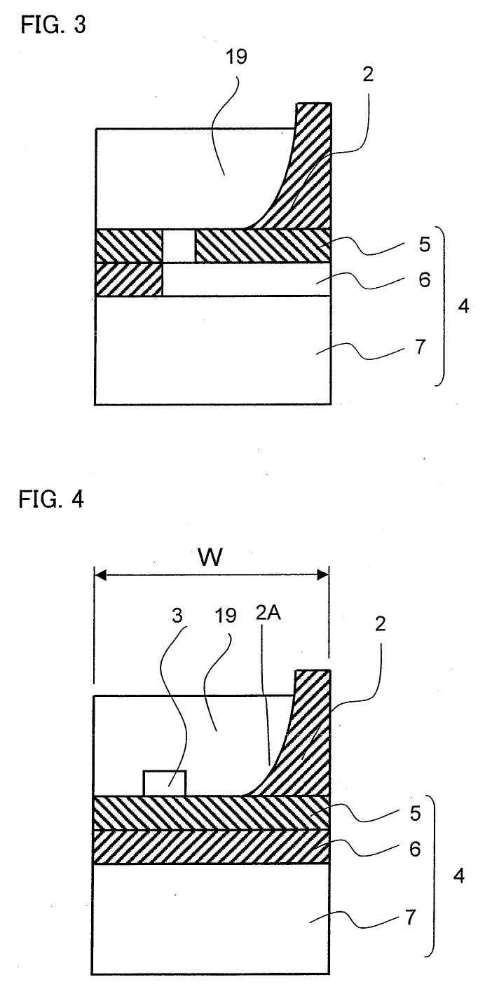

The following description will detail an embodiment of a light emitting diode chip according to the present invention with reference to attached drawings. FIG. 1 is an oblique perspective view of a light emitting element 1 in Embodiment 1 of the present invention, and FIG. 2 is a longer-side-direction cross sectional view of the light emitting element 1 (the view is taken along a line a-a), and FIG. 3 is a shorter-side-direction cross sectional view of the light emitting element 1 (the view is taken along a line b-b), and FIG. 4 is a shorter-side-direction cross sectional view of the light emitting element 1 (the view is taken along a line c-c).

As illustrated in FIGS. 1 to 4, an LED chip 3 is provided on a die-bond area/electrode section (first metallic portion) 8 positioned on a surface layer 5 (installation surface) of the laminate substrate 4. The LED chip 3 is a semiconductor chip, made of a GaN semiconductor material and the like, which includes electrode terminals (not shown) provided on its upper surface (surface opposite to a die-bonded surface) and having an anode electrode and a cathode electrode. The thus arranged LED chip 3 emits blue light. The cathode electrode is connected to the die-bond area/electrode section 8 on the surface layer 5 by wire-bonding. The anode electrode is connected to an island electrode (second metallic portion) 9, formed on the surface layer 5 of the laminate substrate 4, by wire-bonding. Note that, the LED chip 3 may be arranged so that the anode electrode is disposed on its upper surface and the cathode electrode is disposed on its lower surface (these electrodes may be disposed upside down).

A metallic reflecting plate 2 is positioned by one side of the LED chip 1 so as not to cover an area in an upward direction 18. By another side, there is a side wall shield-free surface 12 which is a side face of a translucent sealant 19. As illustrated in the cross sectional view of FIG. 4, the metallic reflecting plate 2 has a cross sectional shape perpendicular to a light projecting surface 17 so that the cross sectional shape is a skirt shape 2A whose wider portion in the vicinity of the laminate substrate 4 is positioned closer to the LED chip 3.

Further, the translucent sealant 19 made of resin such as epoxy, silicone, and the like covers the LED chip 3 so that the LED chip 3 is sealed therewith. It is desirable that the light projecting surface 17 of the translucent sealant 19 is substantially parallel to a surface of the laminate substrate 4, and the translucent sealant 19 is cut so as to expose the side wall shield-free surface 12.

Scattering particles may be included in the translucent sealant 19. In this case, the LED chip emits light in a substantially isotropic manner. Thus, it is possible to uniformly project light from the light projecting surface 17 through reflection by the metallic reflecting plate 2. As the scattering particles, it is possible to use white particles, whose particle diameter ranges from several μm to several dozen μm, e.g., titanium oxide.

Further, the translucent sealant 19 may include a fluorescent substance. In this case, by converting the blue light emitted from the LED chip into yellow light through the fluorescent substance, it is possible to obtain white light due to synthesis of the blue light emitted from the LED chip and the yellow light emitted from the fluorescent substance. The fluorescent substance particles serve also as the scattering particles.

### First Production Step of Embodiment 1

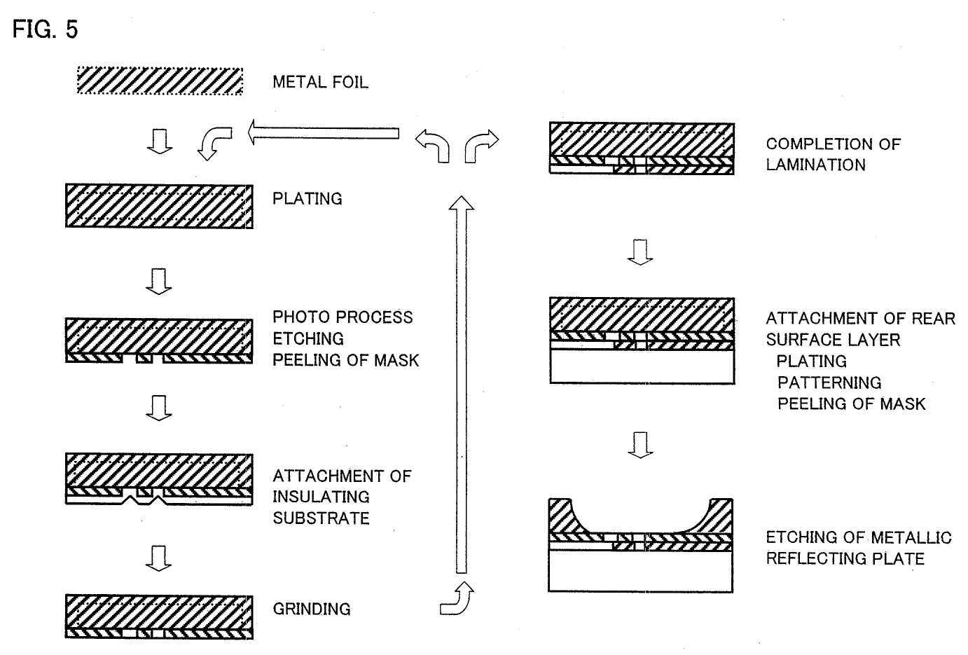

FIG. 5 is a flowchart illustrating a first production step of the light emitting element 1 according to Embodiment 1 of the present invention. As illustrated in FIG. 5, a metal foil (here, copper foil) is used as a base, and an entire surface of the metal foil is plated with the same metal (here, copper). Thereafter, a masking material is attached to the resultant by a photo process, and the masking material is subjected to exposure and development so as to have a designed size, thereby forming a mask pattern. A metal portion which is not covered by the mask pattern is etched by use of a metal etchant, thereby patterning the plated metal and the metal foil. Thereafter, the mask material is peeled off.

Further, an insulating substrate having the same thickness as that of the etched metal portion is combined to the patterned surface of the metal foil and then is pressed. The combined surface is ground until the metal surface patterned by etching is exposed. Thereafter, processes subsequent to the plating are repeated, thereby completing a multilayer substrate having the insulating substrate and the metal film.

In the flowchart of FIG. 5, two layers as the surface layer 6 and a rear surface layer 7 are processed on the basis of the aforementioned flow.

Note that, as the metal foil and the metal with which the metal foil is plated, it is desirable to use copper, gold, or nickel which is excellent in heat conductivity or to use silver of the like whose reflectivity is high with respect to the blue light. The rear surface layer 7 of the multilayer substrate is bonded to a lower portion of an intermediate layer of the multilayer substrate, and the rear surface layer 7 is generally used as an electrode after installation of the light emitting element 1 and a liquid crystal panel backlight, so that detail description thereof is omitted.

Next, the metal foil has a face which has not been patterned after bonding of the rear surface layer 7 and the face is etched by the aforementioned photo process. The etching is so-called wet etching in which a chemical solution such as alkaline solution is used. Thus, the etching is promoted in an isotropic manner, and a smaller area is etched as an etching depth is larger, so that it is possible to form a skirt shape which is suitable for more efficiently projecting light. Note that, the metal foil of the base is used as a metallic reflecting plate in the present invention, so that it is necessary to perform the etching until the etching depth penetrates the metal foil and reaches the surface layer 5 of the multilayer substrate. Further, in order to improve the reflectivity of the metallic reflecting plate, the metallic reflecting plate is plated with silver whose reflectivity with respect to light (blue light in this case) from the LED is high. In this manner, a light emitting element group obtained by integrating a plurality of light emitting elements is formed.

FIG. 6 is an oblique perspective view illustrating a state in which two light emitting elements out of the light emitting element group subjected to the aforementioned process have not been separated yet. The metal foil becomes the metallic reflecting plate 2 due to the etching. In a perforated bottom section 15 obtained by performing etching removal with respect to the metallic reflecting plate 2, the surface layer 5 of the laminate substrate 4 is exposed, and the exposed portion corresponds to the die-bond area/electrode section 8 illustrated in FIG. 1. The island electrode 9 formed on the surface layer 5 of the laminate substrate 4 is insulated from the die-bond area/electrode section 8 by an insulating ring 10 surrounding the island electrode 9. The die-bond area/electrode section 8 is integrally constituted of the same metal as the metal constituting the metallic reflecting plate 2, so that the island electrode 9 is designed and disposed so as not to be in contact with at least the metallic reflecting plate 2.

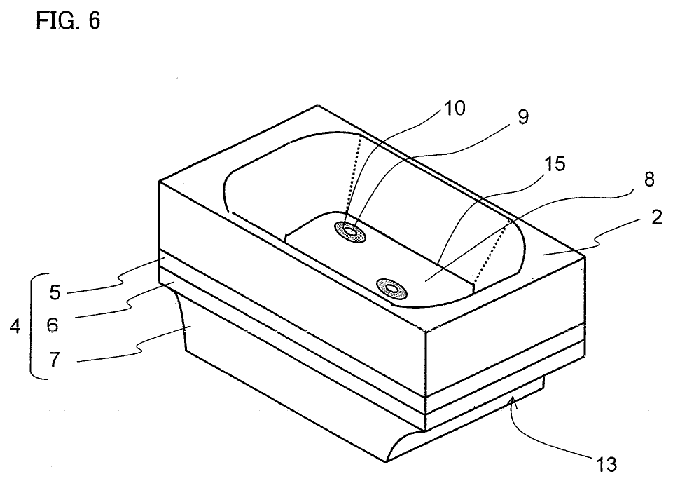

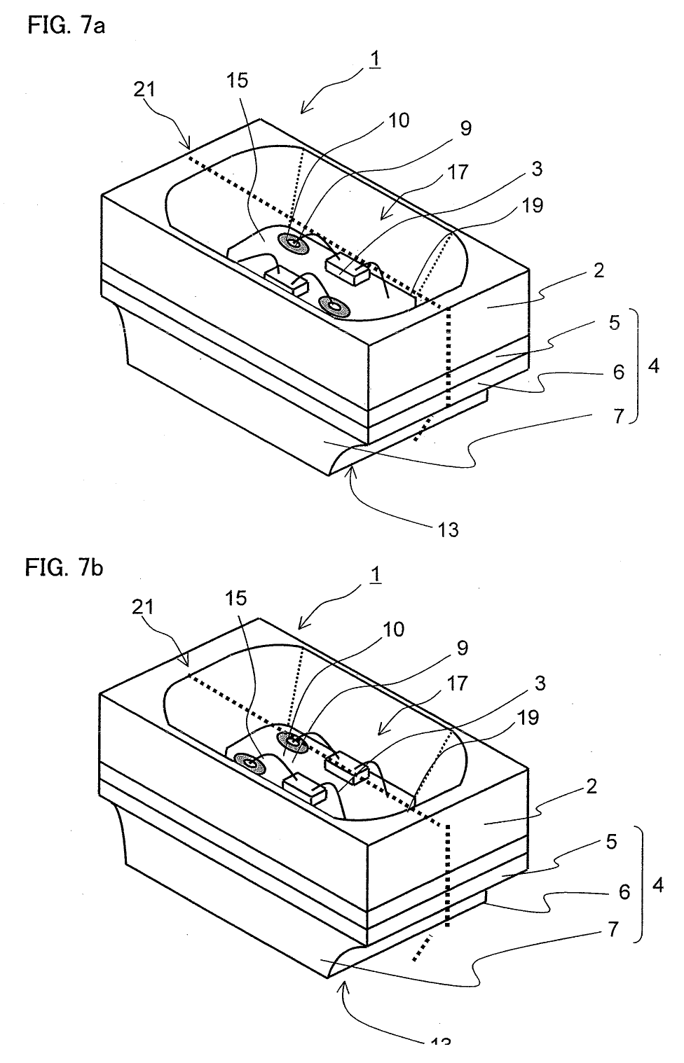

Each of FIG. 7(a) and FIG. 7(b) is an oblique perspective view illustrating a state in which the LED 3 is provided on the light emitting element group. In FIG. 7, each of the LED chips is disposed so that its longitudinal direction is along a longitudinal direction of the perforated bottom section 15, and the insulating rings 10 and the island electrodes 9 are disposed in an axisymmetric manner with respect to a center of the perforated bottom section 15. Further, in FIG. 7(b), each of the LED chips is disposed in the same manner as in FIG. 7(a), and the insulating rings 10 and the island electrodes 9 are disposed in a plane-symmetric manner with respect to the center of the perforated bottom section 15.

After disposing the LED chip 3, a resin such as epoxy, silicone, and the like is injected into an internal space formed by the metallic reflecting plate 2 and the injected resin is solidified so as to seal the LED chips 3, thereby molding the translucent sealant 19. Note that, the fluorescent substance is included in the translucent sealant 19 as necessary.

After molding the translucent sealant 19, dicing is carried out along a cutting plane line 21 so that a plurality of LED chips 3 are separated and respective light emitting elements are obtained. As a result, the light emitting element 1 having the metallic reflecting plate 2 and the side wall shield-free surface 12 in its side face is obtained.

By adopting the foregoing production method, it is possible to integrate the metallic reflecting plate and the laminate substrate, so that the heat radiating property is enhanced. Further, the island electrode can be formed in a fine manner, so that a width W of the light emitting element illustrated in FIG. 4 can be made narrower. As a result, a liquid crystal panel backlight using the present light emitting element can be made thinner.

### Second Production Step of Embodiment 1

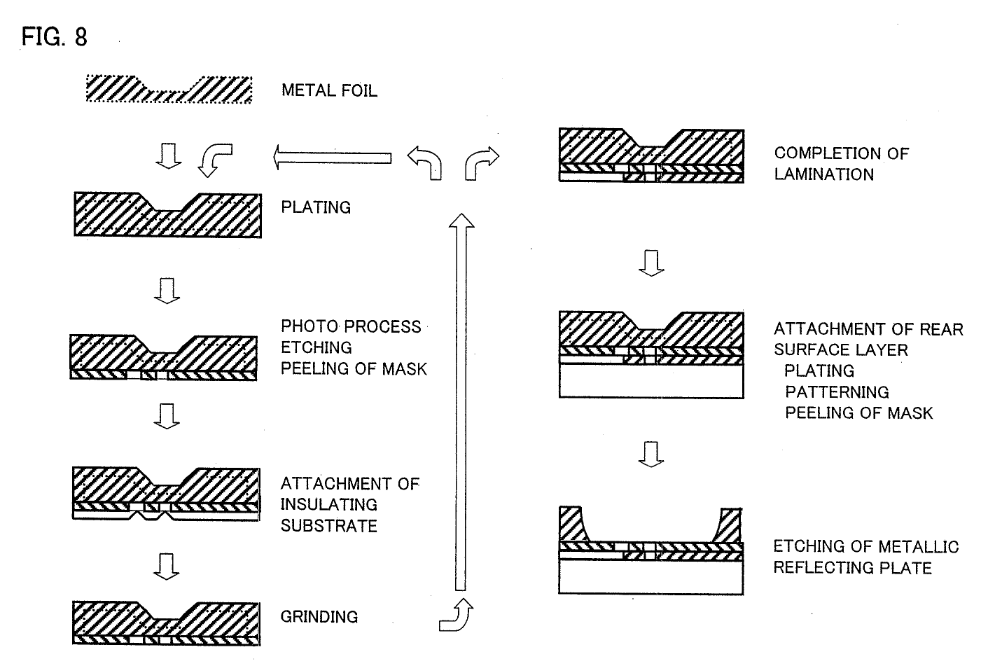

In order to further improve the controllability of the skirt shape of the metallic reflecting plate, it is possible to adopt the following production method. FIG. 8 illustrates a flow of a second production step according to Embodiment 1. The metal foil is pressed with it overlapped by a reflecting plate etching section so as to form a concave shape. Thereafter, respective processes as plating, photo-process/etching/mask-peeling, attachment of the insulating substrate, a grounding process, completion of lamination, attachment of the rear surface layer, plating/patterning/mask-peeling, and etching of the metallic reflecting plate, are carried out, and the resultant is subjected to silver plating for improving the reflectivity. Note that, the steps subsequent to the plating step are the same as the first production step of Embodiment 1. In the present production step, the concave shape is formed in advance before the wet etching, so that this allows formation of the desired shape with less wet etching, and it is possible to improve the controllability of the cross sectional shape of the metallic reflecting plate. Thus, it is possible to form a narrower bottom of the cross sectional shape of the metallic reflecting plate. As a result, the width W of the cross sectional surface shown in FIG. 4 can be made further smaller, thereby making the light emitting element and the liquid crystal panel backlight further thinner.

### Embodiment 2

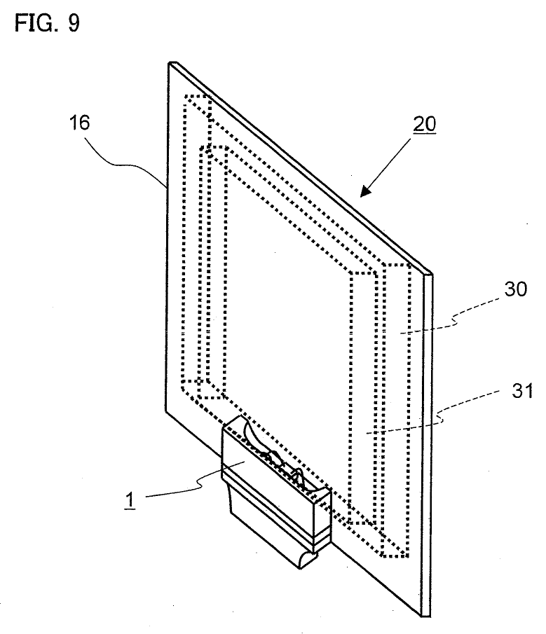

FIG. 9 is an oblique perspective view of a liquid crystal panel backlight 20 of Embodiment 2. A light emitting element 1 illustrated in FIG. 9 is arranged in the same manner as the light emitting element 1 of Embodiment 1. As illustrated in FIG. 9, a side wall shield-free surface 12 of the light emitting element 1 is bonded to a reflective sheet 16 with a translucent adhesive. An optical waveguide 30 is provided in contact with the reflective sheet 16, and light emitted from the light emitting element 1 and being incident on the optical waveguide 30 is suitably scattered, which results in illumination from a backside of a liquid crystal panel 31. Note that, the reflective sheet 16 is generally used in combination with a laterally illuminating LED which laterally illuminates a thin display such as a liquid crystal panel, and the reflective sheet 16 serves as a part of the liquid crystal panel backlight unit as well as the optical waveguide 30. In the present invention, the reflective sheet has not only an essential function for providing light to the whole liquid crystal panel but also a function as a reflective wall on the sidewall shield-free surface 12 having no metallic reflecting plate of the light emitting element 1. Thus, light emitted from the light emitting element 1 and projected from the sidewall shield-free surface 12 can be effectively used.

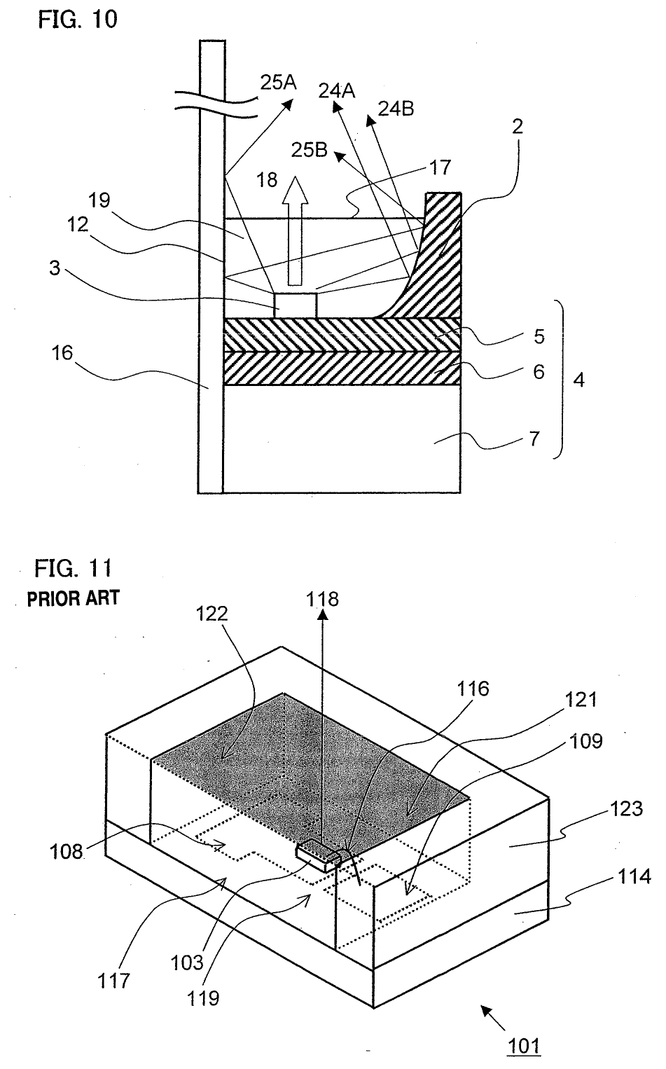

FIG. 10 is a shorter-side-direction cross sectional view (taken along a line c-c) of the liquid crystal panel 20 of Embodiment 2 with the reflective sheet 16 being bonded. As illustrated in FIG. 10, a light projecting surface 17 of the light emitting element 1 is positioned in an upward direction 18 of the LED chip 3 and is formed in a direction perpendicular to a surface of the reflective sheet 16. Thus, light emitted from the LED chip 3 into the upward direction 18 moves directly to the light projecting surface 17 of the light emitting element 1. Further, light beams 24A and 24B emitted from the LED chip 3 to the metallic reflecting plate 2 are reflected by the metallic reflecting plate 2 so as to be projected from the light emitting surface 17 outward. A cross sectional shape of the metallic reflecting plate 2 is a skirt shape whose wider portion in the vicinity of the laminate substrate 4 is positioned closer to the LED chip 3, so that light emitted from the LED chip 3 is guided into an upward direction and moves to the light projecting surface 17. Thus, it is possible to efficiently converge the light emitted from the LED chip 3 onto the light projecting surface 17.

Light beams 25A and 25b emitted from the LED chip 3 to the sidewall shield-free surface 12 are reflected by the reflective sheet 16. The light beam 25B is reflected also by the metallic reflecting plate 2 and is projected outward from the light projecting surface 17. Due to the metallic reflecting plate 2 or the reflective sheet 16, a large part of the scattering light in the translucent sealant 19 is projected outward from the light projecting surface 17.

In this manner, due to the metallic reflecting plate 2 and the reflective sheet 16, it is possible to efficiently project light even if the width W of the light emitting element 1 is small.

### Other Possible Embodiment Thereof

The light projecting surface 17 and the sidewall shield-free surface 12 may be subjected to antireflective coating. These surfaces may be made rough.

In FIGS. 7(a) and 7(b), the light emitting element group having two LEDs is divided into two light emitting elements, but a plurality of LED chips may be provided on each light emitting element. For example, a pair of blue LED chips may be provided on a single light emitting element, or a group made up of blue, green, and red LED chips is provided on a single light emitting element.

Each of FIGS. 7(a) and 7(b) illustrates an example where the light emitting element group is divided into two. However, it may be so arranged that the light emitting element group is divided into four light emitting elements each of which has two shield-free surfaces.

In each of FIGS. 7(a) and 7(b), a single LED chip is provided on each of the two light emitting elements obtained by dividing the light emitting element group, but it may be so arranged that an LED chip is provided only on the one of the light emitting elements and no LED chip is provided on the other of the light emitting elements.

In the translucent sealant 19, a fluorescent substance may be uniformly dispersed. Alternatively, for example, the fluorescent substance may be dispersed mainly on the side nearer to the laminate substrate 4.

### Embodiment 3

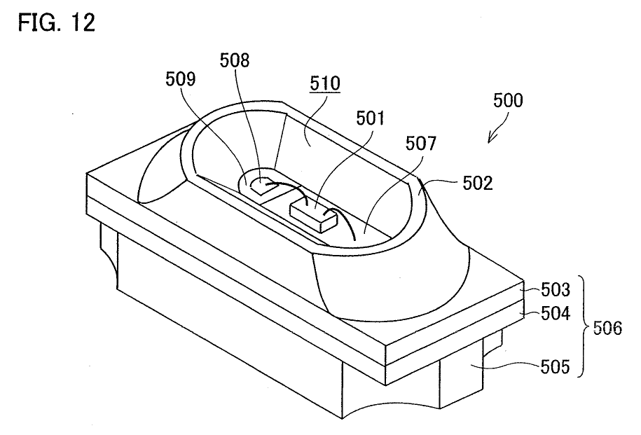

The following description will explain another embodiment of the present invention with reference to FIGS. 12 to 16.

FIG. 12 is an oblique perspective view illustrating an example of an arrangement of a light emitting element 500 of the present embodiment.

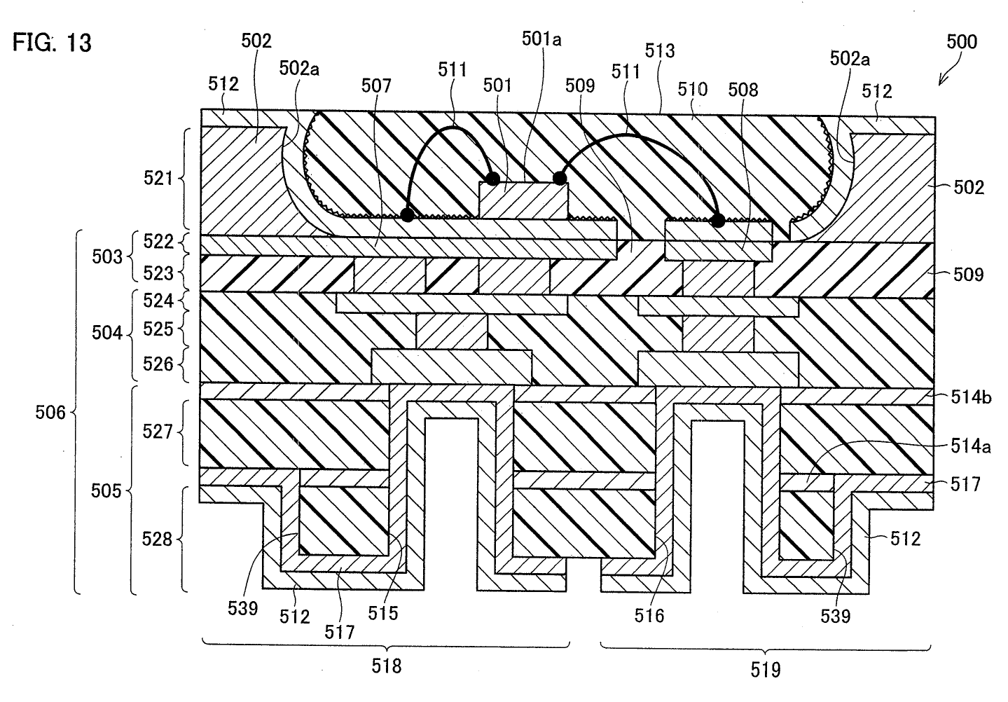

FIG. 13 is a cross sectional view which details the arrangement of the light emitting element 500.

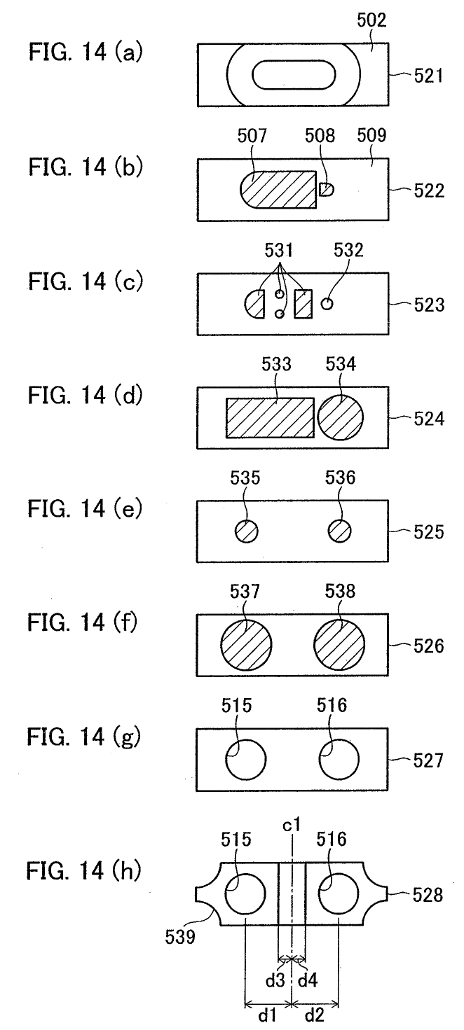

FIG. 14 illustrates, as examples, etching patterns of a metallic reflecting plate 502 and respective layers of a laminate substrate 506. FIG. 14(a) illustrates a first layer 521, FIG. 14(b) illustrates a second layer 522, FIG. 14(c) illustrates a third layer 523, FIG. 14(d) illustrates a fourth layer 524, FIG. 14(e) illustrates a fifth layer 525, FIG. 14(f) illustrates a sixth layer 526, FIG. 14(g) illustrates a seventh layer 527, and FIG. 14(h) illustrates an eighth layer 528.

As illustrated in FIG. 12, the light emitting element 500 of the present embodiment includes: an LED chip 501 provided on a laminate substrate 506; and a metallic reflecting plate 502 which is provided, on the installation surface, upright in a light projecting direction of the LED chip 501 so as to surround an entire periphery of the LED chip 501 and which reflects light from the LED chip 501 and guides the reflected light to a light projecting surface provided in the light projecting direction, wherein a translucent sealant 510 is formed so as to fill a space formed by the installation surface and surrounded by the metallic reflecting plate 502.

Further, the light emitting element 500 is provided so that the light projecting surface is positioned opposite to a side face of a liquid crystal panel provided on a display screen of a mobile phone or the like. Thus, the light emitting element 500 is used as a backlight which laterally illuminates the liquid crystal panel.

The LED chip 501 is a semiconductor chip made of GaN semiconductor material and the like, and the LED chip 501 emits blue light from the light emitting surface 501a. Further, the LED chip 501 is provided on a below-described die-bond area/electrode section (first electrode section, installation surface metallic reflecting film) 507 by die-bonding so that the light emitting surface 501a is positioned upward. On the LED chip 501, electrode terminals (not shown) respectively serving as an anode electrode and a cathode electrode are provided so as to be positioned in the light emitting surface 501a.

The laminate substrate 506 is arranged so that a surface layer 503, an intermediate layer 504, and a rear surface layer 505 are laminated from the side of the installation surface. As illustrated in FIG. 13, the laminate substrate 506 includes seven layers so that the two-layered surface layer 503, the three-layered intermediate layer 504, and the two-layered rear surface layer are laminated. The metallic reflecting plate 502 and the laminate substrate 506 are integrally formed by laminating the laminate substrate 506 on the metallic reflecting plate 502.

With reference to FIGS. 13 and 14, the arrangement of the laminate substrate 506 is detailed as follows.

First, an arrangement of the surface layer 503 is described.

The surface layer 503 has a two-layered structure in which the second layer 522 and the third layer 523 are laminated from the installation surface.

Note that, the second layer 522, that is, a surface of the laminate substrate 506 is regarded as an installation surface on which the LED chip is provided.

On the second layer 522 (installation surface), there are formed a die-bond area/electrode section (first metallic portion) and an island electrode (second metallic portion) 508 which are respectively connected to the LED chip 501 as electrode terminals each supplying a driving current to the LED chip 501. Further, an insulating section 509 for electrically insulating the island electrode 508 from the die-bon area/electrode section 507 is formed so as to surround the external periphery of the island electrode 508.

The die-bond area/electrode section 507 is connected to the cathode electrode of the LED chip 501 via wire bonding (wire 511). The die-bond area/electrode section 507 and the metallic reflecting plate 502 are integrally constituted of the same metal (copper in the present embodiment).

Note that, the material constituting the die-bond area/electrode section 507 and the metallic reflecting plate 502 is not limited to copper, and other metal may be used. However, it is desirable to use copper, silver, gold, or nickel, which has high reflectivity.

That is, in the present embodiment, the metallic reflecting plate 502 can be integrated to the die-bond area/electrode section 507 serving as the installation surface metallic reflecting film in accordance with a plating method without using any adhesive. Thus, unlike the conventional arrangement, heat generated at the time of light emission of the LED chip does not remain in a resin or the like which hardly allows heat conduction and the heat is conducted to the die-bond area/electrode section 507 formed on the surface of the substrate integrated to the metallic reflecting plate 502, so that the heat can be effectively radiated to the rear surface side of the substrate. Further, the metallic reflecting plate 502 and the die-bond area/electrode section 507 are integrated in this manner, so that metal occupies a larger area of the element. As a result, it is possible to improve the structure not only in terms of the heat radiating property but also in terms of the prevention of the light leakage.

Note that, as will be detailed later, the die-bond area/electrode section 507 has a dicing margin so as to prevent damage caused by occurrence of any burr at the time of dicing of the light emitting element 500.

While, the island electrode 508 serving as the other electrode terminal is made of copper, and the island electrode 508 is connected to the anode electrode of the LED chip 500 via wire bonding (wire 511). Further, in the area positioned at the second layer 522 serving as the installation surface and surrounded by the metallic reflecting plate 502, the island electrode 508 is formed in an island shape so that its external periphery is surrounded by the insulating section 509.

Further, a shape of the island electrode 508 is not only the shape described in the present embodiment but also any shape such as triangle, square, and rectangle. However, it is preferable to form a shape whose corners are rounded so as to avoid convergence of electric field. Further, on the island electrode 508, an element or a circuit which adjusts a driving condition of the LED chip may be provided. For example, a protective circuit element, such as a zener diode, for limiting a current applied to the LED chip may be provided. Note that, these arrangements are applicable to embodiments other than the present embodiment.

In the present embodiment, as described above, the cathode electrode of the LED chip 501 is connected to the die-bond area/electrode section 507, and the cathode electrode of the LED chip 500 is connected to the island electrode 508. However, the present embodiment is not limited to this, and it may be so arranged that the anode electrode of the LED chip 500 is connected to the die-bond area/electrode section 507 and the cathode electrode of the LED chip 500 is connected to the island electrode 508.

Note that, the die-bond area/electrode section 507 and the island electrode 508 are different from each other in a potential, and one of the anode electrode and the cathode electrode of the LED chip 501 is connected to either the die-bond area/electrode section 507 or the island electrode 508 depending on design thereof.

The insulating section 509 is made of resin and electrically insulates the die-bond area/electrode section 507 from the island electrode 508. In the present embodiment, as illustrated in FIG. 13, an interface between the insulating section 509 and the die-bond area/electrode section 507 is linear in a direction perpendicular to the light emitting surface 501a of the LED chip 501. However, in the installation surface surrounded by the metallic reflecting plate 502, it is preferable, in view of the light utilization efficiency, to narrow the insulating section 509 surrounding the island electrode 508 as much as possible so that the die-bond area/electrode section 507 serving as the installation surface metallic reflecting film occupies a larger area.

As described above, the second layer 522 includes the die-bond area/electrode section 507, the island electrode 508, and the insulating section 509. The die-bond area/electrode section 507 is laminated so as to be integrated to the metallic reflecting plate 502 and is insulated from the island electrode 508 by the insulating section 509 formed so as to surround the island electrode 508.

The third layer 523 is provided so as to electrically connect the second layer 522 to the below-described fourth layer 524 and is used to more firmly bond the insulating section 509 in forming the insulating section 509 on the second layer 522.

In a patterning surface where the insulating section 509 is not formed and the die-bond area/electrode section 507 and the island electrode 508 are formed, there is a thickness (level difference) corresponding to etching which is performed with respect to only outlines of the die-bond area/electrode section 507 and the island electrode 508. In this case, even if the insulating material having the same thickness as the aforementioned thickness is pressed with it combined to the patterning surface so as to form the insulating section 509, there is a possibility that the insulating material may come off since the bonding face is flat.

Thus, the third layer 523 including conduction sections 531 and 532 each having an etched outline is added so as to be positioned more internally than an etched outline of the second layer 522, so that a larger area is in contact with the insulating section 509. This enhances the adhesiveness of the insulating section 509.

Note that, in order to more surely separate the anode and the cathode, it is necessary to make a size of the conduction section 532 below the island electrode 508 smaller than a size of the island electrode 508.

Next, an arrangement of the intermediate layer 504 is described.

The intermediate layer 504 has a three-layered structure in which the fourth layer 524, the fifth layer 525, and the sixth layer 526 are laminated from the installation surface side. The intermediate layer 504 electrically connects the third layer 523 to electrode sections respectively formed on through holes 515 and 516 provided in the below-described fifth layer 525 and sixth layer 526.

The fourth layer 524 is formed so that the conduction section 533 electrically connected to the die-bond area/electrode section 507 and the conduction section 534 electrically connected to the island electrode 508 are not in contact with each other. The conduction section 533 is formed so that an entire area of the conduction section 531 of the third layer 523 is covered. In the same manner, the conduction section 534 is formed so that an entire area of the conduction section 532 of the third layer 523 is covered. Note that, each of the conduction sections 533 and 534 has a dicing margin in order to prevent damage caused by a burr in dicing the light emitting element 500.

The fifth layer 522 is formed so that the conduction section 535 electrically connected to the die-bond area/electrode section 507 and the conduction section 536 electrically connected to the island electrode 508 are not in contact with each other.

The sixth layer 526 is formed so that the conduction section 535 electrically connected to the die-bond area/electrode section 507 and the conduction section 538 electrically connected to the island electrode 508 are not in contact with each other.

The conduction sections 537 and 538 are respectively formed so as to have sizes larger than sizes of below-described through holes 515 and 516 respectively and so as to cover the through holes 515 and 516 in order to prevent copper from leaking from gaps of the through holes 515 and 516 in plating the through holes 515 and 516 with copper. That is, the conduction sections 537 and 538 serve as covers of the through holes 515 and 516.

Next, the rear surface layer 505 is described.

The rear surface layer 505 has a two-layered structure in which the seventh layer 527 and the eighth layer 528 are laminated. Each of the seventh layer 527 and the eighth layer 528 is constituted of a composite base material such as a glass epoxy substrate or the like by use of an adhesive tape 514a.

In the rear surface layer 505 having a two-layered structure constituted of the seventh layer 527 and the eighth layer 528, the through holes 515 and 516 are formed. The through hole 515 allows wiring of the cathode electrode connected to the die-bond area/electrode section 507, and the through hole 516 allows wiring of the anode electrode connected to the island electrode 508. The through holes 515 and 516 are provided on lower sides of the die-bond area/electrode section 507 and the island electrode 509 respectively.

The through holes 515 and 516 are disposed so as to be respectively separated from a center c1 of the installation surface with equal distances (d1=d2) from the center c1 in order to equalize heat capacities of the anode and the cathode with each other, and formation thereof is performed by drilling.

This arrangement is adopted for the following reason: in carrying out soldering so as to connect rear surface electrodes (below-described rear surface electrodes 518 and 519) to external electrodes, if an anode-side area of the rear surface electrode is different from a cathode-side area of the rear surface electrode in size, there occurs a difference in heat radiation, so that the solder unevenly melts, which results in insufficient soldering.

Further, the anode electrode and the cathode electrode are disposed on a rear surface of the laminate substrate 506 so as to be respectively separated from the center c1 with equal distances (d3=d4). Note that, a diameter of each of the through holes 515 and 516 is determined, depending on design thereof, so as to secure the dicing margin and so as not to cause any insufficient plating.

In this manner, the rear surface layer 505 in which the seventh layer 527 and the eighth layer 528 are laminated are pressed so as to be combined to the sixth layer 526 with an adhesive tape 514b intervening therebetween. Note that, the through holes 515 and 516 are respectively covered by the conduction sections 537 and 538 of the sixth layer 526.

In this state, internal peripheries of the through holes 515 and 516 are plated with copper 517. Further, the conduction sections 537 and 538 of the sixth layer 526 are provided so as to respectively cover the through holes 515 and 516, so that the copper 517 is provided also on each of the conduction sections 537 and 538 of the sixth layer 526 which are exposed toward the insides of the through holes 515 and 516.

Further, the copper 517 is formed also on a lower surface of the eighth layer 528. In addition, the copper 517 between the through holes 515 and 516 is etched. As a result, the rear surface electrode 518 electrically connected to the die-bond area/electrode section 507 and the rear surface electrode 519 electrically connected to the island electrode 508 are formed. Each of the rear surface electrodes 518 and 519 is plated with silver 512 at the same time as in plating an internal periphery face 502a of the metallic reflecting plate 502 with silver 512.

The metallic reflecting plate 502 reflects light emitted from the light emitting surface 501a of the LED chip 501 and guides the light to the light projecting surface 513. Further, the metallic reflecting plate 502 is made of copper and is provided on the installation surface of the substrate and is integrated to the laminate substrate 506 so as to surround the LED chip 501 and the island electrode 508. In more detail, the metallic reflecting plate 502 is integrated to the die-bond area/electrode section 507 so that the die-bond area/electrode section 507 is partially exposed at a portion surrounded by the internal periphery of the metallic reflecting plate 502.

As illustrated in FIG. 13, the metallic reflecting plate 502 is formed so that the internal periphery 502a has an arch-shaped cross section in the laminating direction.

Note that, the shape of the internal periphery of the metallic reflecting plate 502 is formed by etching a substantially cuboid metallic reflecting plate. Alternatively, it may be so arranged that: a metal foil is pressed so as to have a concave shape, and the concave shape is etched so as to form a shape of the internal periphery of the metallic reflecting plate 502. As a result, the concave shape having been formed is etched, so that it is possible to more easily form the shape of the internal periphery of the metallic reflecting plate 502.

An external periphery of the metallic reflecting plate 502 has a gentle curve in its cross sectional shape perpendicular to the laminate substrate 506 due to wet etching. In more detail, the cross section has a gentle curve which is separated further away from the LED chip 501 as it extends from the upper end to the lower end.

The translucent sealant 510 is formed so as to cover an internal space formed by the laminate substrate 506 and the metallic reflecting plate 502. Further, the translucent sealant 510 is made of resin. In the present embodiment, silicone is used as the resin. The light emitted from the light emitting surface 501a of the LED chip 501 is projected outward from a light projecting surface 513 which is provided on the translucent sealant 510 so as to be in the light projecting direction.

An upper surface of the metallic reflecting plate 502 and the internal periphery face 502a of the metallic reflecting plate 502 are plated with silver 512. Silver has extremely high reflectivity with respect to blue light. Thus, by plating the upper surface and the internal periphery 502a with silver, it is possible to more efficiently reflect light emitted from the LED chip 501, thereby guiding the light to the light projecting surface 513.

Note that, the translucent sealant 510 is used to protect the LED chip 501, a wire 511, and silver.

As described above, the metallic reflecting plate 502 is plated with the silver 512 having high reflectivity with respect to blue light so that light from the LED chip 501 is efficiently reflected. However, silver is highly reactive, so that its color is significantly changed and its quality is deteriorated due to corrosive gas or the like. Thus, in order to prevent silver from reacting or coming off under an unfavorable condition, silver is protected by the translucent sealant 510.

In the present embodiment, as described above, an internal periphery of the metallic reflecting plate 502 has edges in the light projecting direction of the LED chip so that the edges constitute an opening, as the light projecting surface 513, at an uppermost level of a space formed by the installation surface and the metallic reflecting plate 502, and the translucent sealant 510 is provided so as to fill the space. The space has such a shape that a lateral width at an intermediate level between the light projecting surface 513 (end opening) and the installation surface serving as a bottom is larger than a lateral maximum width of the light projecting surface 513, and the space becomes narrower from the intermediate portion to the opening.

Further, the internal periphery 502a which is a part of the metallic reflecting plate 502 and is plated with the silver 512 has a rough and bumpy surface, and the die-bond area/electrode section 507 and the island electrode 508 whose internal peripheries are in contact with the translucent sealant 510 have rough and bumpy surfaces.

A preferable example of the rough surface is a shape in which sharp peaks and troughs are continuously formed. In making the surface rough, it is possible to adopt various methods generally and conventionally used. In the step of forming the metallic reflecting plate 502 by etching, or in the etching step of removing a nickel layer (not shown) provided between the metallic reflecting plate 502 and the second layer 522 from the installation surface after the foregoing step, an etchant or an etching condition is changed from a normal condition so as to make the surface of the metallic reflecting plate 502 rough, thereby making the internal periphery face 502a rough.

The silver 512 with which the plating is carried out is so reactive that it is likely to be deteriorated and corroded, so that it is necessary to protect the silver 512 and prevent coming-off and deterioration of the silver 512. Thus, the present embodiment is arranged in the foregoing manner so that the translucent sealant 510 is tightly in contact with the silver 512, thereby improving a function as a protective film of the resin sealant 510.

Note that, in case of obtaining the white light based on the blue light emitted from the LED chip 501, it is possible to adopt the method using the yellow fluorescent substance as described above or a method using a green fluorescent substance and a red fluorescent substance. Combination of these methods allows mixture of different kinds of light, so that it is possible to obtain white light.

Next, the following description explains a direction in which light from the LED chip 501 moves in the light emitting element 500 arranged in the foregoing manner.

First, light emitted from the light emitting surface 501a of the LED chip 501 is required to be efficiently projected without any loss of light from the light projecting surface 513. As described above, a direction in which intensity of light emitted from the light emitting surface 501a of the LED chip 501 is highest is a direction perpendicular to the light emitting surface 501a. Thus, the light projecting surface 513 of the translucent sealant 510 is provided so as to be opposite to the light emitting surface 501a of the LED chip 501, so that the light projecting surface 513 is most favorably disposed.

However, in more detail, light emitted from the light emitting surface 501a of the LED chip 501 is emitted in all directions from the light emitting surface 501a. Moreover, a wavelength of the light is converted by the fluorescent substance and the converted light is emitted in a scattering manner while passing through the translucent sealant 510. Therefore, the light moves in any direction within 180°.

The metallic reflecting plate 502 has the circumference without any segmentation, so that the light moving toward the metallic reflecting plate 502 is reflected by the internal periphery face 502a of the metallic reflecting plate 502 without leaking outward from the metallic reflecting plate 502. Further, after single or several-time reflection of the light, the light is projected from the light projecting surface 513 of the translucent sealant 510.

Note that, the fluorescent substance is inclined to sink to the bottom. Thus, in the translucent sealant 510, the fluorescent substance is inclined to sink toward the substrate. However, in the light emitting element 500 of the present embodiment, light is reflected by the metallic reflecting plate 502, thereby guiding the light toward the substrate. Therefore, it is possible to effectively utilize the fluorescent substance.

While, light emitted from the LED chip 501 does not entirely reach the light projecting surface 513, and also light moving toward the laminate substrate 506 occurs. A light path in this case is detailed as follows.

If the laminate substrate 506 is made of resin, the laminate substrate 506 allows transmission of light due to its light transmitting property. In order to cover the disadvantage, it is possible to adopt the following arrangement: metal is provided on any one of layers of the laminate substrate so as to suppress light which has passed through the resin and leaks from a laminating direction (i.e., a laminating direction opposite to the side of the light emitting surface 501a).

However, in the production steps, the light emitting element 500 is finally separated by dicing. At an end face formed by the dicing, ends of the respective layers are exposed. Therefore, light moving in the layers is projected outward from the end face.

That is, suppose that a package of the light emitting element 500 is substantially cuboid, the LED chip 501 is a weighted center, and the light projecting surface 513 is a certain face. In this case, light leaks from four faces each of which has an angle of 90° with respect to the light projecting surface 513.

In the present embodiment, in order to prevent the light leakage, the die-bond area/electrode section 507 and the island electrode 508 are formed on the area positioned at the installation surface and surrounded by the metallic reflecting plate so that the island electrode 508 is surrounded by the insulating section, and the die-bond area/electrode section 507 is extensively formed on an area other than the insulating section.

The light which leaks from the light emitting element becomes stray light. When the light emitting element is provided as a light source such as a backlight of a liquid crystal panel, the stray light is unnecessary light in making display on the liquid crystal panel. Further, also in case of causing the light source to remove the unnecessary light, this arrangement results in light loss. Therefore, it is impossible to effectively utilize the light emitted from the LED chip.

Further, the stray light is absorbed by other member provided on an outside of the light emitting element, so that this results in significant energy loss in total. Likewise, it is impossible to effectively utilize light emitted from the LED chip.

Metal reflects light. Therefore, even if light moves toward the laminate substrate 506, the arrangement realizes the following effect: Metal is formed on a larger area of the installation surface surrounded by the metallic reflecting plate 502, so that it is possible to increase light moving toward the light projecting surface 513 by reflecting the light again while preventing the light from passing through the laminate substrate 506. Also, it is possible to further suppress light passing through the laminate substrate 506.

The light emitting element 500 according to the present invention is arranged so that the metallic reflecting plate 502 for reflecting light emitted from the LED chip 501 and for guiding the light to the light projecting surface 513 provided in the light projecting direction is provided upright in the light projecting direction of the LED chip 501 and surrounds the entire periphery of the LED chip 501. Thus, it is possible to efficiently reflect the light irradiated from the LED chip 501 by the metallic reflecting plate and guide the light to the light projecting surface 513. As a result, it is possible to control the light leakage from the side face of the light emitting element 500, so that it is possible to enhance intensity of light projected from the light projecting surface 513.

Further, in the area positioned at the installation surface and surrounded by the metallic reflecting plate 502, the die-bond area/electrode section 507 serving as the installation surface metallic reflecting film is formed on an area other than an area where the insulating section 509 for insulating the island electrode 508 from the die-bond area/electrode section 507 is formed. Thus, out of light emitted from the LED chip, a large part of light moving toward the substrate is reflected by the die-bond area/electrode section 507, thereby guiding the light to the light projecting surface 513 provided in the light projecting direction. Thus, it is possible to decrease an amount of light absorbed by the substrate and an amount of light which passes through the substrate and leaks outward from the rear surface side. As a result, it is possible to enhance intensity of light projected from the light projecting surface.

Further, in the light emitting element 500 of the present embodiment, the LED chip 501 generates heat due to its light emission. However, the LED chip 501 is provided on the die-bond area/electrode section 507 which occupies a large area, and the die-bond area/electrode section 507 is integrated to the metallic reflecting plate 502. Therefore, the light emitting element 500 according to the present embodiment has excellent heat radiating property and can reduce such problem that the heat damages members constituting the element or damages the element per se.

Further, the translucent sealant 510 of the light emitting element 500 is made of silicone. The silicone is less adhesive, so that silicone may come off if it is merely combined to a flat surface.

However, in the light emitting element 500, the metallic reflecting plate 502 is formed so that a lateral width of the opening corresponding to the light projecting surface 513 is smaller than a lateral width at the intermediate level between the opening section and the bottom section on the installation surface side, thereby preventing the translucent sealant 510 from coming off from the light emitting element 500.

Further, in the light emitting element 500 of the present invention, the metallic reflecting plate 502 whose internal periphery is plated with the silver 512 and is in contact with the translucent sealant 510 has a bumpy shape. In this manner, a contact area between the translucent sealant 510 and the metallic reflecting plate 502 is increased. Therefore, it is possible to more firmly bond the translucent sealant 510 and the metallic reflecting plate 502 with each other. As a result, it is possible to suppress such problem that the translucent sealant 510 comes off.

Further, as illustrated in FIG. 13, it is desirable that at least the rear surface electrode 519 is formed so as to cover an entire area corresponding, in a laminating direction, to an area where the insulating section 509 surrounding the island electrode 508 is formed. Thus, it is possible to prevent such disadvantage that, out of light emitted from the LED chip 501, light moving from the installation surface into the substrate passes through the insulating section 509 of the substrate and leaks from the rear surface side to the outside of the element. As a result, it is possible to enhance intensity of light projected from the light projecting surface 513.

Thus, it is possible to reflect the light passing through the laminate substrate, thereby preventing the light from leaking outward. Therefore, it is possible to suppress the light leakage.

The island electrode 508 is connected to the rear surface electrode 519 via the conduction section 534 formed on the fourth layer 524. Note that, it is desirable that the conduction section 524 is formed so as to cover an entire area corresponding, in a laminating direction, to an area where the insulating section 509 is formed.

In this manner, the insulating section 509 is formed so as to be covered by the conduction section 534 provided nearer to the substrate installation surface than the rear surface electrode 519, thereby more effectively decreasing an amount of light which passes through the insulating section 509 and leaks from the rear surface side to the outside of the element.

In addition, it is preferable to form the conduction section 534 so as to have a size covering the insulating section 509 surrounding the island electrode 508 positioned more internally than the internal periphery of the metallic reflecting plate 502 so that the conduction section 534 covers the insulating section 509. This allows light passing through the laminate substrate 506 to be reflected, thereby preventing the light from passing to the rear surface layer 505. Therefore, it is possible to further suppress the light leakage.

Further, notches 539 are respectively provided on four corners of the eighth layer 528 of the laminate substrate 506. Also each of the notches 539 is plated with copper 517.

In case of the foregoing arrangement, when finally dicing the light emitting element 500, also the copper-plated portion formed on the notch 539 is diced. Therefore, the copper-plated portion in the cut surface has a burr. Thus, a metal hangnail derived from the burr comes into contact with the metallic reflecting plate 502, so that short circuit may occur.

A largest outer periphery of the metallic reflecting plate 502 is disposed more internally than a position where the notch 539 is formed, thereby preventing occurrence of the short circuit.

Specific description thereof is as follows. As the maximum thickness, the metal hangnail has the same thickness as the rear surface layer 505. Suppose that a distance between the largest outline of the external periphery of the metallic reflecting plate 502 and the notch 539 is A, and a thickness of a portion sandwiched by the metallic reflecting plate 502 and the rear surface layer 505 (a distance from the second layer 522 to the seventh layer 527) is B, and a thickness of the rear surface layer 505 is C. The arrangement is preferably designed so that A>C−B.

Further, shapes of the opening and the external periphery of the metallic reflecting plate 502 are determined depending on shapes and designs each of which allows easy etching. FIG. 15 illustrates a metallic reflecting plate 541 having a shape of another external periphery. FIG. 16 illustrates a metallic reflecting plate 542 having a shape of still another external periphery and an opening 543.

Also, it is desirable to reduce an external shape size of the light emitting element as much as possible so as to meet needs for reducing a size of the light source. However, in order to secure a light emitting area of the light source, the opening of the metallic reflecting plate 502 is designed to be as large as possible.

### Embodiment 4

The following description will explain another embodiment of the present invention with reference to FIGS. 17 to 25 and FIGS. 34 to 37. Note that, the present embodiment is arranged in the same manner as Embodiments 1 to 3 except for an arrangement described below. For convenience in description, the same reference numerals are given to members having the same functions of the members illustrated in Embodiments 1 to 3, and descriptions thereof are omitted.

Further, in addition to the effects exhibited by the light emitting element 500 of the aforementioned embodiments, a light emitting element 600 of the present embodiment further exhibits effects such as more favorable suppression of light leakage and reduction of the number of layers in a laminate substrate 606. The following description explains only the effects and the arrangement exhibiting the effects.

In the light emitting element 500 of the aforementioned embodiments, the insulating section 509 is arranged so that the interface between the insulating section 509 and the die-bond area/electrode section 507 is linear in a direction perpendicular to the light projecting surface.

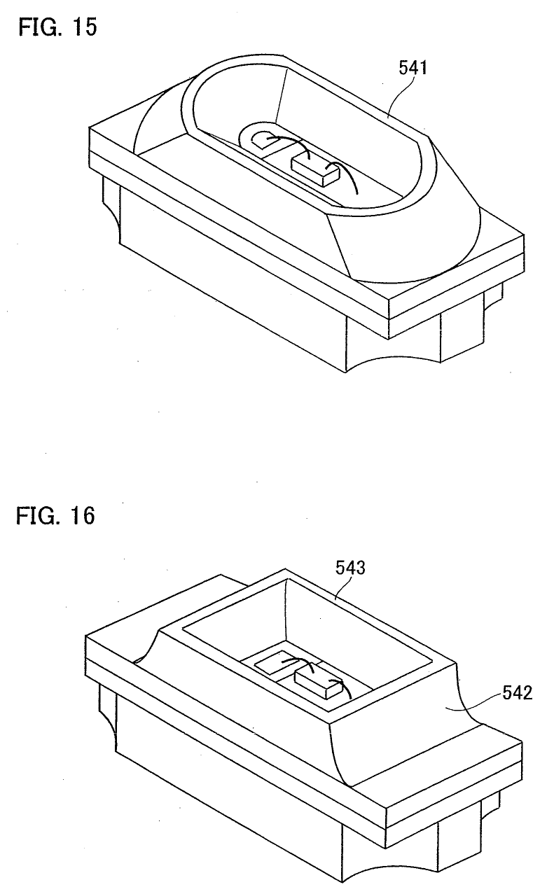

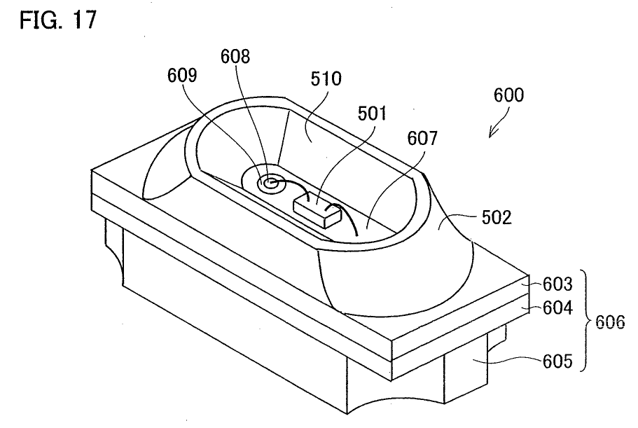

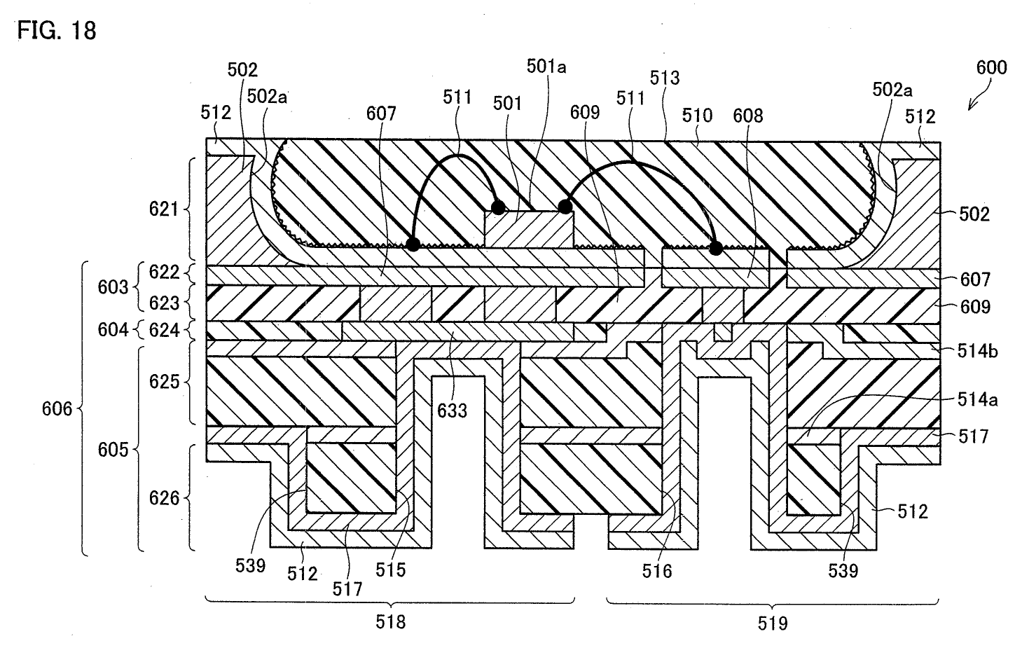

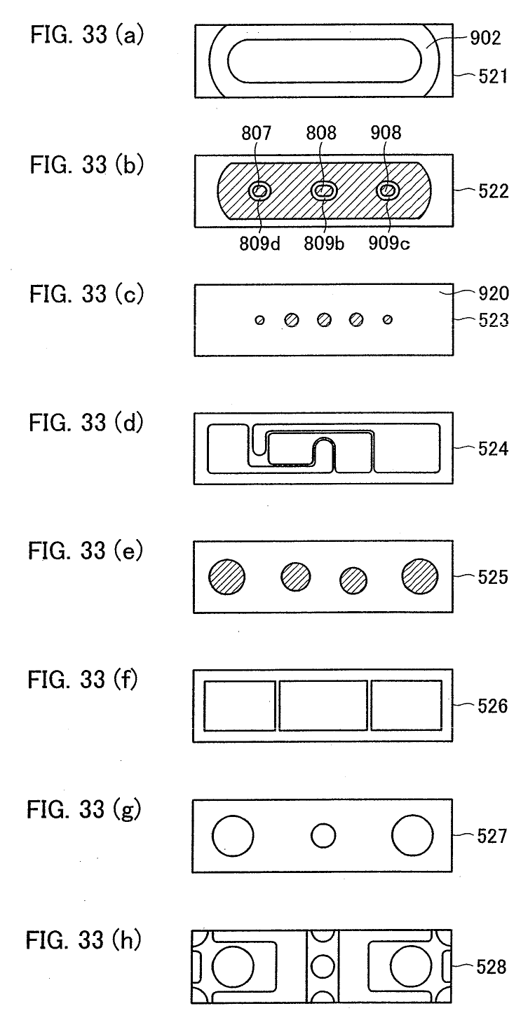

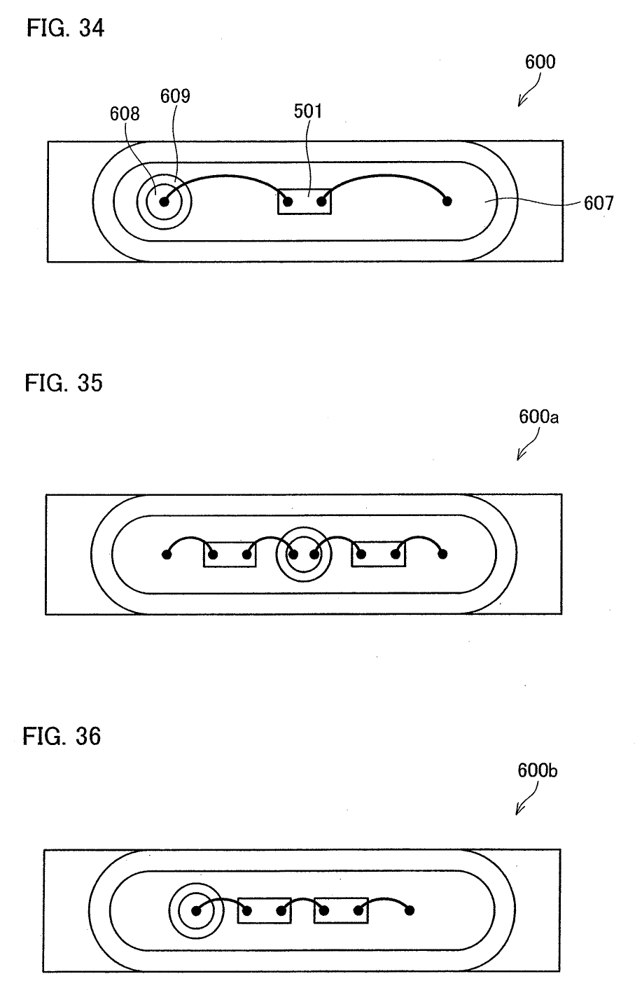

In the present embodiment, as illustrated in FIG. 17, FIG. 18, and FIG. 34, an insulating section 609 for electrically insulating the island electrode 608 from the die-bond area/electrode section 607 is formed in a circular shape on an area positioned at the installation surface and surrounded by the metallic reflecting plate 502 so as to surround an external periphery of the island electrode 608. Thus, the island electrode 608 can be insulated from the die-bond area/electrode section 607 with a smaller area.

Further, the die-bond area/electrode section 607 is formed so as to surround the insulating section 609 for electrically insulating the island electrode 608 from the die-bond area/electrode section 607, and the die-bond area/electrode section 607 intervenes between the insulating section 609 and the metallic reflecting plate 502. Thus, even if any positional deviation occurs in the step of forming the metallic reflecting plate 502, a shape and an area size of the insulating section 609 are not influenced by the positional deviation, so that there is no unevenness in an amount of light leakage from the insulating section 609. Further, it is possible to minimize a separation distance for insulating the metallic reflecting plate 502 from the die-bond area/electrode section 507 and the second island electrode 508 without caring an alignment error in the process, so that an area of the insulating section 609 can be designed so as to be minimized. Thus, it is possible to more effectively prevent the light leakage from the insulating section 609, so that light moving from the metallic reflecting plate 502 toward the substrate can be more efficiently reflected by the installation surface metallic reflecting film toward the light projecting surface 513. As a result, it is possible to further improve the light utilization efficiency and the heat radiating property.

That is, the die-bond area/electrode section 607 serving as the installation surface metallic reflecting film can be extensively formed on the area positioned at the installation surface and surrounded by the metallic reflecting plate 502 so as to surround the island electrode 608 via the insulating section 609, so that it is possible to decrease an amount of light absorbed by the substrate and an amount of light which passes through the substrate and leaks from the rear surface side to the outside compared with the arrangement of Embodiment 3.

FIG. 17 is an oblique perspective view illustrating an example of an arrangement of the light emitting element 600 of the present embodiment.

As illustrated in FIG. 17, the light emitting element 600 includes an LED chip 501, a metallic reflecting plate 502, a laminate substrate 606 (a surface layer 603, an intermediate layer 604, and a rear surface layer 605), and a translucent sealant 510.

On the surface layer 603, a die-bond area/electrode section (first metallic portion) 607, an island electrode (second metallic portion) 502, and an insulating ring (insulating section) 609 are formed.

As described above, the insulating ring 609 is formed in a circular manner so as to surround the island electrode 608. Thus, even if the die-bond area/electrode section (first metallic portion) 607 serving as the installation surface metallic reflecting film is extensively formed on an area positioned at the installation surface and surrounded by the metallic reflecting plate 502, it is possible to insulate the island electrode 608 from other portions of the area. Thus, out of light emitted from the LED chip 501, a large part of light moving toward the substrate is reflected by the installation surface reflecting film, so that the light can be guided toward the light projecting surface 513 provided in the light projecting direction. Thus, it is possible to decrease an amount of light absorbed by the substrate and an amount of light which passes through the substrate and leaks from the rear surface side to the outside of the element, thereby enhancing intensity of light projected from the light projecting surface 513.

Further, in the light emitting element 600 according to the present embodiment, a resin which less radiates heat is formed on a smaller area, and the die-bond area/electrode section 507 serving as the installation surface metallic reflecting film is extensively formed, so that it is possible to improve also the heat radiating property. Further, as in Embodiment 4, the die-bond area/electrode section 607 is integrated to the metallic reflecting plate 502, so that heat generated at the metallic reflecting plate 502 can be more efficiently radiated outward.

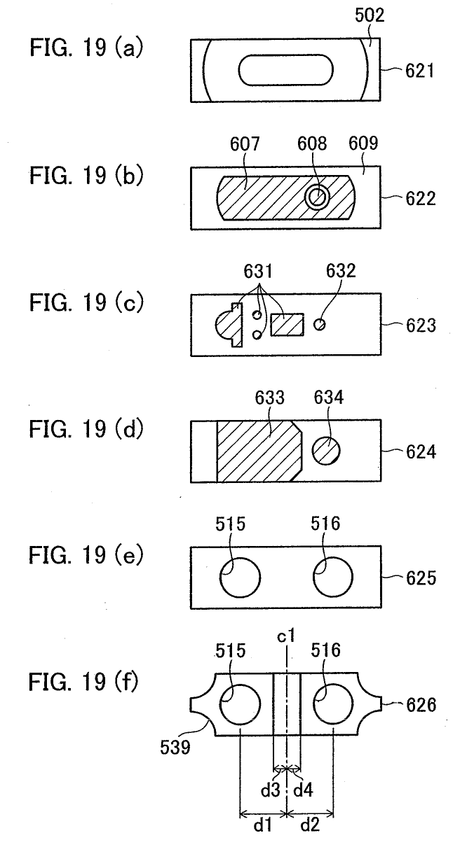

Further, the laminate substrate 606 of the light emitting element 600 of the present embodiment has fewer layers than those of the laminate substrate 506 of the light emitting element 500 of the aforementioned embodiments. The following description explains an arrangement of the laminate substrate 606 with reference to FIGS. 18 and 19. Note that, the laminate substrate 606 is integrated to the metallic reflecting plate 502, so that the number of layers is counted by regarding the metallic reflecting plate 502 as a first layer 621.

FIG. 18 is a cross sectional view which details an arrangement of the light emitting element 600.

FIG. 19 illustrates examples of an etching pattern between the metallic reflecting plate 502 and respective layers of the laminate substrate 606. FIG. 19(a) illustrates the first layer 621, FIG. 19(b) illustrates a second layer 622, FIG. 19(c) illustrates a third layer 623, FIG. 19(d) illustrates a fourth layer 624, FIG. 19(e) illustrates a fifth layer 625, and FIG. 19(f) illustrates a sixth layer 626.

The surface layer 603 is constituted of the second layer 622 and the third layer 623.

On the second layer 622, the die-bond area/electrode section (first metallic portion) 607 and the island electrode (second metallic portion) 608 which are respectively connected to the LED chip 501 as electrode terminals each of which supplies a driving current to the LED chip 501. Further, the insulating ring 609 for electrically insulating the island electrode 608 from the die-bond area/electrode section 607 is formed in a circular manner so as to surround the island electrode 608.

Unlike Embodiment 3, the die-bond area/electrode section 607 is formed on the installation surface of the present embodiment so as to surround an external periphery of the island electrode 608 via the insulating section 609. That is, the die-bond area/electrode section 607 serving as the installation surface metallic reflecting film is formed also between the metallic reflecting plate 602 and the insulating section 609 which are formed on the installation surface.

Note that, the die-bond area/electrode section 607, the island electrode 608, and the insulating ring 609 are arranged in the same manner as the die-bond area/electrode section 507, the island electrode 508, and the insulating section 509 of the aforementioned embodiments except for the shapes thereof.

The third layer 623 is a layer which electrically connects the second layer 622 and the below-described fourth layer 624 to each other, and is used to more firmly bond the insulating section in forming the second layer 622 on the insulating section.

Further, the conduction sections 631 and 632 each of which electrically connects each electrode on the installation surface to each rear surface electrode are formed on the third layer 623. The conduction sections 631 and 632 are arranged basically in the same manner as the conduction sections 531 and 532 of the aforementioned embodiments. Note that, sizes of the conduction sections 631 and 632 are suitably determined according to shapes of the die-bond area/electrode section 607 and the island electrode 608.

Next, the intermediate layer 604 is described.

The intermediate layer 604 of the present embodiment is constituted only of the fourth layer 624 unlike the laminate substrate including the intermediate layer 504 having the three-layered structure of Embodiment 3.

The fourth layer 624 is a connection layer which electrically connects rear surface electrodes 518 and 519 which are respectively formed on through holes 515 and 516 respectively provided in the fifth layer 625 and the sixth layer 626.

Further, on the fourth layer 624, there are formed the conduction section 633 electrically connected to the die-bond area/electrode section 607 and the conduction section 634 electrically connected to the island electrode 608 so that the conduction sections 533 and 634 are not in contact with each other.

In order to prevent copper from leaking in plating the through hole 515 with copper, the conduction section 633 is formed so as to entirely cover the through hole 515. That is, the conduction section 633 serves as a cover of the through hole 515. Note that, a burr may occur in dicing the light emitting element 600, but the conduction section 633 has the same potential as the metallic reflecting plate 502, so that the burr raises no critical problem.

The conduction section 634 is formed on the third layer 623 so as to entirely covers a portion where the conduction section 632 is formed and so as to have a smaller width than the through hole 516 in a plane direction. Further, the conduction section 634 is formed so as to have a dicing margin so that damage caused by occurrence of any burr is prevented in dicing the light emitting element 600.

Next, the rear surface layer 605 is described.

The rear surface layer 605 has a two-layered structure in which the fifth layer 625 and the sixth layer 626 are laminated. The fifth layer 625 and the sixth layer 626 are arranged in the same manner as the seventh layer 527 and the eighth layer 528 of the aforementioned embodiments.

The rear surface layer 605 in which the fifth layer 625 and the sixth layer 626 are laminated is pressed so as to be combined to the fourth layer 624 with an adhesive tape therebetween. At this time, the through hole 515 is covered by the conduction section 633 of the fourth layer 624.

While, the through hole 516 stores the conduction section 634 of the fourth layer 624 therein and is covered by the third layer 623. In this manner, a lateral width of the conduction section 634 of the fourth layer 624 is made smaller than a lateral width of the through hole 516, so that the through hole 516 is covered by the third layer 623. The fifth layer 625 and the sixth layer 626 which are laminated and integrated are geometrically such that only a plane of the conduction section 633 is in contact with the fourth layer 624, so that pressurization may cause the plane to slant, which results in occurrence of a gap. However, by suitably adjusting the thickness of the conduction section 633 and the adhesive tape 514b, it is possible to carry out bonding with respect to the fourth layer 624 in a flat manner while preventing the fifth layer 625 and the sixth layer 262 that are laminated and integrated from slanting. Therefore, even if below-described plating is carried out with copper 517, the copper does not leak.

Under this condition, an internal periphery of each of the through holes 515 and 516 is plated with copper 517. Further, the conduction section 633 of the fourth layer 624 is formed so as to cover the through hole 515, so that the copper 517 is provided also on the conduction section 633 which is formed on the fourth layer 624 so as to be exposed at the inside of the through hole 515. Further, the conduction section 634 provided through the third layer 623 and the fourth layer 624 is formed so as to cover the through hole 516, so that the copper 517 is provided also on the conduction section 634 provided through the third layer 623 and the fourth layer 624 so as to be exposed at the inside of the through hole 516. Thus, the rear surface electrodes 518 and 519 each of which serves as an external connection electrode terminal of the light emitting element 600 are formed.

As described above, it is possible to reduce the number of layers of the laminate substrate 606 by making the size of the conduction section 634 of the fourth layer 624 smaller than the size of the through hole 516 and suitably adjusting the thickness of the conduction section 633 and the adhesive tape. Thus, it is possible to reduce the size of the light emitting element 600 and it is possible to reduce the production cost of the light emitting element 600.

As in Embodiment 3, a shape of an opening of the metallic reflecting plate 502 and a shape of an external periphery of the metallic reflecting plate 502 are determined so as to be a shape which allows easy etching or are determined according to design. For example, FIG. 20 illustrates the metallic reflecting plate 641 having another peripheral shape. FIG. 21 illustrates the metallic reflecting plate 642 having another peripheral shape and the opening 643.

Further, in the light emitting element 600, the rear surface electrodes 518 and 519 are finally formed on the rear surface side opposite to the light projecting surface as external connection electrode terminals, but the arrangement is not limited to this. These external connection electrode terminals may be formed on the side of the light projecting surface.

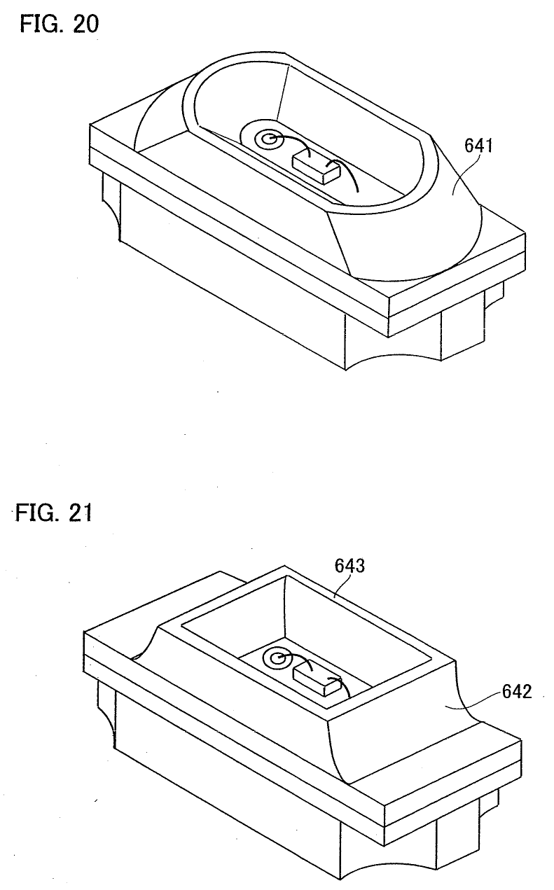

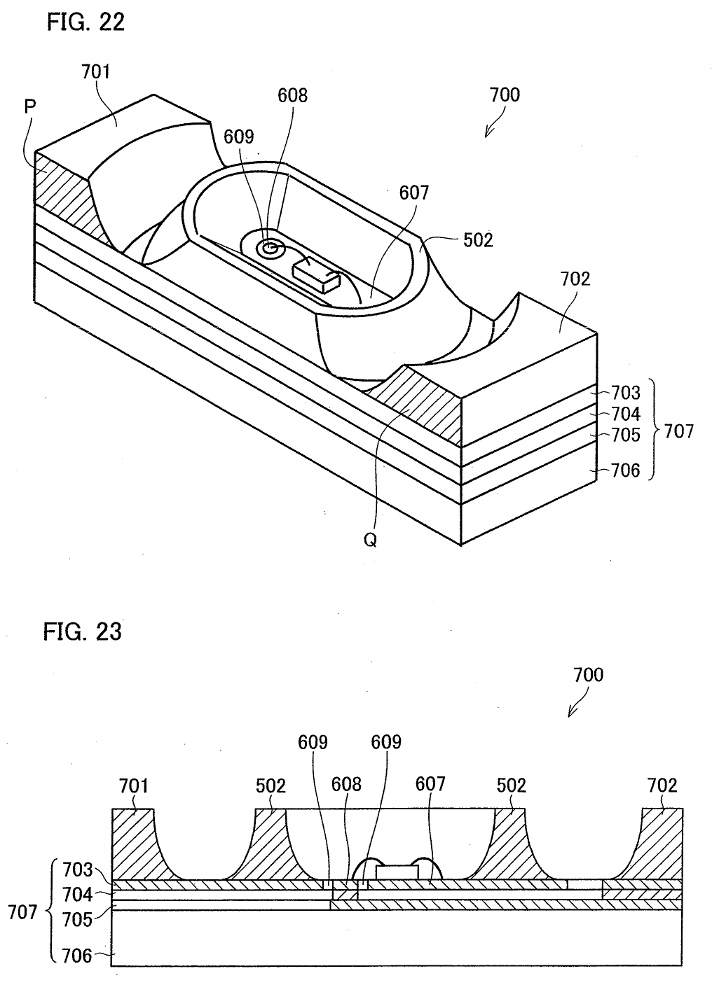

That is, as illustrated in FIGS. 22 and 23, external connection electrodes 701 and 702 are integrated to the metallic reflecting plate 502. As a result, areas P and Q which are respectively parts of side faces of the external connection electrodes 701 and 702 can be used as soldered surfaces, so that it is possible to improve the wettability of solder.

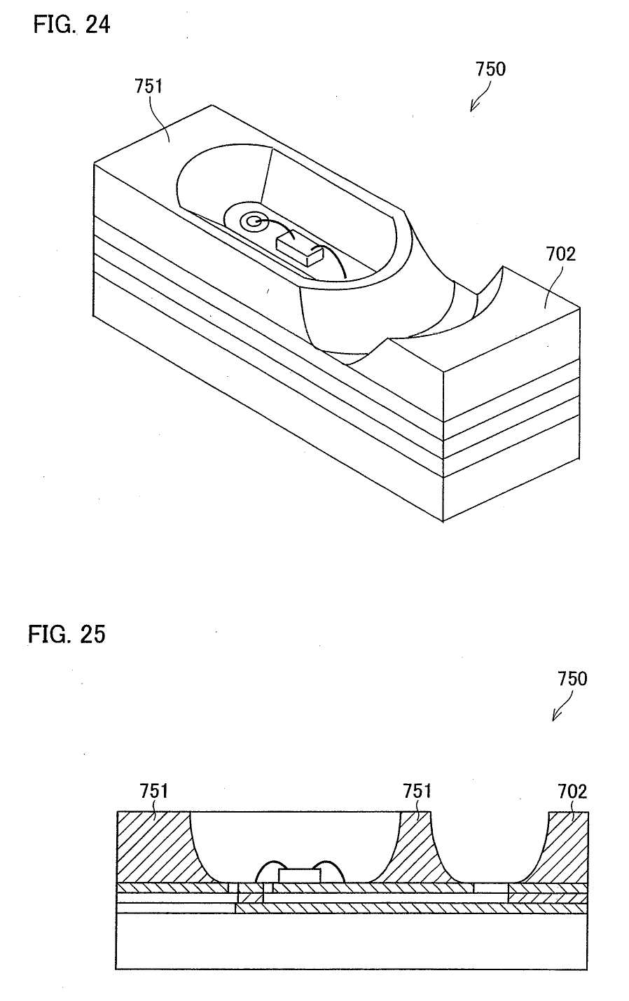

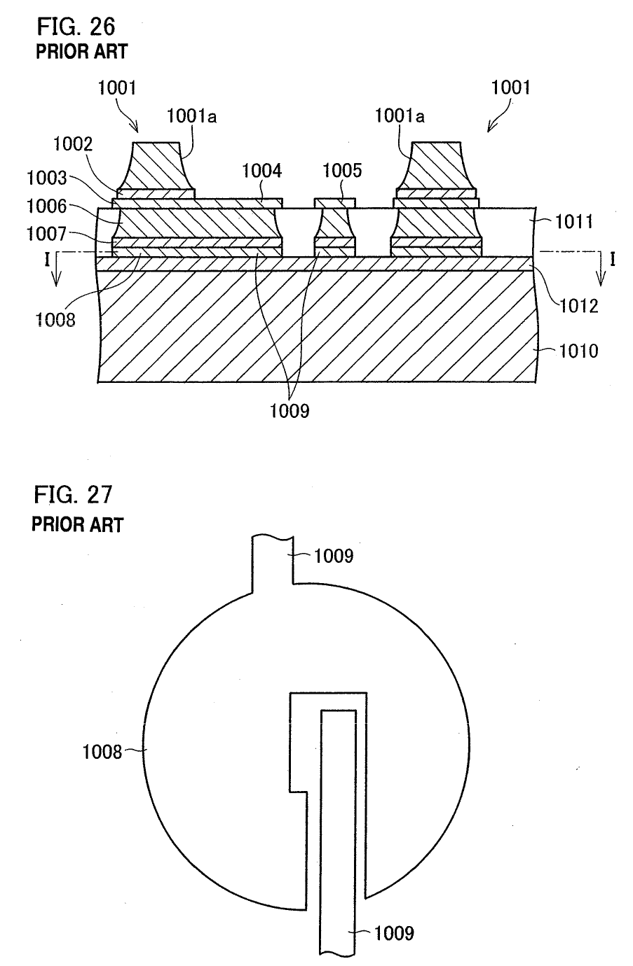

However, formation of the external connection electrodes 701 and 702 causes the package size of the light emitting element to be larger. In contrast, an arrangement in which the package size of the light emitting element is made smaller is illustrated in FIGS. 24 and 25.

In an arrangement illustrated in each of FIGS. 24 and 25, an integrated external connection electrode 751 is provided by integrating the metallic reflecting plate 502 to the external connection electrode 701, thereby making the package size of the light emitting element smaller.

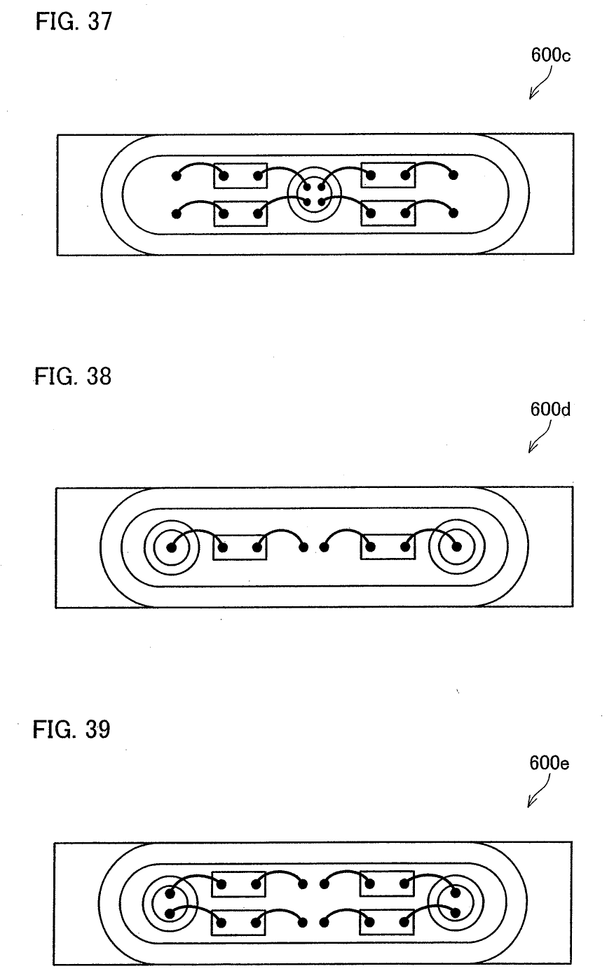

Note that, the foregoing description explained the arrangement in which a single LED chip 501 is provided, but the present embodiment is not limited to this. As in a light emitting element 600a of FIG. 35, a light emitting element 600b of FIG. 36, and a light emitting element 600c of FIG. 37, it may be so arranged that two or more LED chips are provided.

In each of the arrangements of FIGS. 34 to 37, a potential of the island electrode 608 is different from a potential of another area including the die-bond area/electrode section 607 surrounded by the metallic reflecting plate 502.

A plurality of LED chips are suitably disposed and provided on a single light emitting element in this manner, so that it is possible to enhance intensity of projected light without making the structure of the element larger. Note that, the number of LED chips provided is not limited to four. In an arrangement having a large element substrate, it is possible to further increase the number of LED chips provided.

### Embodiment 5

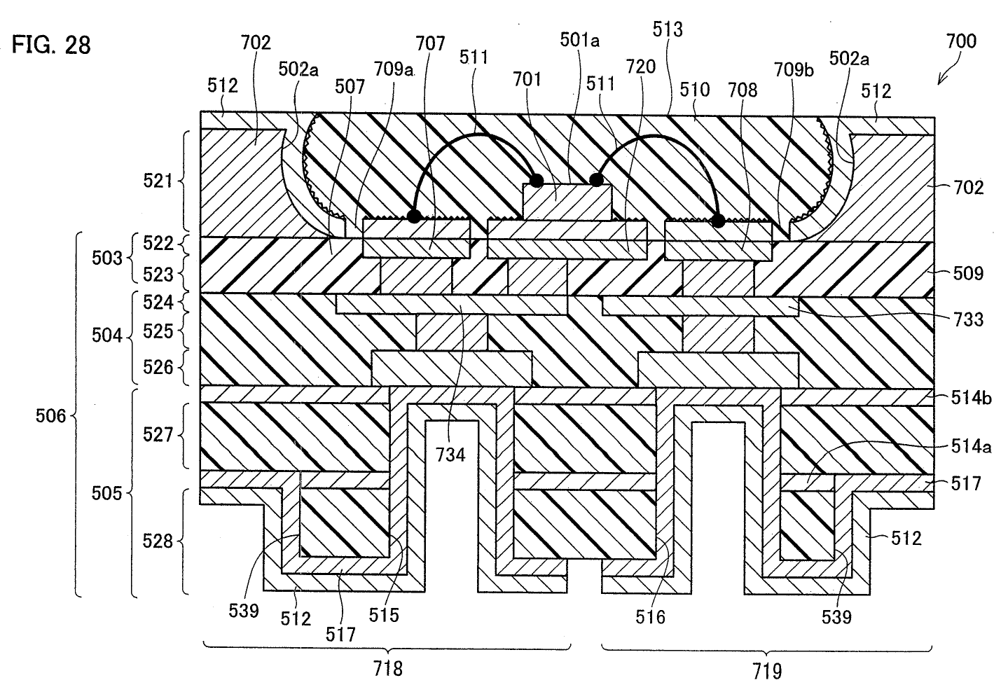

The following description will explain still another embodiment of the present invention with reference to FIGS. 28, 29, 38 to 42. Note that, the same reference numerals are given to members identical with the members illustrated in the aforementioned embodiments and drawings, and descriptions thereof are omitted.

A light emitting element 700 according to the present embodiment includes a laminate substrate arranged in the same manner as in the laminate substrate 506 of the light emitting element 500 of Embodiment 3.

As illustrated in FIG. 28, each of electrodes connected to an LED chip 701 as electrode terminals each of which supplies a driving current to the LED chip 702 is an island electrode. That is, the arrangement is different from Embodiment 3 in that: a metallic reflecting plate 702 which reflects light emitted from the LED chip 701 and guides the light to the light projecting surface 513 provided in a light projecting direction is electrically insulated from any electrodes each of which supplies a driving current to the LED chip 701.

In the present embodiment, a cathode electrode of the LED chip 501 is connected to a first island electrode (first metallic portion) 707 and an anode electrode of the LED chip 701 is connected to a second island electrode (second metallic portion) 708.

The first island electrode 707 is electrically insulated from other portions, which are in an area positioned at the installation surface and surrounded by the metallic reflecting plate 702, by a first insulating section 709a formed in a circular manner so as to surround an external periphery of the first island electrode 707.

The second island electrode 708 is electrically insulated from aforementioned other portions of the area by a second insulating section 709b formed in a circular manner so as to surround an external periphery of the second island electrode 708 as in the island electrode 508 of Embodiment 3.

Further, an installation surface metallic reflecting film 720 is formed on an entire part of the aforementioned area except for an area where the first insulating section 709a is formed and an area where the second insulating section 709b is formed.

As in Embodiments 3 and 4, the light emitting element 700 is arranged so that: the metallic reflecting plate 702 for reflecting light emitted from the LED chip 701 and guides the light to the light projecting surface 513 provided in the light projecting direction is formed so as to be in a direction in which the LED chip 701 emits light and so as to surround an entire periphery of the LED chip 701. Thus, light irradiated from the LED chip 701 is reflected by the metallic reflecting plate 702, thereby efficiently guiding the light to the light projecting surface 513. Thus, it is possible to suppress light leakage from the side face of the element, thereby enhancing intensity of light projected from the light projecting surface 513.

Further, the installation surface metallic reflecting film 720 intervenes between the first insulating section 709a and the metallic reflecting plate 702 and between the second insulating section 709b and the metallic reflecting plate 702. Thus, even if positional deviation occurs in the step of forming the metallic reflecting plate 702, the positional deviation can be covered by the installation surface metallic reflecting film 720, so that a shape and an area size of each of the first insulating section 709a and the second insulating section 709b are not influenced by the positional deviation. Thus, even if the area size of each of the first insulating section 709a and the second insulating section 709b that are formed on the installation surface of the substrate is reduced, it is possible to surely insulate the first insulating section 709a and the second insulating section 709b. Thus, according to the foregoing arrangement, it is possible to reduce the area size of each of the first insulating section 709a and the second insulating section 709b that are formed on the installation surface, so that the installation surface metallic reflecting film 720 surrounding the first island electrode 707 and the second island electrode 708 via the insulating sections can be formed on a larger area. Thus, it is possible to effectively prevent light leakage from the second insulating section 709b, so that light moving from the metallic reflecting plate 702 toward the substrate can be efficiently reflected toward the light projecting surface 513 by the installation metallic reflecting film. As a result, it is possible to more efficiently utilize light and more efficiently radiate heat.

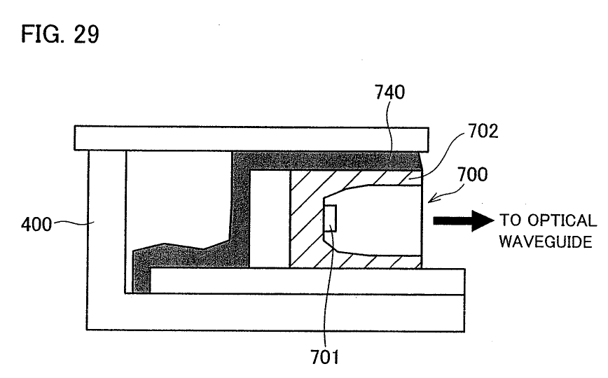

Further, as described above, the metallic reflecting plate 702 according to the present embodiment is electrically insulated from both the first island electrode 707 and the second island electrode 708. Thus, as illustrated in FIG. 29, in providing the light emitting element 700 onto a housing 400 provided as a member of an electronic device such as a mobile phone and made of metal such as aluminum, the metallic reflecting plate 702 has no potential. Thus, the light emitting element 700 can be provided, not via a resin or the like which less radiates heat, with the metallic reflecting plate 702 in contact with the housing 400. Thus, heat generated at the metallic reflecting plate 702 can be efficiently radiated outward from the light emitting element 700.

Further, as illustrated in FIG. 29, the light emitting element 700 according to the present embodiment is arranged so that: a heat radiating sheet 740 for radiating heat generated at the metallic reflecting plate 702 outward is formed on at least a part of an external periphery of the metallic reflecting plate 702 and on an external periphery of the element so as to be positioned also on a bottom of the laminate substrate 506.

Thus, heat generated at the metallic reflecting plate 702 can be more efficiently radiated outward via the heat radiating sheet 740.

As the heat radiating sheet 740, it is desirable to use a conductive material which can favorably radiate heat. As described above, the metallic reflecting plate 702 according to the present embodiment is insulated from other members, so that the metallic reflecting plate 704 has no potential. Thus, this raises no problem such as short circuit, so that it is possible to efficiently radiate heat, generated at the metallic reflecting plate 702, outward via the heat radiating sheet made of conductive material which can favorably radiate heat. Note that, as the conductive material, it is preferable to use graphite which can favorably radiate heat.

Further, the installation surface metallic reflecting film 720 is formed on the installation surface so as to be positioned at the outside of the first insulating section 709a and the second insulating section 709b. Thus, out of light emitted from the LED chip 701, a large part of light moving toward the substrate can be reflected by the installation surface metallic reflecting film 720, so that the light can be guided to the light projecting surface 513. Thus, it is possible to decrease an amount of light absorbed by the substrate and an amount of light which passes through the substrate and leaks from the rear surface side to the outside of the light emitting element 700. Thus, it is possible to enhance intensity of light projected from the light projecting surface.

The light emitting element 700 is arranged so that: a rear surface electrode (first rear surface electrode) 718 and a rear surface electrode (second rear surface electrode) 719 which are respectively connected to the first island electrode 707 and the second island electrode 708 are provided, as external connection electrode terminals, on the rear surface opposite to the installation surface of the laminate substrate 506.

In this manner, the rear surface electrodes 718 and 719 are provided on the rear surface side of the installation substrate 506 as the external connection electrode terminals, it is possible to decrease an amount of light which passes through the installation substrate 506 and leaks from the rear surface side to the outside of the light emitting element 700.

However, the present embodiment is not limited to this, and it may be so arranged that these external connection electrode terminals are provided on the side of the light projecting surface.

Further, as illustrated in FIG. 28, the rear surface electrode 718 is formed so as to cover an entire area corresponding, in a laminating direction, to an area where the first insulating section 709a is formed, and the rear surface electrode 719 is formed so as to cover an entire area corresponding, in the laminating direction, to an area where the first insulating section 709b is formed.

Thus, out of light emitted from the LED chip 701, light moving from the installation surface into the substrate can be effectively prevented from leaking from the rear surface side after passing through the first insulating section 709a and the second insulating section 709b of the laminate substrate 506 to the outside of the light emitting element. Thus, it is possible to enhance intensity of light projected from the light projecting surface.

Further, as in Embodiment 3, the rear surface electrode 718 is electrically connected to the first island electrode 707 via the conduction section 734 formed on the fourth layer 524, and the rear surface electrode 719 is electrically connected to the second island electrode 708 via the conduction section 733 formed on the fourth layer 524. In the present embodiment, the conduction section 734 is formed so as to cover an entire area corresponding, in the laminating direction, to an area where the first insulating section 709a is formed, and the conduction section 733 is formed so as to cover an entire area corresponding, in the laminating direction, to an area where the first insulating section 709b is formed.

In this manner, the first insulating section 709a and the second insulating section 709b are formed so as to respectively cover the conduction sections 734 and 733 which are disposed nearer to the substrate installation surface than the rear surface electrodes 718 and 719, thereby more effectively decreasing an amount of light which passes through the first insulating section 709a and the second insulating section 709b and leaks from the rear surface side to the outside of the element.

Further, as in the aforementioned embodiments and below-described Embodiments 6 and 7, the light emitting element 700 is arranged so that: an internal periphery of the metallic reflecting plate has edges in the light projecting direction of the LED chip 701 so that the edges constitute an opening, as the light projecting surface 513, at an uppermost level of a space formed by the installation surface and the metallic reflecting plate. In addition, the translucent sealant 510 is provided so that the space is filled with the translucent sealant 510, and the space has such a shape that a lateral width at an intermediate level between the light projecting surface 513 and the installation surface is larger than a maximum lateral width of the light projecting surface 513 and the space becomes narrower from the intermediate level to the opening.

As a sealing resin of the translucent sealant 510, silicone or the like which has less adhesive than epoxy or the like is used. Thus, by forming the metallic reflecting plate 702 so that the opening which serves as the light projecting surface 513 is made narrower in the foregoing manner, it is possible to enhance adhesiveness with respect to the internal periphery of the metallic reflecting plate 702 of the translucent sealant 510, so that it is possible to suppress coming-off of the translucent sealant 510. As a result, it is possible to protect the internal periphery of the metallic reflecting plate 702 plated with silver by use of a resin sealant under a stable condition.

Further, it is preferable that: at least the internal periphery of the metallic reflecting plate 702 which internal periphery is in contact with the translucent sealant 510 has a bumpy surface so as to increase an area which is in contact with the translucent sealant 510 as illustrated in FIG. 28. Thus, it is possible to more firmly bond the translucent sealant 510 to the internal periphery of the metallic reflecting plate 510, so that it is possible to suppress coming-off of the translucent sealant 510. As a result, the internal periphery of the metallic reflecting plate 702 plated with silver can be protected by the resin sealant 510 under a stable condition.

As materials of the first island electrode 707, the second island electrode 708, the metallic reflecting plate 702, and the installation surface metallic reflecting film 720 which constitute the light emitting element 700 according to the present embodiment, it is possible to use copper, silver, gold, or nickel which is highly reflective. Such material allows light emitted from the LED chip 701 to be efficiently guided to the light projecting surface 531. Thus, the foregoing material is preferable.

The foregoing description explained the arrangement having a single island electrode 608, but the present embodiment is not limited to this. It may be so arranged that a plurality of island electrodes are provided as in a light emitting element 600d illustrated in FIG. 38 and a light emitting element 600e illustrated in FIG. 39.

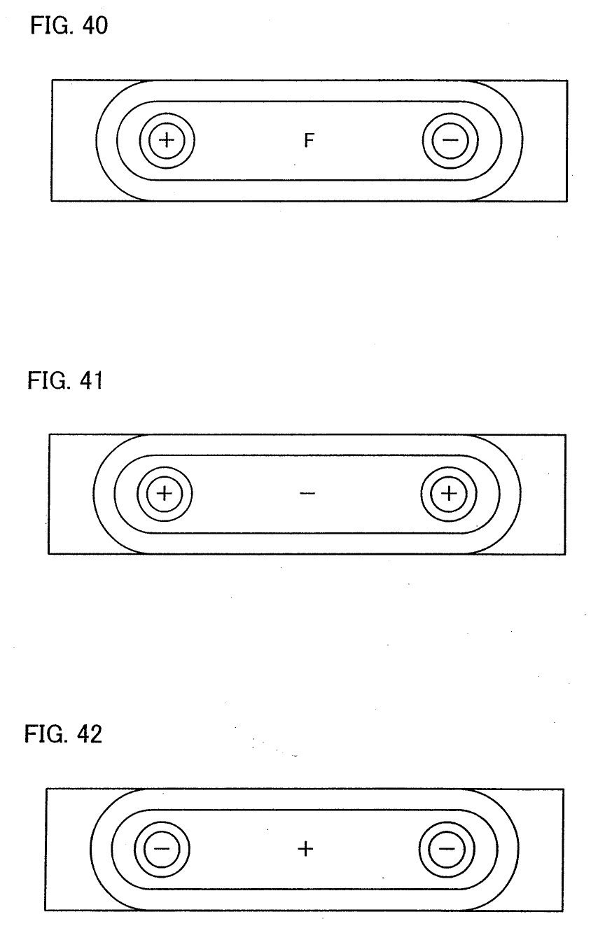

In case where two LED chips 501 are serially connected in the arrangement of FIG. 38, and in case where LED chip groups each having two LED chips connected in parallel are serially connected in the arrangement of FIG. 39, as illustrated in FIG. 40, two island electrodes are electrically connected respectively to the rear surface electrodes different from each other so that one of the island electrodes has an anode potential and the other has a cathode potential. While, in case of serially connecting two chips in the arrangement of FIG. 38 and in case of connecting four LED chips 501 in parallel as illustrated in FIG. 40, two island electrodes are identical with each other in a potential as illustrated in FIG. 41 or 42. In this case, each of the two island electrodes is formed by disposing a conduction section of each layer in the laminate substrate so as to be electrically connected to one of the rear surface electrodes (not shown).

Note that, in FIGS. 40 to 42, + and − respectively represent an anode (+) and a cathode (+) in the island electrode and the die-bond area/electrode section. F represents a floating potential without dropping a potential anywhere. The reference signs are used in the same way as in following embodiments.

### Embodiment 6

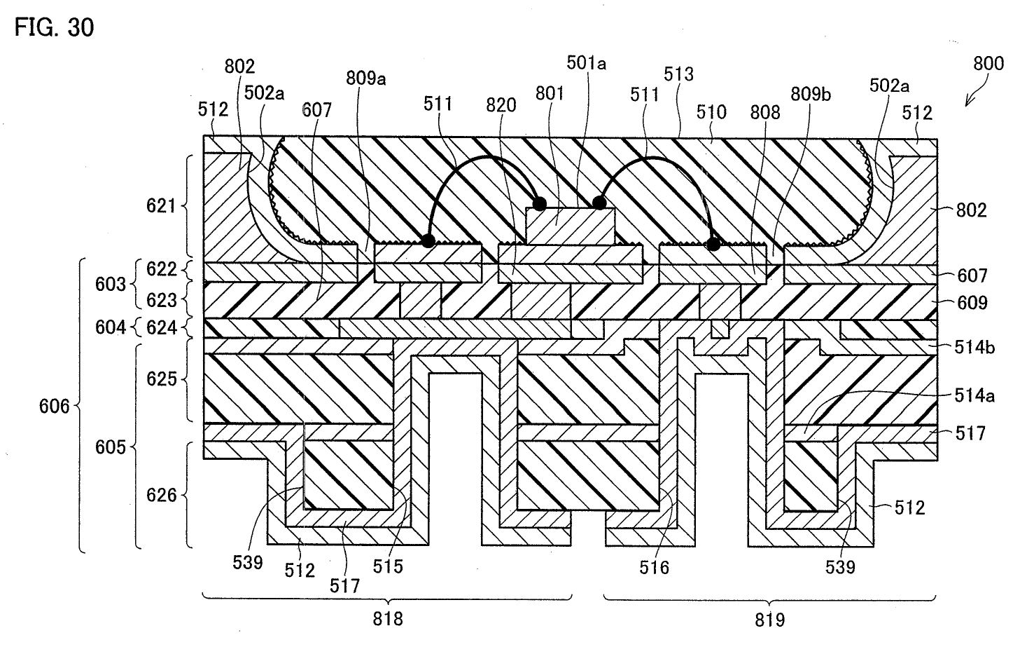

The following description will explain still another embodiment with reference to FIGS. 30, 31, 33, 40, and 43 to 45. Note that, for convenience in description, the same reference numerals are given to members identical to the members illustrated in the aforementioned embodiment and drawings, and descriptions thereof are omitted.

A light emitting element 800 according to the present embodiment includes a laminate substrate arranged in the same manner as the laminate substrate 606 of the light emitting element 600 of Embodiment 4.

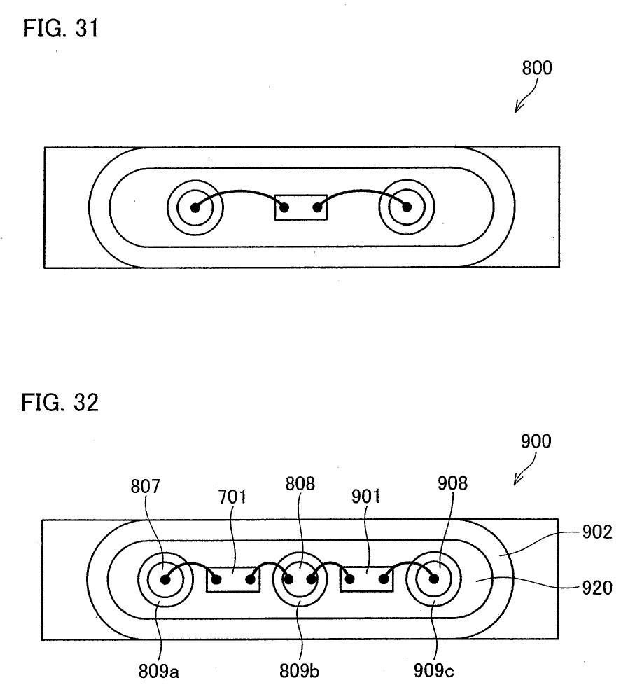

As illustrated in FIGS. 30 and 31, as in the light emitting element 700 of Embodiment 5, the light emitting element 800 according to the present embodiment is arranged so that each of electrodes connected to the LED chip 801 as electrode terminals for supplying driving currents to the LED chip 701 is an island electrode. Further, the present embodiment is different from Embodiment 4 in that: a metallic reflecting plate 802 for reflecting light emitted from the LED chip 701 so as to guide the light to the light projecting surface 513 is electrically insulated from each electrode for supplying a driving current to the LED chip 801.

In the present embodiment, a cathode electrode of the LED chip 801 is connected to a first island electrode (first metallic portion) 807 and an anode electrode of the LED chip 801 is connected to a second island electrode (second metallic portion) 808.

The first island electrode 807 is electrically insulated from other portions, which are in an area positioned at the installation surface and surrounded by the metallic reflecting plate 802, by the first insulating section 709a.

The second island electrode 808 is, as in the island electrode 608 of Embodiment 4, electrically insulated from other portions of the area by the second insulating section 809b formed in a circular manner so as to surround an external periphery of the second island electrode 808.

Further, an installation surface metallic reflecting film 820 is formed on an entire part of the area except for an area where the first insulating section 809a is formed and an area where the second insulating section 809b is formed.

As in the aforementioned embodiments 3 to 5, the light emitting element 800 is arranged so that: the metallic reflecting plate 802 for reflecting light emitted from the LED chip 701 and for guiding the light to the light projecting surface 513 formed in the light projecting direction is formed so as to be in a direction in which the LED chip 701 emits light and so as to surround an entire periphery of the LED chip 701. Thus, light irradiated from the LED chip 701 is reflected by the metallic reflecting plate 802, thereby efficiently guiding the light to the light projecting surface 513. Thus, it is possible to suppress light leakage from the side face of the element, thereby enhancing intensity of light projected from the light projecting surface 513.

Further, as illustrated in FIG. 30, the light emitting element 800 of the present embodiment is arranged so that the metallic reflecting plate 802 is integrated to the installation surface metallic reflecting film 820.

Thus, it is possible to form the installation surface metallic reflecting film 820 on a large area of the installation surface. As a result, by providing metal on a larger area of the entire element, it is possible to realize a light emitting element which is excellent in its heat radiating property. Further, heat generated at the time of light emission of the LED chip 701 is transmitted toward the surface of the laminate substrate 606 to which the installation surface metallic reflecting film 820 is integrated, and the heat is effectively radiated toward the rear surface. As a result, it is possible to suppress deterioration caused by heat, so that it is possible to realize a light emitting element having high reliability over the long term.

Further, in the present embodiment, the metallic reflecting plate 802 is electrically insulated from both the first island electrode 807 and the second island electrode 808 as described above. Thus, as illustrated in FIG. 29, in providing the light emitting element 800 onto the housing 400 provided as a member of an electronic device such as a mobile phone and made of metal such as aluminum, the metallic reflecting plate 802 has no potential. Thus, the light emitting element 800 can be provided, not via a resin or the like which less radiates heat, with the metallic reflecting plate 802 in contact with the housing 400. Thus, heat generated at the metallic reflecting plate 802 can be efficiently radiated outward from the light emitting element 800.

As in the light emitting element 700 of Embodiment 5, the light emitting element 800 according to the present embodiment is arranged so that: a heat radiating sheet 740 for outward radiating heat generated at the metallic reflecting plate 802 is formed on at least a part of an external periphery of the metallic reflecting plate 802 and on an external periphery of the element so as to be positioned also on a bottom of the laminate substrate 606.

Thus, heat generated at the metallic reflecting plate 802 can be more efficiently radiated outward via the heat radiating sheet 740.

As the heat radiating sheet 740, it is desirable to use a conductive material which can favorably radiate heat. As described above, the metallic reflecting plate 802 according to the present embodiment is insulated from other members, so that the metallic reflecting plate 804 has no potential. Thus, this raises no problem such as short circuit, so that it is possible to efficiently radiate heat, generated at the metallic reflecting plate 802, to the outside via the heat radiating sheet made of conductive material which can favorably radiate heat. Note that, as the conductive material, it is preferable to use graphite which can favorably radiate heat.

Further, the conductive heat radiating sheet is grounded with it insulated from the rear surface electrode in the housing, so that the installation surface metallic reflecting film where the metallic reflecting plate and an LED chip electrically and thermally connected to the metallic reflecting plate are formed does not have any floating potential. As a result, it is possible to prevent such disadvantage that: the LED chip has unnecessary surge, which results in breakage or improper operation of the light emitting element.

Further, in the present embodiment, unlike Embodiment 5, each of the first insulating section 809a and the second insulating section 809b on the installation surface is formed in a circular manner, so that it is possible to insulate each electrode from other portions with a smaller area.

Thus, as illustrated in FIGS. 30 and 31, the installation surface metallic reflecting film 820 can be formed on an entire area surrounded by the metallic reflecting plate 802 so as to, via the insulating sections 809a and 809b, surround the first island electrode 807 and the second island electrode 808. Thus, out of light emitted from the LED chip 801, a large part of light moving toward the substrate is reflected by the installation surface metallic reflecting film 820, so that the light can be guided to the light projecting surface 513 provided in a light projecting direction. As a result, it is possible to more effectively decrease an amount of light absorbed by the laminate substrate 606 and an amount of light which passes through the laminate substrate 607 and leaks from the rear surface side to the outside of the light emitting element 800. Thus, it is possible to further enhance intensity of light projected from the light projecting surface compared with the arrangement of Embodiment 5.

The light emitting element 800 is arranged so that: a rear surface electrode (first rear surface electrode) 818 and a rear surface electrode (second rear surface electrode) 819 which are respectively connected to the first island electrode 807 and the second island electrode 808 are provided, as external connection electrode terminals, on the rear surface opposite to the installation surface of the laminate substrate 606.

In this manner, the rear surface electrodes 818 and 919 are provided on the rear surface side of the installation substrate 606 as the external connection electrode terminals, so that it is possible to decrease an amount of light which passes through the installation substrate 606 and leaks from the rear surface side to the outside of the light emitting element 800.

However, the present embodiment is not limited to this, and it may be so arranged that these external connection electrode terminals are provided on the side of the light projecting surface.

Further, as illustrated in FIG. 30, the rear surface electrode 818 is formed so as to cover an entire area corresponding, in a laminating direction, to an area where the first insulating section 809a is formed, and the rear surface electrode 819 is formed so as to cover an entire area corresponding, in the laminating direction, to an area where the second insulating section 809b is formed.

Thus, out of light emitted from the LED chip 801, light moving from the installation surface into the substrate can be effectively prevented from leaking from the rear surface side after passing through the first insulating section 809a and the second insulating section 809b of the laminate substrate 606 to the outside of the light emitting element. Thus, it is possible to enhance intensity of light projected from the light projecting surface.

As materials of the first island electrode 807, the second island electrode 808, the metallic reflecting plate 802, and the installation surface metallic reflecting film 820 which constitute the light emitting element according to the present embodiment, it is possible to use copper, silver, gold, or nickel which is highly reflective. Such material allows light emitted from the LED chip 801 to be efficiently guided to the light projecting surface 531. Thus, the foregoing material is preferable.

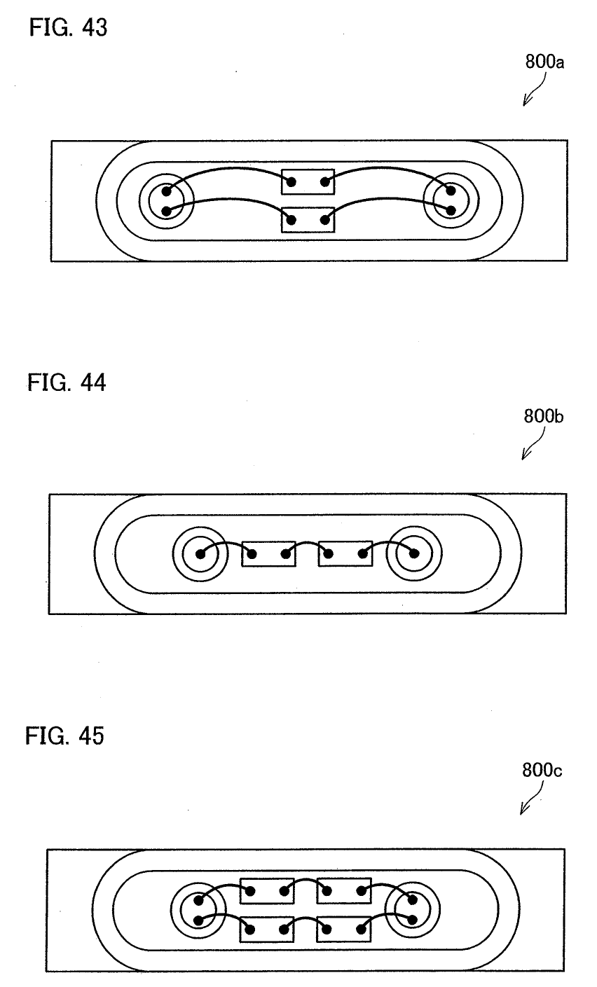

The foregoing description explained the arrangement having a single LED chip 701, but the present embodiment is not limited to this. It may be so arranged that two or more LED chips are provided as in a light emitting element 800a of FIG. 43, a light emitting element 800b of FIG. 44, and a light emitting element 800c of FIG. 45.

Further, in case where two LED chips are connected in series/in parallel as illustrated in FIGS. 43 and 44, in case where LED chip groups each having two LED chips connected in parallel are connected in series as illustrated in FIG. 45, the two island electrodes are arranged so that one of the island electrodes has an anode potential and the other has a cathode potential.

In this manner, a plurality of LED chips are suitably disposed and provided in a single light emitting element, so that it is possible to enhance intensity of emitted light without increasing the size of the structure of the element. Note that, an upper limit of the number of the LED chips provided is not four. In an arrangement having a large element substrate, it is possible to further increase the number of LED chips provided.

### Embodiment 7

The following description will explain still another embodiment with reference to FIGS. 32 and 46 to 48. Note that, for convenience in description, the same reference numerals are given to members identical to the members illustrated in the aforementioned embodiments and drawings, and descriptions thereof are omitted.

Each of the aforementioned embodiments described the light emitting element having a single LED chip, but the light emitting element of the present invention is not limited to this. It may be so arranged that a plurality of LED chips are provided.

With reference to FIG. 23, the following description explains a case where Embodiment 6 is arranged so that a plurality of LED chips are provided.

As illustrated in FIG. 32, a light emitting element 900 according to the present embodiment includes not only the LED chip 701 but also an LED chip (second LED chip) 901.

As in the light emitting element 800, the light emitting element 900 is arranged so that a cathode electrode of the LED chip 701 is connected to the first island electrode (first metallic portion) 807 and an anode electrode of the LED chip 701 is connected to the second island electrode (second metallic portion) 808.

In the present embodiment, the second island electrode 808 serving as an electrode terminal for supplying a driving current to the LED chip 701 functions also as a power source terminal for supplying a driving current to the LED chip 901. That is, the second island electrode 808 is connected also to an anode electrode of the LED chip 901. Further, the light emitting element 900 includes a third island electrode 908 which serves as an electrode terminal connected to the anode electrode of the LED chip 901 and electrically connected to the first island electrode via the conduction section in the laminate substrate, and the metallic reflecting plate 802 is electrically insulated from all the first to third island electrodes.

As in the light emitting element 800 of Embodiment 6, by the first insulating section 809a formed in a circular manner so as to surround an external periphery of the first island electrode 807, the first island electrode 807 is electrically insulated from other portions which are provided on the installation surface and are positioned at an area surrounded by the metallic reflecting plate 802. Further, as in the island electrode 608 of Embodiment 4 and the island electrode 808 of Embodiment 6, the second island electrode 808 is electrically insulated from other portions of the area by the second insulating section 809b formed in a circular manner so as to surround an external periphery of the second island electrode 808.

Further, in the present embodiment, also the third island electrode (third electrode section) 908 is electrically insulated from other portions of the area by the third insulating section 909c formed in a circular manner so as to surround an external periphery of the third island electrode 908.

That is, the light emitting element 900 of the present embodiment includes two LED chips 701 and 901 provided in a single circuit system. Thus, it is possible to obtain light intensity twice as high as that of conventional arrangement without increasing the size of the element.

Further, as in Embodiment 6, the present embodiment is arranged so that each of the first to third insulating sections is formed in a circular shape on the installation surface. Thus, it is possible to insulate each electrode from other portions with a smaller area.

Thus, as illustrated in FIG. 32, the installation surface metallic reflecting film 920 can be formed on an entire part of an area, which is in the installation surface and is surrounded by the metallic reflecting plate 802, so as to respectively surround the first to third island electrodes 807 to 809 via the first to third insulating sections. Thus, out of light emitted from the LED chips 701 and 901, a large part of light moving toward the substrate is reflected by the installation surface metallic reflecting plate 920, so that the light can be guided to the light projecting surface provided in a light projecting direction. Thus, it is possible to more effectively decrease an amount of light absorbed by the laminate substrate and an amount of light which passes through the laminate substrate 607 and leaks from the rear surface side to the outside of the light emitting element 900.

As in Embodiments 3 to 8, the light emitting element 900 is arranged so that: the metallic reflecting plate 802 for reflecting light emitted from the LED chips 701 and 901 and for guiding the light to the light projecting surface 513 is provided upright in the light projecting direction of each of the LED chips 701 and 901 so as to surround an entire periphery of each of the LED chips 701 and 901. Thus, light irradiated from the LED chips 701 and 901 is reflected by the metallic reflecting plate 802, thereby efficiently guiding the light to the light projecting surface 513. As a result, it is possible to suppress light leakage from the side face of the element, thereby enhancing intensity of light projected from the light projecting surface 513.

Further, as illustrated in FIG. 32, the light emitting element 900 of the present embodiment is arranged so that the metallic reflecting plate 802 is integrated to the installation surface metallic reflecting film 920.

Thus, it is possible to form the installation surface metallic reflecting film 920 on a larger area of the installation surface. By providing metal on a larger area of the entire element, it is possible to realize a light emitting element which is excellent in its heat radiating property. Further, heat generated at the time of light emission of the LED chips 701 and 901 is transmitted toward the surface of the laminate substrate 606 to which the installation surface metallic reflecting film 920 is integrated, and the heat is effectively radiated toward the rear surface. As a result, it is possible to suppress deterioration caused by heat, so that it is possible to realize a light emitting element having high reliability over the long term.

Further, as described above, the metallic reflecting plate 802 according to the present embodiment is electrically insulated from all of the first island electrode 807, the second island electrode 808, and the third island electrode 908. Thus, as illustrated in FIG. 29, in providing the light emitting element 900 onto a housing 400 provided as a member of an electronic device such as a mobile phone and made of metal such as aluminum, the metallic reflecting plate 802 has no potential. Thus, the light emitting element 900 can be provided, not via a resin or the like which less radiates heat, with the metallic reflecting plate 802 in contact with the housing 400. Thus, heat generated at the metallic reflecting plate 802 can be efficiently radiated outward from the light emitting element 900.

As in the light emitting element 700 of Embodiment 5 and the light emitting element 800 of Embodiment 6, the light emitting element 900 according to the present embodiment is arranged so that: a heat radiating sheet 740 for outward radiating heat generated at the metallic reflecting plate 802 is formed on at least a part of an external periphery of the metallic reflecting plate 802 and on an external periphery of the element so as to be positioned also on a bottom of the laminate substrate 606.

Thus, heat generated at the metallic reflecting plate 802 can be more efficiently radiated outward via the heat radiating sheet 740. As a result, it is possible to realize the light emitting element 900 having high reliability over the long term.

As the heat radiating sheet 740, it is desirable to use a conductive material which can favorably radiate heat. As described above, the metallic reflecting plate 802 according to the present embodiment is insulated from other members, so that the metallic reflecting plate 804 has no potential. Thus, this raises no problem such as short circuit, so that it is possible to efficiently radiate heat, generated at the metallic reflecting plate 802, outward via the heat radiating sheet made of conductive material which can favorably radiate heat. Note that, as the conductive material, it is preferable to use graphite which can favorably radiate heat.

Further, the conductive heat radiating sheet is grounded with it insulated from the rear surface electrode in the housing, so that the installation surface metallic reflecting film where the metallic reflecting plate and an LED chip electrically and thermally connected to the metallic reflecting plate are formed does not have any floating potential. As a result, it is possible to prevent such disadvantage that: the LED chip has unnecessary surge, which results in breakage or improper operation of the light emitting element.

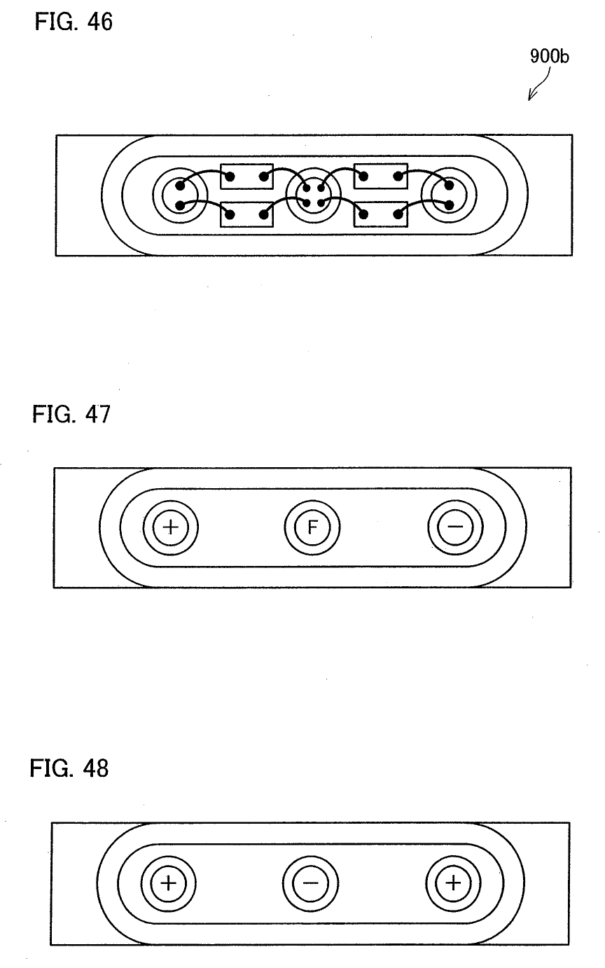

Note that, the foregoing description explained the arrangement in which two LED chips 801 are provided, but the present embodiment is not limited to this, and it may be so arranged that four LED chips are provided as in a light emitting element 900b illustrated in FIG. 46.

In case of serially connecting two LED chips 801 in the arrangement of FIG. 32, in case of serially connecting LED chip groups each having two LED chips connected in parallel in the arrangement of FIG. 46, as illustrated in FIG. 47, the two island electrodes are electrically connected respectively to the rear surface electrodes different from each other so that one of the island electrodes has an anode potential and the other has a cathode potential. While, in case of serially connecting two LED chips 801 in the arrangement of FIG. 32 and in case of connecting four LED chips 801 in parallel as illustrated in FIG. 46, two island electrodes are identical with each other in a potential as illustrated in FIG. 41 or 42. In this case, each of the two island electrodes is formed by disposing a conduction section of each layer in the laminate substrate so as to be electrically connected to one of the rear surface electrodes (not shown).

In this manner, a plurality of LED chips are suitably disposed and provided in a single light emitting element, so that it is possible to enhance intensity of emitted light without increasing the size of the structure of the element. Note that, an upper limit of the number of the LED chips provided is not four. In an arrangement having a large element substrate, it is possible to further increase the number of LED chips provided.

Note that, the foregoing description explained the arrangement in which: in providing the installation surface metallic reflecting film 820 having the LED chip onto the housing 400 provided as a member of an electric device such as a mobile phone and made of aluminum or the like, no potential floats by grounding via the conductive sheet, and the arrangement can prevent malfunction or breakage of the light emitting element which caused by surge. However, without adopting such technique, it is possible to realize the same effect by arranging the laminate substrate of FIG. 32 as follows: as illustrated in FIG. 33, the conduction section of each layer in the laminate substrate is disposed so that the installation surface metallic reflecting film is electrically and thermally connected to a third rear surface electrode insulated from the first and second rear surface electrodes which are respectively connected to the anode and cathode of the external power source. Further, according to the example, it is possible to further improve the heat radiating property of the LED chip 501 via the third rear surface electrode.

This technique is applicable to examples illustrated in FIGS. 31 and 43 to 46 of the aforementioned embodiments in the same manner.

As described above, each of the light emitting elements described in the aforementioned embodiments highly efficiently project light with less light leakage and has high heat radiating property, so that the light emitting element is applicable to a backlight unit having a waveguide provided in the vicinity of the light projecting surface.

That is, by including the light emitting element of the present invention, it is possible to realize a backlight unit which highly efficiently utilizes light and has reliability over a long term.

As described above, a light emitting element according to the present invention includes: a first metallic portion formed on an installation surface of a substrate; a second metallic portion which is insulated from the first metallic portion and is formed on the installation surface; an LED chip which is provided on the first metallic portion so that a light emitting surface is positioned opposite to the installation surface and whose one electrode is connected to the first metallic portion and other electrode is connected to the second metallic portion; a metallic reflecting plate which is provided on sides of the installation surface so as to surround the installation surface; and a translucent sealant with which a space formed by the substrate and the metallic reflecting plate is filled and which has a light projecting surface opposite to the light emitting surface of the LED chip, wherein the first metallic portion is integrated to the metallic reflecting plate, and the second metallic portion has an island shape so that an insulating section formed in an area surrounded by the metallic reflecting plate surrounds the second metallic portion.

It is desirable to efficiently project outward light emitted from the light emitting surface of the LED chip without any light loss at the light projecting surface. However, the LED chip emits light from its light emitting surface in all directions.

Thus, according to the foregoing arrangement, out of light emitted from the light emitting surface of the LED chip in all directions, light emitted in a direction of the light projecting surface of the translucent sealant is projected outward from the light projecting surface without any problem.

While, the installation surface is completely surrounded by the metallic reflecting plate, so that light emitted in a direction of the metallic reflecting plate is projected toward the light projecting surface, without dispersing, through reflection by a surface of the metallic reflecting plate.

However, light emitted from the LED chip does not entirely reach the light projecting surface, and some components of the light move toward the substrate. Thus, if the substrate is constituted of resin, the substrate allows transmission of light due to its translucency. Note that, light leakage from a portion other than the light projecting surface causes the light intensity to drop.

According to the foregoing arrangement, the first metallic portion is integrated to the metallic reflecting plate and is extensively formed on the installation surface surrounded by the metallic reflecting plate so as not to be positioned on the second metallic portion and the insulating section while insulating the first metallic portion and the second metallic portion from each other, thereby increasing an area where the first metallic portion is formed.

Metal reflects light. Even if light moves toward the substrate, the installation surface surrounded by the metallic reflecting plate has a large metallic area, so that light is reflected without transmission through the substrate, thereby increasing light moving toward the light projecting surface.

Thus, the light emitting element of the present invention can suppress light leakage and can enhance intensity of light projected from the light projecting surface. Further, the LED chip is provided on the first metallic portion integrated to the metallic reflecting plate, so that its heat radiating property is excellent.

Further, it is preferable to arrange the light emitting element according to the present invention so that the insulating section is formed in a circular manner on the area surrounded by the metallic reflecting plate so as to be positioned more internally than the first metallic portion.

According to the foregoing arrangement, the insulating section is formed in a circular manner on the area surrounded by the metallic reflecting plate so as to be positioned more internally than the first metallic portion, so that the first metallic portion is extensively formed on the installation surface surrounded by an internal periphery of the metallic reflecting plate so as not to be positioned on the second metallic portion and the insulating section and so as to be entirely in contact with the internal periphery of the metallic reflecting plate. Therefore, the insulating area is smaller, so that it is possible to further suppress the light leakage. Further, the first metallic portion is formed so as to be entirely in contact with the internal periphery of the metallic reflecting plate, so that its heat transmission area increases. Thus, it is possible to further improve the heat radiating property.

Further, it is preferable to arrange the light emitting element of the present invention so that the metallic reflecting plate has an opening corresponding to the light projecting surface so that a lateral width of the opening is smaller than a lateral width at an intermediate level between the opening and a bottom of the installation surface.

According to the foregoing arrangement, the metallic reflecting plate has an opening corresponding to the light projecting surface so that the lateral width of the opening is smaller than the lateral width at the intermediate level between the opening and a bottom of the installation surface, so that it is possible to prevent the translucent sealant with which a space formed by the metallic reflecting plate is filled from coming off from the light emitting element.

Further, it is preferable to arrange the light emitting element of the present invention so that the metallic reflecting plate has an internal periphery whose surface is bumpy.

According to the foregoing arrangement, the metallic reflecting plate has an internal periphery whose surface is bumpy, thereby increasing a contact area between (a) the translucent sealant with which a space formed by the metallic reflecting plate is filled and (b) the metallic reflecting plate. Therefore, it is possible to more firmly bond the translucent sealant to the metallic reflecting plate.

Further, it is preferable to arrange the light emitting element of the present invention so that the substrate has a rear surface which is opposite to the installation surface and has a rear surface electrode connected to the first metallic portion and a rear surface electrode connected to the second metallic portion.

According to the foregoing arrangement, the substrate has a rear surface which is opposite to the installation surface and has a rear surface electrode connected to the first metallic portion and a rear surface electrode connected to the second metallic portion, so that the two rear surface electrodes can be connected to external members. That is, it is possible to allow conduction of the first metallic portion and the second metallic portion.

Further, it is preferable to arrange the light emitting element of the present invention so that at least the rear surface electrode connected to the second metallic portion is formed so as to cover an area where the insulating section is formed.

According to the foregoing arrangement, at least the rear surface electrode connected to the second metallic portion is formed so as to cover an area where the insulating section is formed, so that light passing through the substrate is reflected, thereby preventing the light from leaking to the outside. That is, it is possible to suppress light leakage from the substrate.

Further, it is preferable to arrange the light emitting element of the present invention so that the rear surface electrode is connected to the first metallic portion via at least one conduction section and the rear surface electrode is connected to the second metallic portion via at least one conduction section, and at least one of the conduction sections is formed so as to cover an area where the insulating section is formed.

According to the foregoing arrangement, at least one of the conduction sections provided on the substrate is formed so as to cover the area where the insulating section is formed, so that light which passes through the substrate is reflected, thereby preventing the light from leaking to the outside. That is, it is possible to suppress light leakage from the substrate.

Further, it is preferable to arrange the light emitting element of the present invention so that each of the conduction sections is more internally disposed than side faces of the substrate.

According to the foregoing arrangement, each of the conduction sections is more internally disposed than side faces of the substrate, so that it is possible to prevent occurrence of any burr in dividing light emitting elements by dicing peripheries thereof at the final production step so as to obtain each final light emitting element.

Further, it is preferable to arrange the light emitting element of the present invention so that one of the conduction sections which is insulated from the metallic reflecting plate is more internally disposed than side faces of the substrate.

According to the foregoing arrangement, one of the conduction sections which is insulated from the metallic reflecting plate is more internally disposed than side faces of the substrate, so that it is possible to prevent occurrence of any burr in dividing light emitting elements by dicing peripheries thereof at the final production step so as to obtain each final light emitting element.

Further, one of the conduction sections which is insulated from the metallic reflecting plate is extended to each side face of the substrate, so that it is possible to reflect more light passing through the substrate by extensively forming the conduction section.

Further, a method according to the present invention for producing a light emitting element which includes: a first metallic portion formed on an installation surface of a substrate; a second metallic portion which is insulated from the first metallic portion and is formed on the installation surface; an LED chip which is provided on the first metallic portion so that a light emitting surface is positioned opposite to the installation surface and whose one electrode is connected to the first metallic portion and other electrode is connected to the second metallic portion; a metallic reflecting plate which is provided on a side of the installation surface so as to surround the installation surface; and a translucent sealant with which a space formed by the substrate and the metallic reflecting plate is filled and which has a light projecting surface opposite to the light emitting surface of the LED chip, the method including the steps of: integrating the first metallic portion to the metallic reflecting plate; forming the insulating section in a hollow manner on the first metallic portion in the area surrounded by the metallic reflecting plate so as to form the second metallic portion surrounded by the insulating section; and etching the metallic reflecting plate so as to form an opening corresponding to the light projecting surface so that a lateral width of the opening is smaller than a lateral width at an intermediated level between the opening and a bottom of the installation surface.

According to the foregoing arrangement, the first metallic portion, the second metallic portion, and the insulating section are formed on the installation surface surrounded by the metallic reflecting plate, so that the metallic reflecting plate can surround the LED chip 2 without being segmentized. Further, the metallic reflecting plate has the opening corresponding to the light projecting surface, and the opening is formed through etching so that the lateral width of the opening is smaller than the lateral width at the intermediate level between the opening and the bottom of the installation surface, so that it is possible to prevent the translucent sealant with which the space formed by the metallic reflecting plate is filled from coming off from the light emitting element.

Another light emitting element of the present invention may be arranged so as to include: an LED chip provided on an installation surface; a translucent sealant which is provided to seal the LED chip and has a plurality of side faces and a light projecting surface opposite to a light emitting surface of the LED chip; and a reflecting plate provided on one of the side faces of the translucent sealant, wherein at least one of the side faces is a shield-free surface.

Further, it is preferable to arrange the light emitting element of the present invention so that the reflecting plate has a skirt shape whose wider portion in a vicinity of the substrate is positioned closer to the LED chip.

Further, it is preferable to arrange the light emitting element of the present invention so that the reflecting plate is made of metal.

Further, it is preferable to arrange the light emitting element of the present invention so that the metal or metal constituting the first metallic portion, the second metallic portion, and the metallic reflecting plate is silver, copper, gold, or nickel.

Further, it is preferable to arrange the light emitting element of the present invention so that the same metal as that of the reflecting plate is provided on a surface of the substrate.

Further, it is preferable to arrange the light emitting element of the present invention so that the metal provided on the surface of the substrate is integrated to the reflecting plate.

Further, it is preferable to arrange the light emitting element so that an insulating ring is formed on a portion which is not connected to the reflecting plate, and an island shape made of the same metal as that of the metallic reflecting plate is surrounded by the insulating ring.

Further, it is preferable to arrange the light emitting element of the present invention so that a reflective sheet is disposed in contact with the shield-free surface.

Further, it is preferable to arrange the light emitting element of the present invention so that a reflective sheet is bonded to the shield-free surface.

Further, it is preferable to arrange the light emitting element so that scattering particles are diffused in the translucent sealant.

Further, a backlight unit of the present invention may be arranged so as to include: the light emitting element having the shield-free surface; and a waveguide disposed in a vicinity of the light projecting surface.

Further, a method according to the present invention for producing a light emitting element includes the steps of: providing a reflecting plate in contact with a substrate; providing one or more LED chips surrounded by the reflecting plate on the substrate; forming a translucent sealant on an area surrounded by the reflecting plate so as to seal the LED chip; and separating the area surrounded by the reflecting plate so as to form a shield-free surface corresponding to a side face of the translucent sealant.

Further, it is preferable to arrange the method of the present invention so that the step of forming the shield-free surface is carried out by dicing.

Further, it is preferable to arrange the method of the present invention so that the reflecting plate is formed by etching a metallic plate so as to have, as a cross sectional shape thereof, a skirt shape whose wider portion in a vicinity of the substrate is positioned closer to the LED chip.

Further, it is preferable to arrange the method of the present invention so that a metallic foil is pressed so as to form a bumpy shape, and the bumpy shape is etched so as to form the reflecting plate or the metallic reflecting plate.

Further, it is preferable to arrange the method of the present invention so that the etching is wet etching.

Further, an object of the present invention is to provide a light emitting element which can be made thinner and can efficiently project light emitted from the LED chip.

As described above, the light emitting element of the present invention includes: an LED chip provided on a substrate; a translucent sealant provided so as to seal the LED chip and having a plurality of side faces and a light projecting surface opposite to the LED chip; and a reflecting plate which is in contact with the substrate and is provided on one of the side faces of the translucent sealant, wherein at least one of the side faces has a shield-free surface.

As described above, a light emitting element of the present invention includes: at least one LED chip provided on an installation surface of a substrate; a metallic reflecting plate, provided upright in a light projecting direction of the LED chip on the installation surface so as to surround an entire periphery of the LED chip, the metallic reflecting plate reflecting light projected from the LED chip to guide the light to a light projecting surface provided in the light projecting direction; and a first metallic portion and a second metallic portion, respectively connected to the LED chip as electrode terminals for supplying a driving current to the LED chip, each of which is provided in an area surrounded by the metallic reflecting plate on the installation surface, wherein an insulating section is provided in the area so as to surround the second metallic portion, to electrically insulate the second metallic portion from other portion of the area, and the first metallic portion is formed outside the insulating section in the area as an installation surface metallic reflecting film so as to be in contact with the metallic reflecting plate.

According to the arrangement, the metallic reflecting plate which reflects light emitted from the LED chip and guides the light toward the light projecting surface provided in the light projecting direction is provided upright in the light projecting direction of the LED chip so as to surround an entire periphery of the LED chip. Thus, light irradiated from the LED chip is reflected by the metallic reflecting plate, so that the light can be efficiently guided to the light projecting surface. As a result, it is possible to suppress light leakage from the side face of the element and to enhance intensity of light projected outward from the light projecting surface.

In the area positioned at the installation surface and surrounded by the metallic reflecting plate, the insulating section for electrically insulating the second metallic portion from other portion of the area is formed so as to surround the second metallic portion. Thus, the installation surface metallic reflecting film can be formed on the area except for an area where the insulating section is formed. Thus, out of light emitted from the LED chip, a large part of light moving toward the substrate can be more efficiently guided by the installation surface metallic reflecting film toward the light projecting surface provided in a direction in which the reflected light is projected outward.

It is desirable to arrange the light emitting element according to the present invention so that: in the area surrounded by the metallic reflecting plate on the installation surface, the first metallic portion which serves as the installation surface metallic reflecting film is provided so as to surround an external periphery of the second metallic portion via the insulating section.

According to the arrangement, the first metallic layer serves also as the installation surface metallic reflecting film and is formed so as to surround the external periphery of the second metallic layer via the insulating section formed on the external periphery of the second metallic layer. Thus, the first metallic layer serving as the installation surface metallic reflecting film can be formed on an entire surface except for an area where the insulating section is formed while insulating the first metallic layer from the second metallic layer. The first metallic layer serving as the installation surface metallic reflecting film can be extensively formed on the installation surface in this manner. Thus, out of light emitted from the LED chip, a large part of light moving toward the substrate can be more efficiently guided to the light projecting surface by the first metallic layer. As a result, it is possible to further decrease an amount of light absorbed by the substrate, so that it is possible to further enhance intensity of light projected outward from the light projecting surface.

In order to solve the foregoing problems, another light emitting element according to the present invention includes: at least one LED chip provided on an installation surface of a substrate; a metallic reflecting plate, provided upright in a light projecting direction of the LED chip on the installation surface so as to surround an entire periphery of the LED chip, the metallic reflecting plate reflecting light projected from the LED chip to guide the light to a light projecting surface provided in the light projecting direction; a first metallic portion and a second metallic portion, respectively connected to the LED chip as electrode terminals for supplying a driving current to the LED chip, each of which is provided in an area surrounded by the metallic reflecting plate on the installation surface; and an installation metallic reflecting film, provided on the installation surface in the area surrounded by the metallic reflecting plate so as to be in contact with the metallic reflecting plate, wherein the metallic reflecting plate is electrically insulated from both the first metallic portion and the second metallic portion.

According to the arrangement, the metallic reflecting plate which reflects light emitted from the LED chip and guides the light toward the light projecting surface provided in the light projecting direction is provided upright in the light projecting direction of the LED chip so as to surround an entire periphery of the LED chip. Thus, light irradiated from the LED chip is reflected by the metallic reflecting plate, so that the light can be efficiently guided to the light projecting surface. As a result, it is possible to suppress light leakage from the side face of the element and to enhance intensity of light projected from the light projecting surface.

Further, the metallic reflecting plate is insulated from both the first metallic portion and the second metallic portion. Thus, in providing the light emitting element of the present invention onto a housing provided as a member of an electronic device such as a mobile phone and made of aluminum or the like, the metallic reflecting plate has no potential. As a result, it is possible to provide the light emitting element, not via a resin which less radiates heat, with the metallic reflecting plate in contact with the housing. Thus, heat generated at the metallic reflecting film can be efficiently radiated to the outside of the element. As a result, it is possible to realize a light emitting element having long-term reliability.

It is desirable to arrange the light emitting element according to the present invention so that: a first insulating section for electrically insulating the first metallic portion from other portion in the area on the installation surface and surrounded by the metallic reflecting plate is provided so as to surround the first metallic portion, and a second insulating section for electrically insulating the second metallic portion from other portion in the area is provided so as to surround the second metallic portion, and the installation surface metallic reflecting film is provided on the installation surface in the area surrounded by the metallic reflecting plate so as to cover an entire area outside the first insulating section and the second insulating section.

According to the arrangement, the external periphery of the first metallic portion is surrounded by the first insulating section and the external periphery of the second metallic portion is surrounded by the second insulating section, so that it is possible to reduce an area of the first insulating section for electrically insulating the first metallic portion from other portion in the area surrounded by the metallic reflecting plate and it is possible to reduce an area of the second insulating section for electrically insulating the second metallic portion from other portion in the area surrounded by the metallic reflecting plate. Thus, the installation surface metallic reflecting film can be extensively formed on an entire area except for the first and second insulating sections. Thus, out of light emitted from the LED chip, a large part of light moving toward the substrate can be more efficiently guided by the installation surface metallic reflecting film toward the light projecting surface provided in a direction in which the reflected light is projected outward. As a result, it is possible to further decrease an amount of light absorbed by the substrate and an amount of light which passes through the substrate and is projected outward from the rear surface, thereby enhancing intensity of light projected from the light projecting surface.

It is desirable to arrange the light emitting element according to the present invention that further includes a second LED chip provided on the installation surface, wherein the first metallic portion connected to the LED chip as an electrode terminal for supplying a driving current to the LED chip serves also as one of electrode terminals each supplying a driving current to the second LED chip, and the light emitting element further comprises a third metallic portion serving as the other of the electrode terminals, wherein the metallic reflecting plate is electrically insulated from all the first to third metallic portions.

According to the arrangement, a single light emitting element has two LED chips in a single circuit system. Thus, it is possible to obtain light intensity which is twice as high as that of the conventional arrangement without increasing the size of the element. As a result, it is possible to enhance intensity of light projected from the light projecting surface.

It is desirable to arrange the light emitting element so that a third insulating section is provided on the installation surface so as to surround the third metallic portion in area surrounded by the metallic reflecting plate so as to electrically insulate the third metallic portion from other portion in the area, and the installation surface metallic reflecting film is formed on the installation surface in the area surrounded by the metallic reflecting plate so as to cover an entire area outside the first to third insulating sections.

According to the arrangement, the first metallic portion is surrounded by the first insulating section, and the second metallic portion is surrounded by the second insulating section, and the third metallic portion is surrounded by the third insulating section, so that it is possible to further reduce an area of the first insulating section for electrically insulating the first metallic portion from other portion of the area surrounded by the metallic reflecting plate, and it is possible to further reduce an area of the second insulating section for electrically insulating the second metallic portion from other portion of the area surrounded by the metallic reflecting plate, and it is possible to further reduce an area of the third insulating section for electrically insulating the third metallic portion from other portion of the area surrounded by the metallic reflecting plate. Thus, the installation surface metallic reflecting film can be extensively formed on an entire area except for the first and second insulating sections. Thus, out of light emitted from the LED chip, a large part of light moving toward the substrate can be more efficiently guided by the installation surface metallic reflecting film toward the light projecting surface provided in a direction in which the reflected light is projected outward. As a result, it is possible to further decrease an amount of light absorbed by the substrate and an amount of light which passes through the substrate and is projected outward from the rear surface, thereby enhancing intensity of light projected from the light projecting surface.

It is desirable to arrange the light emitting element according to the present invention so that a heat radiating sheet covers not only an external periphery of the light emitting element but also at least a part of an external periphery of the metallic reflecting plate of the light emitting element.

According to the arrangement, the heat radiating sheet covers not only an external periphery of the light emitting element but also at least a part of an external periphery of the metallic reflecting plate of the light emitting element, so that heat generated at the metallic reflecting plate can be more efficiently radiated via the heat radiating sheet to the outside of the element.

It is desirable to arrange the light emitting element according to the present invention so that the heat radiating sheet is made of conductive material. As described above, the metallic reflecting plate of the present invention is insulated from other member, so that the metallic reflecting plate has no potential. Thus, no short circuit occurs, and it is possible to efficiently radiate heat generated at the metallic reflecting plate outward via the heat radiating sheet made of conductive material having excellent heat radiating property.

As described above, another light emitting element of the present invention includes: at least one LED chip provided on an installation surface of a substrate; a metallic reflecting plate, provided upright in a light projecting direction of the LED chip so as to reflect light projected from the LED chip and guide the light to a light projecting surface provided in the light projecting direction; and a translucent sealant which is provided so as to seal the LED chip and whose end in the light projecting direction has an opening as the light projecting surface, wherein a part of the side face of the translucent sealant serves as a shield-free surface, and the metallic reflecting plate is provided so as to entirely cover the side face other than the part which is shield-free, and the shield-free part is formed in a direction substantially perpendicular to a direction in which the light projecting surface is formed.

According to the arrangement, the light projecting surface is provided in the light projecting direction of the LED chip. Thus, unlike the arrangement of Tokukai 2005-223082 in which the reflecting plate is formed in the light projecting direction and the light projecting surface deviates by 90° from the light projecting direction, it is possible to project light, emitted from the LED chip, outward from the light projecting surface without any loss.

Further, the metallic reflecting plate which is provided upright in the light projecting direction of the LED chip so as to reflect light emitted from the LED chip and so as to guide the light to the light projecting surface provided in the light projecting direction is formed on a side face of the translucent sealant for sealing the LED chip, and a side face on which the metallic reflecting plate is not formed has a shield-free surface in a direction substantially perpendicular to a direction in which the light projecting surface is formed. Thus, for example, the backlight unit reflective sheet is disposed so as to cover the shield-free surface which is not covered by the foregoing metallic reflecting plate, thereby using the backlight unit reflective sheet also as a part of the metallic reflecting plate of the light emitting element.

Thus, if the light emitting element arranged in the foregoing manner is used for the backlight unit, it is possible to form a metallic reflecting plate which reflects light emitted from the LED chip under such condition that the backlight unit reflective sheet and the metallic reflecting plate of the light emitting element entirely cover side faces of the translucent sealant sealing the LED chip and guide the light to the light projecting surface provided in the light projecting direction. As a result, it is possible to reduce the thickness of the backlight unit without decreasing efficiency at which light is projected outward.

It is desirable to arrange the light emitting element according to the present invention so that: a first metallic portion and a second metallic portion electrically connected to the LED chip are provided on the installation surface in the area surrounded by the metallic reflecting plate, and an insulating section for electrically insulating the second metallic portion from other portion in the area is provided so as to surround the second metallic portion.

It is desirable to arrange the light emitting element according to the present invention so that the first metallic portion serving as an installation surface metallic reflecting film is provided on the installation surface in the area surrounded by the metallic reflecting plate so as to surround an external periphery of the second metallic portion via the insulating section.

It is desirable to arrange the light emitting element according to the present invention so that: the insulating section has a circular shape, and the second metallic portion is electrically insulated from the metallic reflecting plate via the insulating section, and the second metallic portion is made of the same metal as the metallic reflecting plate and has an island shape.

It is desirable to arrange the light emitting element according to the present invention so that a reflective sheet is disposed in contact with the shield-free surface.

It is desirable to arrange the light emitting element according to the present invention so that a reflective sheet is bonded to the shield-free surface.

It is desirable to arrange the light emitting element according to the present invention so that the metallic reflecting plate is integrated to the installation surface metallic reflecting film.

According to the arrangement, the metallic reflecting plate is integrated to the installation surface metallic reflecting film. Thus, the installation surface metallic reflecting film can be extensively formed on the installation surface. In this manner, it is possible to realize the light emitting element having excellent heat radiating property by forming metal on a large area of the light emitting element. Further, heat generated at the time of light emission of the LED chip can be transmitted toward the surface of the substrate to which the installation surface metallic reflecting film is integrated, and the heat can be efficiently radiated toward the rear surface. As a result, it is possible to suppress deterioration caused by the heat, so that it is possible to realize the light emitting element having the long-term reliability.

It is desirable to arrange the light emitting element according to the present invention so that the metallic reflecting plate has a skirt shape whose wider portion in a vicinity of the substrate is positioned closer to the LED chip.

It is desirable to arrange the light emitting element according to the present invention so that at least the second rear surface electrode covers an entire area corresponding, in a laminating direction, to an area where the insulating section is formed.

It is desirable to arrange the light emitting element according to the present invention so that at least the second rear surface electrode is connected to the second metallic portion via at least one conduction section formed so as to cover an entire area corresponding, in the laminating direction, to the area where the insulating section is formed.

It is desirable to arrange the light emitting element according to the present invention so that the substrate has a rear surface on the opposite side of the installation surface so that a first rear surface electrode connected to the first metallic portion and a second rear surface electrode connected to the second metallic portion are provided on the rear surface as external connection electrode terminals.

According to the arrangement, the first rear surface electrode and the second rear surface electrode which are respectively connected to the first metallic portion and the second metallic portion are formed on the rear surface of the substrate as external connection electrode terminals. In this manner, it is possible to decrease an amount of light which passes through the substrate and moves outward from the rear surface side by providing the external connection electrode terminals on the rear surface side of the light emitting element.

It is desirable to arrange the light emitting element according to the present invention so that the first rear surface electrode is formed so as to cover an entire area corresponding, in the laminating direction, to an area where the first insulating section is formed, and the second rear surface electrode is formed so as to cover an entire area corresponding, in the laminating direction, to an area where the second insulating section is formed.

According to the arrangement, the first rear surface electrode is formed so as to cover the area where the first insulating section is formed, and the second rear surface electrode is formed so as to cover the area where the second insulating section is formed. Thus, out of light emitted from the LED chip, light moving from the installation surface toward the rear surface side can be prevented from passing through the first and second insulating sections of the substrate, thereby preventing the light from moving from the rear surface side to the outside of the element. As a result, it is possible to enhance intensity of light projected from the light projecting surface.

It is desirable to arrange the light emitting element according to the present invention so that the first rear surface electrode is connected to the first metallic portion via at least one conduction section formed so as to cover the entire area corresponding, in the laminating direction, to the area where the first insulating section is formed, and the second rear surface electrode is connected to the second metallic portion via at least one conduction section formed so as to cover the entire area corresponding, in the laminating direction, to the second insulating section.

According to the arrangement, the first insulating section is covered by the conduction section which is formed nearer to the installation surface of the substrate than the first rear surface electrode, and the second insulating section is covered by the conduction section which is formed nearer to the installation surface of the substrate than the second rear surface electrode. Thus, it is possible to more effectively decrease an amount of light which passes through the first and second insulating sections and leaks from the rear surface side to the outside of the element. As a result, it is possible to further enhance intensity of light projected from the light projecting surface.

It is desirable to arrange the light emitting element according to the present invention so that the conduction section is more internally disposed than side faces of the substrate.

It is desirable to arrange the light emitting element according to the present invention so that an external periphery of the metallic reflecting plate is positioned more internally than an external periphery of the light emitting element in a longitudinal direction of the light emitting element.

It is desirable to arrange the light emitting element according to the present invention so that the conduction section insulated from the metallic reflecting plate is more internally disposed than side faces of the substrate.

It is desirable to arrange the light emitting element according to the present invention so that each of the first metallic portion, the second metallic portion, and the metallic reflecting plate is made of copper, silver, gold, or nickel.

According to the arrangement, copper, silver, gold, or nickel which is highly reflective metal is used, so that it is possible to efficiently guide light emitted from the LED chip to the light projecting surface.

It is desirable to arrange the light emitting element according to the present invention so that the substrate has a rear surface on the opposite side of the installation surface so that the rear surface has, as external connection electrode terminals, first to third rear surface electrodes connected to the installation surface metallic reflecting film on which the first metallic portion, the second metallic portion, and the LED chip are provided.

According to the arrangement, the first to third rear surface electrodes respectively connected to the first to third metallic portions are formed on the rear surface of the substrate as external connection electrode terminals. It is possible to decrease an amount of light which passes through the substrate and moves outward from the rear surface side by providing the external connection electrode terminals of the light emitting element on the rear surface side of the substrate in this manner.

It is desirable to arrange the light emitting element according to the present invention such that: the first rear surface electrode covers an entire area corresponding, in a laminating direction, to an area where the first insulating section is formed, and the second rear surface electrode covers an entire area corresponding, in the laminating direction, to an area where the second insulating section is formed, and the third rear surface electrode covers an entire area corresponding, in the laminating direction, to an area where the third insulating section is formed.

According to the arrangement, the first rear surface electrode is formed so as to cover the area where the first insulating section is formed, and the second rear surface electrode is formed so as to cover the area where the second insulating section is formed, and the third rear surface electrode is formed so as to cover the area where the third insulating section is formed. Thus, out of light emitted from the LED chip, light moving from the installation surface toward the rear surface side can be prevented from passing through the first to third insulating sections of the substrate, thereby preventing the light from moving from the rear surface side to the outside of the element. As a result, it is possible to enhance intensity of light projected from the light projecting surface.

It is desirable to arrange the light emitting element according to the present invention such that: the first rear surface electrode is connected to the first metallic portion via at least one conduction section covering an entire area corresponding, in a laminating direction, to an area where the first insulating section is formed, and the second rear surface electrode is connected to the second metallic portion via at least one conduction section covering an entire area corresponding, in the laminating direction, to an area where the second insulating section is formed, and the third rear surface electrode is connected to the third metallic portion via at least one conduction section covering an entire area corresponding, in the laminating direction, to an area where the third insulating section is formed.

According to the arrangement, the entire area corresponding, in the laminating direction, to the area where the first insulating section is formed is covered by the conduction section which is formed nearer to the installation surface of the substrate than the first rear surface electrode, and the entire area corresponding, in the laminating direction, to the area where the second insulating section is formed is covered by the conduction section which is formed nearer to the installation surface of the substrate than the second rear surface electrode, and the entire area corresponding, in the laminating direction, to the area where the third insulating section is formed is covered by the conduction section which is formed nearer to the installation surface of the substrate than the third rear surface electrode. Thus, it is possible to more effectively decrease an amount of light which passes through the first to third insulating sections and leaks from the rear surface side to the outside of the element. As a result, it is possible to further enhance intensity of light projected from the light projecting surface.

It is desirable to arrange the light emitting element according to the present invention such that each of the first to third metallic portions is made of copper, silver, gold, or nickel.

According to the arrangement, copper, silver, gold, or nickel which is highly reflective metal is used, so that it is possible to efficiently guide light emitted from the LED chip to the light projecting surface.

It is desirable to arrange the light emitting element according to the present invention so that: an internal periphery of the metallic reflecting plate has edges in the light projecting direction of the LED chip so that the edges constitute an opening, as the light projecting surface, at an uppermost level of a space formed by the installation surface and the metallic reflecting plate, and a translucent sealant is provided so as to fill the space, and the space has such a shape that a lateral width at an intermediate level between the light projecting surface and the installation surface is larger than a maximum lateral width of the light projecting surface and the space becomes narrower from the intermediate level to the opening.

Generally, a blue LED which emits blue light is used as the LED provided on the light emitting element. Thus, in order to enhance the reflectivity, the surface of the metallic reflecting plate is plated with silver having high reflectivity with respect to blue light. However, silver is so reactive that it is likely to be deteriorated and corroded, so that it is necessary to protect silver so as not to come off or be deteriorated. Thus, the present invention is arranged so that: the space is filled with the translucent sealant, and the translucent sealant is tightly in contact with silver.

Thus, as a resin constituting the translucent sealant, silicone or the like which is less adhesive than epoxy or the like is generally used. Thus, as in the foregoing arrangement, the opening serving as the light projecting surface of the translucent sealant is made narrower, so that the translucent sealant can be more tightly in contact with the internal periphery of the metallic reflecting plate, thereby suppressing coming-off of the translucent sealant. As a result, the internal periphery of the metallic reflecting plate can be stably protected by the resin sealant.

It is desirable to arrange the light emitting element according to the present invention so that the internal periphery of the metallic reflecting plate has a bumpy surface which is in contact with the translucent sealant.

According to the arrangement, an area where the metallic reflecting plate and the translucent sealant are in contact with each other increases. Thus, as in the foregoing arrangement, the translucent sealant can be more tightly in contact with the internal periphery of the metallic reflecting plate, thereby suppressing coming-off of the translucent sealant. As a result, the internal periphery of the metallic reflecting plate can be stably protected by the resin sealant.

It is preferable to arrange the light emitting element according to the present invention so that the translucent sealant includes scattering particles.

As described above, a backlight unit of the present invention includes the light emitting element and an optical waveguide disposed in a vicinity of the light projecting surface.

According to the arrangement, it is possible to realize a backlight unit which efficiently utilizes light and has long-term reliability due to its light emitting element which allows not only less light leakage and higher efficiency in projecting light but also excellent heat radiation.

It is desirable to arrange the a backlight unit according to the present invention so that a heat radiating sheet covers not only an external periphery of the light emitting element but also at least a part of an external periphery of the metallic reflecting plate of the light emitting element.

It is desirable to arrange the backlight unit so that the light emitting element includes an earth electrode (third rear surface electrode) provided on a rear surface of the substrate and electrically connected to the metallic reflecting plate and an installation surface metallic reflecting film which is in contact with the metallic reflecting plate.

According to the arrangement, in addition to the aforementioned heat radiating sheet, also the third rear surface electrode thermally connected to an LED chip installation surface (installation surface metallic reflecting film) is expected to radiate heat. Further, after providing the LED chip, it is possible to prevent the metallic reflecting plate and the installation surface metallic reflecting film which is in contact with the metallic reflecting plate from having a floating potential by connecting the third rear surface electrode with the earth terminal on the side of installation. As a result, it is possible to prevent malfunction or breakage which caused by surge or the like.

Another backlight unit of the present invention includes: at least one LED chip provided on an installation surface of a substrate; a metallic reflecting plate, provided upright in a light projecting direction of the LED chip so as to reflect light projected from the LED chip and guide the light to a light projecting surface provided in the light projecting direction; and a translucent sealant which is provided so as to seal the LED chip and whose end in the light projecting direction has an opening as the light projecting surface, wherein: a part of the side face of the translucent sealant serves as a shield-free surface, and the metallic reflecting plate is provided so as to entirely cover the side face other than the part which is shield-free, and the shield-free part is formed in a direction substantially perpendicular to a direction in which the light projecting surface is formed, the backlight unit further comprising: an optical waveguide which is disposed in a vicinity of the light projecting surface so as to scatter light projected from the light projecting surface; and a reflective sheet which is disposed in contact with the optical waveguide so as to project the light scattered by the optical waveguide to a desired area, wherein: the reflective sheet is disposed so as to entirely cover the opening which constitutes a part of a side face of the translucent sealant, and the reflective sheet serves also as a metallic reflecting plate which reflects light emitted from the LED chip to guide the light to the light projecting surface.

According to the arrangement, the backlight unit reflective sheet is disposed so as to cover the shield-free surface which is not covered by the foregoing metallic reflecting plate, thereby using the backlight unit reflective sheet also as a part of the metallic reflecting plate of the light emitting element.

Thus, it is possible to form a metallic reflecting plate which reflects light emitted from the LED chip under such condition that the backlight unit reflective sheet and the metallic reflecting plate of the light emitting element entirely cover side faces of the translucent sealant sealing the LED chip and guide the light to the light projecting surface providing in the light projecting direction. As a result, it is possible to reduce the thickness of the backlight unit without decreasing efficiency at which light is projected outward.

As described above, a method according to the present invention for producing a light emitting element includes the steps of: providing at least one LED chip on an installation surface of a substrate; forming a metallic reflecting plate for reflecting light emitted from the LED chip to guide the light to a light projecting surface provided in a light projecting direction on the installation surface, so as to be disposed upright in the light projecting direction to surround an entire periphery of the LED chip; filling a space formed by the installation surface and the metallic reflecting plate with a translucent sealant so as to seal the LED chip; and segmentizing an area surrounded by the metallic reflecting plate so that a segmentized face of the translucent sealant serves as a shield-free surface in a direction substantially perpendicular to a direction in which the light projecting surface is formed.

As described above, another method according to the present invention for producing a light emitting element includes the steps of: providing at least one LED chip on an installation surface of a substrate; forming a metallic reflecting plate for reflecting light emitted from the LED chip to guide the light to a light projecting surface provided in a light projecting direction on the installation surface, so as to be disposed upright in the light projecting direction to surround an entire periphery of the LED chip; forming a first metallic portion and a second metallic portion, each serving as an electrode terminal for supplying a driving current to the LED chip, each of which is provided on the installation surface in an area surrounded by the metallic reflecting plate so as to be electrically connected to the LED chip; and forming an installation surface metallic reflecting film in a space formed by the installation surface and the metallic reflecting plate so as to be in contact with the metallic reflecting plate, wherein the metallic reflecting plate is electrically insulated from both the first metallic portion and the second metallic portion.

According to the arrangement, the metallic reflecting plate which reflects light emitted from the LED chip and guides the light to the light projecting surface provided in the light projecting direction is provided upright in the light projecting direction of the LED chip so as to surround an entire periphery of the LED chip. Thus, the light emitting element produced in accordance with the aforementioned production method allows the metallic reflecting plate to reflect light irradiated from the LED chip, thereby efficiently guiding the light to the light projecting surface. As a result, it is possible to suppress light leakage from the light emitting element, thereby enhancing intensity of light projected from the light projecting surface.

Further, the metallic reflecting plate is insulated from both the first metallic portion and the second metallic portion. Thus, in providing the light emitting element of the present invention onto a housing provided as a member constituting an electronic device such as a mobile phone and made of metal such as aluminum, the metallic reflecting plate has no potential. Thus, it is possible to efficiently radiate heat generated at the metallic reflecting plate to the outside of the element not via a resin or the like which less radiates heat. As a result, it is possible to realize a light emitting element having long-term reliability.

It is desirable to arrange the method according to the present invention for producing a light emitting element so as to include the steps of: forming (i) a first insulating section surrounding the first metallic portion so as to electrically insulate the first metallic portion from other portion of the area positioned at the installation surface and surrounded by the metallic reflecting plate and (ii) a second insulating section surrounding the second metallic portion so as to electrically insulate the second metallic portion from other portion of the area; and forming the installation surface metallic reflecting film in the area surrounded by the installation surface and the metallic reflecting plate so as to cover an entire area outside the first insulating section and the second insulating section.

According to the arrangement, the first insulating section surrounds the external periphery of the first metallic portion and the second insulating section surrounds the external periphery of the second metallic portion, so that area sizes of the first and second metallic portions can be respectively made smaller than area sizes of the first and second insulating sections which electrically insulate the first and second metallic portions respectively from other portions of the area surrounded by the metallic reflecting plate.

Further, the installation surface metallic reflecting film intervenes between the first insulating section and the metallic reflecting plate and intervenes between the second insulating section and the metallic reflecting plate. Thus, even if positional deviation occurs in the step of forming the metallic reflecting plate, this influences neither a shape nor an area of each insulating section. As a result, there is no unevenness in an amount of light leakage from the insulating section. Further, it is possible to minimize a separation distance prepared to insulate the first and second electrodes from the metallic reflecting plate without caring any alignment error, so that areas of the first and second insulating sections can be designed so as to be minimized. Thus, it is possible to more effectively prevent light leakage from the first and second insulating sections, so that light moving from the metallic reflecting plate to the substrate can be more efficiently reflected toward the light projecting surface by the installation surface metallic reflecting film. As a result, it is possible to further improve the light utilization efficiency and the heat radiating property.

Thus, in the light emitting element produced in the foregoing manner, the installation surface metallic reflecting film can be extensively formed on the entire area except for the first and second insulating sections. Thus, out of light emitted from the LED chip, a large part of light moving toward the substrate can be more efficiently guided by the installation surface metallic reflecting film to the light projecting surface provided in a direction in which the reflected light is projected outward. As a result, it is possible to further decrease an amount of light absorbed by the substrate and an amount of light which passes through the substrate and leaks from the rear surface side to the outside, thereby further enhancing intensity of light projected from the light projecting surface.

It is desirable to arrange the method according to the present invention for producing a light emitting element so as to further includes the steps of: forming a second LED chip on the installation surface; forming the first metallic portion electrically connected to the LED chip as an electrode terminal for supplying a driving current to the LED chip so that the first metallic portion functions as one of power source terminals which supplies a driving current to the second LED chip and forming a third metallic portion serving as the other of the power source terminals which supplies a driving current to the second LED chip, wherein the metallic reflecting plate is electrically insulated from all the first to third metallic portions.

According to the arrangement, two LED chips are provided in the element in a single circuit system. Thus, the light emitting element produced according to the foregoing method can project light whose intensity is twice as high as the conventional arrangement without increasing the size of the light emitting element. Further, the installation surface metallic reflecting film is formed on the entire area, except for the first to third insulating sections, which is positioned in the installation surface and is surrounded by the metallic reflecting plate. Thus, out of light emitted from the LED chip, a large part of light moving toward the substrate can be reflected by the installation surface metallic reflecting film toward the light projecting surface. As a result, it is possible to decrease an amount of light absorbed by the substrate, thereby enhancing intensity of light projected from the light projecting surface.

It is desirable to arrange the method according to the present invention for producing a light emitting element so as to include the steps of: forming a third insulating section on the installation surface so as to surround the third metallic portion in area surrounded by the metallic reflecting plate so as to electrically insulate the third metallic portion from other portion in the area; and forming the installation surface metallic reflecting film on an entire area outside the first to third insulating sections.

According to the arrangement, the external periphery of the first metallic portion is surrounded by the first insulating section, and the external periphery of the second metallic portion is surrounded by the second insulating section, and the external periphery of the third metallic portion is surrounded by the third insulating section, so that the areas of the first to third insulating sections which respectively allow electrical insulation between the first to third metallic portions and other portions of the area surrounded by the metallic reflecting plate can be made smaller.

Further, the installation surface metallic reflecting film intervenes between the first insulating section and the metallic reflecting plate, intervenes between the second insulating section and the metallic reflecting plate, and intervenes between the third insulating section and the metallic reflecting plate. Thus, even if any positional deviation occurs in the step of forming the metallic reflecting plate, this influences neither a shape nor an area of each insulating section. As a result, there is no unevenness in an amount of light leakage from the insulating section. Further, it is possible to minimize a separation distance prepared to insulate the first to third electrodes from the metallic reflecting plate without caring any alignment error, so that areas of the first to third insulating sections can be designed so as to be minimized. Thus, it is possible to more effectively prevent light leakage from the first to third insulating sections, so that light moving from the metallic reflecting plate to the substrate can be more efficiently reflected toward the light projecting surface by the installation surface metallic reflecting film. As a result, it is possible to further improve the light utilization efficiency and the heat radiating property.

Thus, in the light emitting element produced in the foregoing manner, the installation surface metallic reflecting film can be extensively formed on the entire area except for the first to third insulating sections. Thus, out of light emitted from the LED chip, a large part of light moving toward the substrate can be more efficiently guided by the installation surface metallic reflecting film to the light projecting surface provided in a direction in which the reflected light is projected outward. As a result, it is possible to further decrease an amount of light absorbed by the substrate and an amount of light which passes through the substrate and leaks from the rear surface side to the outside, thereby further enhancing intensity of light projected from the light projecting surface.

It is desirable to arrange the method according to the present invention for producing a light emitting element so that the metallic reflecting plate is integrated to the installation surface metallic reflecting film.

According to the arrangement, the metallic reflecting plate can be integrated to the installation surface metallic reflecting film in accordance with plating or a similar method without using any adhesive. Thus, unlike the conventional arrangement, heat generated at the time of light emission of the LED chip does not remain in a resin or the like which less conducts heat and the heat is conducted to the installation surface metallic reflecting film formed on a surface of the substrate integrated to the metallic reflecting plate, so that the heat is effectively radiated to the rear surface side of the substrate. As a result, it is possible to produce a light emitting element whose deterioration caused by heat can be suppressed and which has long-term reliability.

It is desirable to arrange the method according to the present invention for producing a light emitting element so as to include the step of forming, as external connection electrode terminals, (a) a first rear surface electrode connected to the first metallic portion and (b) a second rear surface electrode connected to the second metallic portion, on a rear surface of the substrate on the opposite side of the installation surface.

According to the arrangement, the first rear surface electrode connected to the first metallic portion and the second rear surface electrode connected to the second metallic portion are provided on the rear surface of the substrate as external connection electrode terminals. Thus, in the light emitting element produced according to the foregoing method, the external connection electrode terminals of the light emitting element are provided on the rear surface side of the substrate, so that it is possible to decrease an amount of light which passes through the substrate and leaks from the rear surface side to the outside.

It is desirable to arrange the method according to the present invention for producing a light emitting element so that the first rear surface electrode is formed so as to cover an entire area corresponding, in a laminating direction, to an area where the first insulating section is formed, and the second rear surface electrode is formed so as to cover an entire area corresponding, in the laminating direction, to an area where the second insulating section is formed.

According to the arrangement, the first rear surface electrode is formed so as to cover the first insulating section and the second rear surface electrode is formed so as to cover the second insulating section. Thus, in the light emitting element produced in accordance with the foregoing method, out of light emitted from the LED chip, light moving from the installation surface into the substrate can be prevented from passing through the first and second insulating sections of the substrate and from leaking from the rear surface to the outside of the element. As a result, it is possible to enhance intensity of light projected from the light projecting surface.

It is desirable to arrange the method according to the present invention for producing a backlight unit so that the first rear surface electrode is formed so as to be connected to the first metallic portion via at least one conduction section covering an entire area corresponding, in a laminating direction, to an area where the first insulating section is formed, and the second rear surface electrode is formed so as to be connected to the second metallic portion via at least one conduction section covering an entire area corresponding, in the laminating direction, to an area where the second insulating section is formed.

According to the arrangement, the first and second insulating sections are respectively covered by the conduction sections provided nearer to the installation surface than the first and second rear surface electrodes. Thus, the light emitting element produced in accordance with the foregoing method can more effectively decrease an amount of light which passes through the first and second insulating sections and leaks from the rear surface side to the outside of the element. As a result, it is possible to further enhance intensity of light projected from the light projecting surface.

It is desirable to arrange the method according to the present invention for producing a backlight unit so that each of the first metallic portion, the second metallic portion, and the metallic reflecting plate is made of copper, silver, gold, or nickel.

According to the arrangement, copper, silver, gold, or nickel which is highly reflective metal is used, so that it is possible to efficiently guide light emitted from the LED chip to the light projecting surface.

It is desirable to arrange the method according to the present invention for producing a backlight unit so that a first rear surface electrode, a second rear surface electrode, and a third rear surface electrode which are respectively connected to the first metallic portion, the second metallic portion, and the third metallic portion are provided on the substrate as external connection electrode terminals on a rear surface of the substrate on the opposite side of the installation surface.

According to the arrangement, the first to third rear surface electrodes respectively connected to the first to third metallic portions are formed on the rear surface of the substrate as external connection electrode terminals. Thus, in the light emitting element produced in accordance with the foregoing method, the external connection electrode terminals are provided on the rear surface side of the substrate, so that it is possible to decrease an amount of light which passes through the substrate and leaks from the rear surface side to the outside.

It is desirable to arrange the method according to the present invention for producing a backlight unit so that the first rear surface electrode is formed so as to cover an entire area corresponding, in a laminating direction, to an area where the first insulating section is formed, and the second rear surface electrode is formed so as to cover an entire area corresponding, in the laminating direction, to an area where the second insulating section is formed, and the third rear surface electrode is formed so as to cover an entire area corresponding, in the laminating direction, to the area where the third insulating section is formed.

According to the arrangement, the first rear surface electrode is formed so as to cover the area where the first insulating section is formed, and the second rear surface electrode is formed so as to cover the area where the second insulating section is formed, and the third rear surface electrode is formed so as to cover the area where the third insulating section is formed. Thus, out of light emitted from the LED chip, light moving from the installation surface into the substrate can be prevented from passing through the substrate and from leaking from the rear surface to the outside of the element. As a result, it is possible to enhance intensity of light projected from the light projecting surface.

It is desirable to arrange the method according to the present invention for producing a backlight unit so that the first rear surface electrode is formed so as to be connected to the first metallic portion via at least one conduction section covering an entire area corresponding, in a laminating direction, to an area where the first insulating section is formed, and the second rear surface electrode is formed so as to be connected to the second metallic portion via at least one conduction section covering an entire area corresponding, in the laminating direction, to an area where the second insulating section is formed, and the third rear surface electrode is formed so as to be connected to the third metallic portion via at least one conduction section covering an entire area corresponding, in the laminating direction, to an area where the third insulating section is formed.

According to the arrangement, the first rear surface electrode is formed so that the entire area corresponding, in the laminating direction, to the area where the first insulating section is formed is positioned nearer to the installation surface side of the substrate than the area where the first electrode is formed, and the second rear surface electrode is formed so that the entire area corresponding, in the laminating direction, to the area where the second insulating section is formed is positioned nearer to the installation surface side of the substrate than the area where the second electrode is formed, and the third rear surface electrode is formed so that the entire area corresponding, in the laminating direction, to the area where the third insulating section is formed is positioned nearer to the installation surface side of the substrate than the area where the third electrode is formed. Thus, it is possible to more effectively decrease an amount of light which passes through the first to third insulating sections and leaks from the rear surface side to the outside of the element. As a result, it is possible to further enhance intensity of light projected from the light projecting surface.

It is desirable to arrange the method according to the present invention for producing a backlight unit so that each of the first to third metallic portions is made of copper, silver, gold, or nickel.

According to the arrangement, copper, silver, gold, or nickel which is highly reflective metal is used, so that it is possible to efficiently guide light emitted from the LED chip to the light projecting surface.

A method according to the present invention for producing a backlight unit includes the aforementioned light emitting element producing steps and a step of forming a heat radiating sheet for radiating outward heat, generated at the metallic reflecting plate, not only on an external periphery of the light emitting element but also on at least a part of an external periphery of the metallic reflecting plate.

As described above, the metallic reflecting plate of the present invention is insulated from other portions, so that the metallic reflecting plate has no potential. Thus, the light emitting element produced in accordance with the foregoing method can more efficiently radiate heat generated at the metallic reflecting plate to the outside via the heat radiating sheet made of conductive material having excellent heat radiating property without any problem such as short circuit. It is desirable that the conductive material is graphite. It is desirable to arrange the method so as to include a step of forming a heat radiating sheet for radiating heat, generated at the metallic reflecting plate, not only on an external periphery of the light emitting element but also on at least a part of an external periphery of the metallic reflecting plate.

According to the arrangement, the heat radiating sheet for radiating outward heat, generated at the metallic reflecting plate, is formed not only on an external periphery of the light emitting element but also on at least a part of an external periphery of the metallic reflecting plate. Thus, the backlight unit having the light emitting element produced in accordance with the foregoing method can more efficiently radiate heat, generated at the metallic reflecting plate, to the outside via the heat radiating sheet.

It is desirable to arrange the method according to the present invention for producing a backlight unit so that the heat radiating sheet is made of conductive material.

As described above, the metallic reflecting plate of the present invention is insulated from other portions, so that the metallic reflecting plate has no potential. Thus, the light emitting element produced in accordance with the foregoing method can more efficiently radiate heat generated at the metallic reflecting plate to the outside via the heat radiating sheet made of conductive material having excellent heat radiating property without any problem such as short circuit.

It is desirable that the conductive material is graphite.

Further, it is desirable that the heat radiating sheet is grounded by the light source section.

The present invention is not limited to the description of the embodiments above, but may be altered by a skilled person within the scope of the claims. An embodiment based on a proper combination of technical means disclosed in different embodiments is encompassed in the technical scope of the present invention.

1. A light emitting element, comprising:
at least one LED chip provided on an installation surface of a substrate;
a metallic reflecting plate, provided upright on the installation surface of the substrate in a light projecting direction of the LED chip on the installation surface so as to surround an entire periphery of the LED chip, said metallic reflecting plate reflecting light projected from the LED chip to guide the light to a light projecting surface provided in the light projecting direction; and
a first metallic portion and a second metallic portion, respectively connected to said LED chip as electrode terminals for supplying a driving current to the LED chip, each of which is provided in an area surrounded by the metallic reflecting plate on the installation surface, wherein
an insulating section is provided in said area so as to surround the second metallic portion, to electrically insulate the second metallic portion from other portion of said area, and
the first metallic portion is formed outside the insulating section in said area as an installation surface metallic reflecting film so as to be in contact with the metallic reflecting plate.

2. The light emitting element as set forth in claim 1, wherein:
in said area surrounded by the metallic reflecting plate on the installation surface, the first metallic portion which serves as the installation surface metallic reflecting film is provided so as to surround an external periphery of the second metallic portion via the insulating section.

3-13. (canceled)

14. The light emitting element as set forth in claim 2, wherein the metallic reflecting plate is made of the same metal as the installation surface metallic reflecting film.

15. The light emitting element as set forth in claim 14, wherein the metallic reflecting plate is integrated to the installation surface metallic reflecting film.

16. The light emitting element as set forth in claim 1, wherein the metallic reflecting plate has a skirt shape whose wider portion in a vicinity of the substrate is positioned closer to the LED chip.

17. The light emitting element as set forth in claim 2, wherein the substrate has a rear surface on the opposite side of the installation surface so that a first rear surface electrode connected to the first metallic portion and a second rear surface electrode connected to the second metallic portion are provided on the rear surface as external connection electrode terminals.

18. The light emitting element as set forth in claim 17, wherein at least the second rear surface electrode covers an entire area corresponding, in a laminating direction, to an area where the insulating section is formed.

19. The light emitting element as set forth in claim 18, wherein at least the second rear surface electrode is connected to the second metallic portion via at least one conduction section formed so as to cover an entire area corresponding, in the laminating direction, to the area where the insulating section is formed.

20-25. (canceled)

26. The light emitting element as set forth in claim 1, wherein each of the first metallic portion, the second metallic portion, and the metallic reflecting plate is made of copper, silver, gold, or nickel.

27-30. (canceled)

31. The light emitting element as set forth in claim 1, wherein:
an internal periphery of the metallic reflecting plate has edges in the light projecting direction of the LED chip so that the edges constitute an opening, as the light projecting surface, at an uppermost level of a space formed by the installation surface and the metallic reflecting plate, and
a translucent sealant is provided so as to fill the space, and
the space has such a shape that a lateral width at an intermediate level between the light projecting surface and the installation surface is larger than a maximum lateral width of the light projecting surface and the space becomes narrower from the intermediate level to the opening.

32. The light emitting element as set forth in claim 31, wherein the internal periphery of the metallic reflecting plate has a bumpy surface which is in contact with the translucent sealant.

33-47. (canceled)
